(19) United States
(12) Patent Application Publication
(10) Pub. No.: US 2026/0013103 A1
(43) Pub. Date: Jan. 8, 2026

(54) TRANSISTOR AND MEMORY DEVICE

(71) Applicant: Semiconductor Energy Laboratory Co., Ltd., Atsugi-shi, Kanagawa-ken (JP)

(72) Inventors: Hidekazu MIYAIRI, Hadano (JP); Yuji EGI, Atsugi (JP)

(21) Appl. No.: 19/105,929

(22) PCT Filed: Oct. 6, 2023
(86) PCT No.: PCT/IB2023/060029

§ 371 Date: Feb. 24, 2025

(30) Foreign Application Priority Data
Oct. 14, 2022 (JP) 2022-165766

(51) Int. Cl. H10B 12/00

(52) U.S. Cl. CPC H10B 12/31; H10B 12/05

(57) ABSTRACT

A memory device that can be miniaturized or highly integrated is provided. A transistor includes a first conductor including a columnar region, a first insulator including a first region of a tubular shape, a second conductor including an opening penetrated by the first conductor, a first semiconductor positioned over the second conductor and including a second region of a tubular shape, and a third conductor over the first semiconductor. The first region of the first insulator surrounds the columnar region of the first conductor. The first conductor includes a third region positioned above the opening of the second conductor. The third region of the first conductor is surrounded by the second region of the first semiconductor with the first region of the first insulator therebetween.

### TECHNICAL FIELD

One embodiment of the present invention relates to a transistor, a semiconductor device, a memory device, and an electronic appliance. Another embodiment of the present invention relates to a method for manufacturing a memory device or a semiconductor device. Another embodiment of the present invention relates to a semiconductor wafer and a module.

Note that in this specification and the like, a semiconductor device refers to a general device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an image capturing device, an electronic appliance, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, the development of semiconductor devices has progressed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A chip (IC chip) mounted with an integrated circuit (IC) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film that can be used for the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. As another example, Patent Document 2 discloses a memory device that can retain stored contents for a long time by utilizing the feature of the low leakage current of the transistor using an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor using an oxide semiconductor film and a second transistor using an oxide semiconductor film.

Furthermore, by employing vertical transistors, an integrated circuit with higher density can be achieved. For example, Patent Document 4 discloses a vertical transistor in which a side surface of an oxide semiconductor is covered with a gate electrode with a gate insulator therebetween.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et. al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a transistor that can be miniaturized or highly integrated. Another object is to provide a transistor with a high operation speed. Another object is to provide a transistor with favorable electrical characteristics. Another object is to provide a transistor with a small variation in electrical characteristics. Another object is to provide a transistor with high reliability. Another object is to provide a transistor with a high on-state current.

Another object of one embodiment of the present invention is to provide a semiconductor device or a memory device that can be miniaturized or highly integrated. Another object is to provide a semiconductor device or a memory device with a high operation speed. Another object is to provide a semiconductor device or a memory device with high reliability. Another object is to provide a memory device a semiconductor device or with low power consumption.

Another object of one embodiment of the present invention is to provide a novel transistor, semiconductor device, or memory device. Another object is to provide a method for fabricating a novel transistor, semiconductor device, or memory device.

Note that the description of these objects does not preclude the existence of other objects. Note that one embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a transistor including a first conductor including a columnar region, a first insulator including a first region of a tubular shape, a second conductor including an opening penetrated by the first conductor, a first semiconductor positioned over the second conductor and including a second region of a tubular shape, and a third conductor over the first semiconductor. The first region of the first insulator surrounds the columnar region of the first conductor. The first conductor includes a third region positioned above the opening of the second conductor. The third region of the first conductor is surrounded by the second region of the first semiconductor with the first region of the first insulator therebetween.

In the above structure, the third conductor preferably overlaps with the first conductor.

In the above structure, it is preferable that the transistor include a second insulator, the second insulator include a second opening, the first conductor include a region positioned in the second opening, and the second conductor include a region in contact with a top surface of the second insulator.

Another embodiment of the present invention is a transistor including a first conductor including a columnar region, a first insulator including a first region of a tubular shape, a second conductor including an opening penetrated by the first conductor, a first semiconductor positioned over the second conductor and including a second region of a tubular shape, a second insulator over the first conductor, and a third conductor over the second insulator. The first region of the first insulator surrounds the columnar region of the first conductor. The first conductor includes a third region positioned above the opening of the second conductor. The third region of the first conductor is surrounded by the second region of the first semiconductor with the first region of the first insulator therebetween. The third conductor overlaps with the first conductor with the second insulator therebetween.

In the above structure, the third conductor preferably overlaps with the first conductor.

In the above structure, the first semiconductor preferably includes a region positioned over the second insulator and positioned between the second insulator and the third conductor.

In the above structure, it is preferable that the first insulator contain at least one of silicon oxide and silicon oxynitride and the second insulator contain at least one of silicon nitride and silicon nitride oxide.

In the above structure, it is preferable that the transistor include a third insulator, the third insulator include a second opening, the first conductor include a region positioned in the second opening, and the second conductor include a region in contact with a top surface of the second insulator.

In the above structure, the third conductor is preferably in contact with a top surface of the first semiconductor.

In the above structure, the first semiconductor preferably includes a region in contact with a side surface of the third conductor.

In the above structure, the first semiconductor is preferably a metal oxide containing indium or zinc.

Another embodiment of the present invention is a memory device including a transistor and a capacitor over the transistor. The transistor includes a first conductor including a columnar region, a first insulator including a first region of a tubular shape, a second conductor including an opening penetrated by the first conductor, a first semiconductor positioned over the second conductor and including a second region of a tubular shape, and a third conductor over the first semiconductor. The capacitor includes a fourth conductor including a columnar region, a second insulator provided to cover a side surface of the fourth conductor, and a fifth conductor over the second insulator. The first region of the first insulator is placed to surround the columnar region of the first conductor. The first conductor includes a third region positioned above the opening of the second conductor. The third region of the first conductor is surrounded by the second region of the first semiconductor with the first region of the first insulator therebetween. The fourth conductor is positioned over the third conductor.

In the above structure, the third conductor preferably overlaps with the first conductor.

In the above structure, the first conductor and the fourth conductor preferably overlap with each other in a plan view.

In the above structure, it is preferable that the memory device include a third insulator, the third insulator include a second opening, the fourth conductor include a fourth region positioned in the second opening and having a side surface in contact with the third insulator and a fifth region positioned over the fourth region and having a side surface in contact with the second insulator.

### Effect of the Invention

According to one embodiment of the present invention, a transistor that can be miniaturized or highly integrated can be provided. Alternatively, a transistor with a high operation speed can be provided. Alternatively, a transistor with favorable electrical characteristics can be provided. Alternatively, a transistor with a small variation in electrical characteristics can be provided. Alternatively, a transistor with high reliability can be provided. Alternatively, a transistor having a high on-state current can be provided.

According to another embodiment of the present invention, a semiconductor device or a memory device that can be miniaturized or highly integrated can be provided. Alternatively, a semiconductor device or a memory device with a high operation speed can be provided. Alternatively, a semiconductor device or a memory device with high reliability can be provided. Alternatively, a memory device with a small variation in electrical characteristics of transistors can be provided. Alternatively, a semiconductor device or a memory device with low power consumption can be provided.

According to another embodiment of the present invention, a novel transistor, semiconductor device, or memory device can be provided. Alternatively, a method for fabricating a novel transistor, semiconductor device, or memory device can be provided.

Note that the description of these effects does not preclude the existence of other effects. Note that one embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B are plan views illustrating an example of a transistor. FIG. 1C to FIG. 1F are cross-sectional views illustrating examples of transistors.

FIG. 2A and FIG. 2B are cross-sectional views illustrating the examples of transistors.

FIG. 3A is a plan view illustrating an example of a memory device. FIG. 3B is a circuit diagram illustrating an example of a structure of a memory device. FIG. 3C and FIG. 3D are cross-sectional views illustrating the example of the memory device.

FIG. 4A and FIG. 4B are cross-sectional views each illustrating an example of a memory device.

FIG. 5A to FIG. 5F are cross-sectional views illustrating an example of a method for fabricating a memory device.

FIG. 6A to FIG. 6F are cross-sectional views illustrating the example of the method for fabricating a memory device.

FIG. 7A to FIG. 7E are cross-sectional views illustrating the example of the method for fabricating a memory device.

FIG. 8A to FIG. 8E are cross-sectional views illustrating the example of the method for fabricating a memory device.

FIG. 9A to FIG. 9F are cross-sectional views illustrating an example of a method for fabricating a memory device.

FIG. 10A to FIG. 10C are cross-sectional views illustrating the example of the method for fabricating a memory device.

FIG. 11A to FIG. 11C are cross-sectional views illustrating the example of the method for fabricating a memory device.

FIG. 12A and FIG. 12B are cross-sectional views illustrating the example of the method for fabricating a memory device.

FIG. 13A to FIG. 13C are cross-sectional views illustrating an example of a method for fabricating a memory device.

FIG. 14A and FIG. 14B are cross-sectional views illustrating the example of the method for fabricating a memory device.

FIG. 15A to FIG. 15D are cross-sectional views illustrating examples of transistors.

FIG. 16A and FIG. 16B are cross-sectional views each illustrating an example of a memory device.

FIG. 17A to FIG. 17E are cross-sectional views illustrating a method for depositing a metal oxide according to one embodiment of the present invention.

FIG. 18A to FIG. 18D are cross-sectional views of a metal oxide according to one embodiment of the present invention.

FIG. 19A to FIG. 19D are cross-sectional views illustrating a method for depositing a metal oxide according to one embodiment of the present invention.

FIG. 20A to FIG. 20C are cross-sectional views illustrating the method for depositing a metal oxide of one embodiment of the present invention.

FIG. 21A is a plan view illustrating an example of a memory device. FIG. 21B is a cross-sectional view illustrating the example of the memory device.

FIG. 22 is a block diagram illustrating a structure example of a memory device.

FIG. 23A is a schematic view illustrating a structure example of a memory device. FIG. 23B is a circuit diagram illustrating a structure example of a memory device.

FIG. 24A and FIG. 24B are schematic views each illustrating a structure example of a memory device.

FIG. 25 is a circuit diagram illustrating a structure example of a memory device.

FIG. 26 is a cross-sectional view illustrating an example of a memory device.

FIG. 27A and FIG. 27B are schematic views of a semiconductor device of one embodiment of the present invention.

FIG. 28A and FIG. 28B are diagrams illustrating examples of electronic components.

FIG. 29A to FIG. 29E are schematic views of memory devices of one embodiment of the present invention.

FIG. 30A to FIG. 30H are diagrams illustrating electronic devices of one embodiment of the present invention.

FIG. 31 is a diagram illustrating an example of a device for space.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is applied to portions having similar functions, and the portions are not especially denoted by reference numerals in some cases.

Furthermore, especially in a plan view (also referred to as a “top view”), a perspective view, or the like, the description of some components might be omitted for easy understanding of the invention. The description of some hidden lines and the like might also be omitted.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components is changed as appropriate in accordance with the direction in which the components are described. Thus, without limitation to terms described in this specification, the description can be changed appropriately depending on the situation.

In this specification and the like, for example, the expression “X and Y are connected” means the case where X and Y are electrically connected. Here, the expression “X and Y are electrically connected” means connection that enables electrical signal transmission between X and Y in the case where an object (that refers to an element such as a switch, a transistor element, or a diode, a circuit including the element and a wiring, or the like) is present between X and Y. Note that the case where X and Y are electrically connected includes the case where X and Y are directly connected. Here, the expression “X and Y are directly connected” means connection that enables electrical signal transmission between X and Y through a wiring (or an electrode) or the like, not through the above object. In other words, direct connection refers to connection that can be regarded as the same circuit diagram when represented by an equivalent circuit.

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Furthermore, functions of a source and a drain are sometimes interchanged with each other when a transistor of different polarity is used or when the direction of a current is changed in a circuit operation, for example. Therefore, the terms “source” and “drain” can sometimes be interchanged with each other in this specification and the like.

Note that impurities in a semiconductor refer to, for example, elements other than the main components of a semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of impurities which change the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as Vo) are formed in an oxide semiconductor in some cases by entry of impurities, for example.

Note that in this specification and the like, an oxynitride is a material that contains more oxygen than nitrogen in its composition. Examples of the oxynitride include silicon oxynitride, aluminum oxynitride, and hafnium oxynitride. Moreover, a nitride oxide is a material that contains more nitrogen than oxygen in its composition. Examples of the nitride oxide include silicon nitride oxide, aluminum nitride oxide, and hafnium nitride oxide.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, when a plurality of components are denoted with the same reference numeral, and in particular need to be distinguished from each other, an identification sign such as “_1”, “[n]”, or “[m,n]” is sometimes added to the reference numeral.

Note that in this specification and the like, the expression “level with” indicates a structure having the same level from a reference surface (e.g., a flat surface such as a substrate surface) in a cross-sectional view. For example, in a manufacturing process of a memory device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as being “level with” in this specification and the like. For example, the expression “level with” also includes the case where two layers having different levels with respect to the reference surface (here, given as a first layer and a second layer) are provided to have a difference of less than or equal to 20 nm between the top-surface level of the first layer and the top-surface level of the second layer.

Note that in this specification and the like, the expression “end portions are aligned” means that at least outlines of stacked layers partly overlap with each other in a plan view (also referred to as a top view in some cases). For example, the case of processing an upper layer and a lower layer with the use of the same mask pattern or mask patterns that are partly the same is included. Note that, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

Note that it is generally difficult to clearly differentiate “perfectly aligned” from “substantially aligned”. Therefore, in this specification and the like, the expression “aligned” includes both “perfectly aligned” and “substantially aligned”.

Note that in this specification and the like, “normally-on characteristics” means a state where a channel exists without application of a voltage to a gate and a current flows through the transistor. Furthermore, “normally-off characteristics” means a state where a current does not flow through a transistor when no potential or a ground potential is applied to a gate.

In this specification and the like, leakage current sometimes expresses the same meaning as off-state current. Furthermore, in this specification and the like, the off-state current sometimes refers to current that flows between a source and a drain of a transistor in an off state, for example.

### Embodiment 1

In this embodiment, an example of a memory device, an example of a transistor, an example of a capacitor, and fabrication methods thereof, which are embodiments of the present invention, will be described.

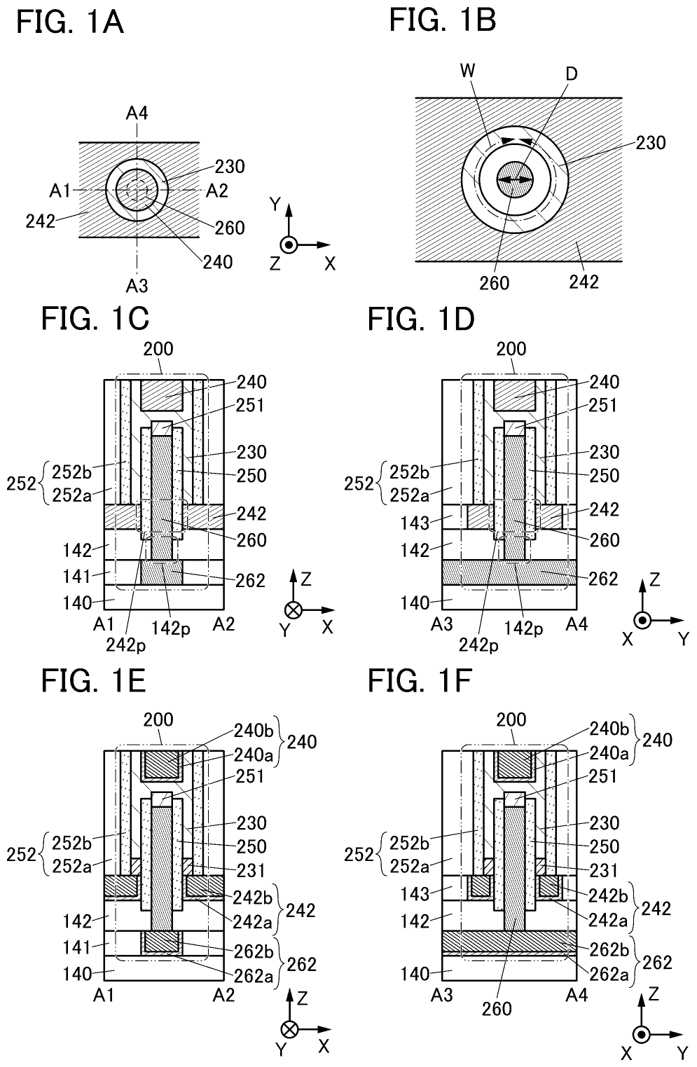

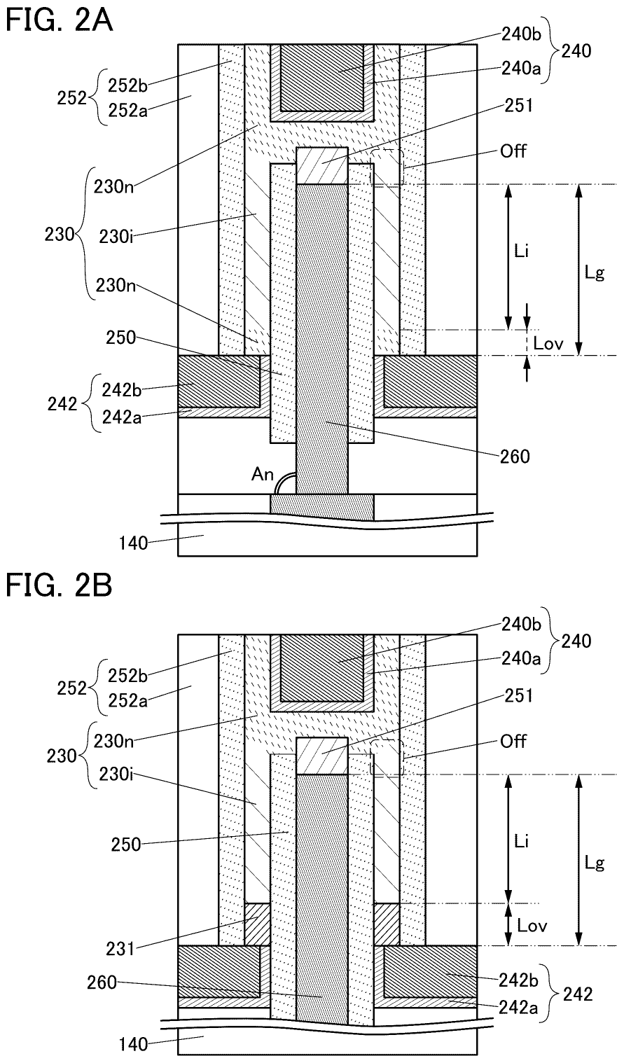

The memory device of one embodiment of the present invention includes a transistor and a capacitor. FIG. 1A to FIG. 1F illustrate structure examples each including the transistor of one embodiment of the present invention. FIG. 2A and FIG. 2B each illustrate an enlarged part of FIG. 1E. The details of a transistor 200 illustrated in FIG. 1A to FIG. 1F and the like will be described later.

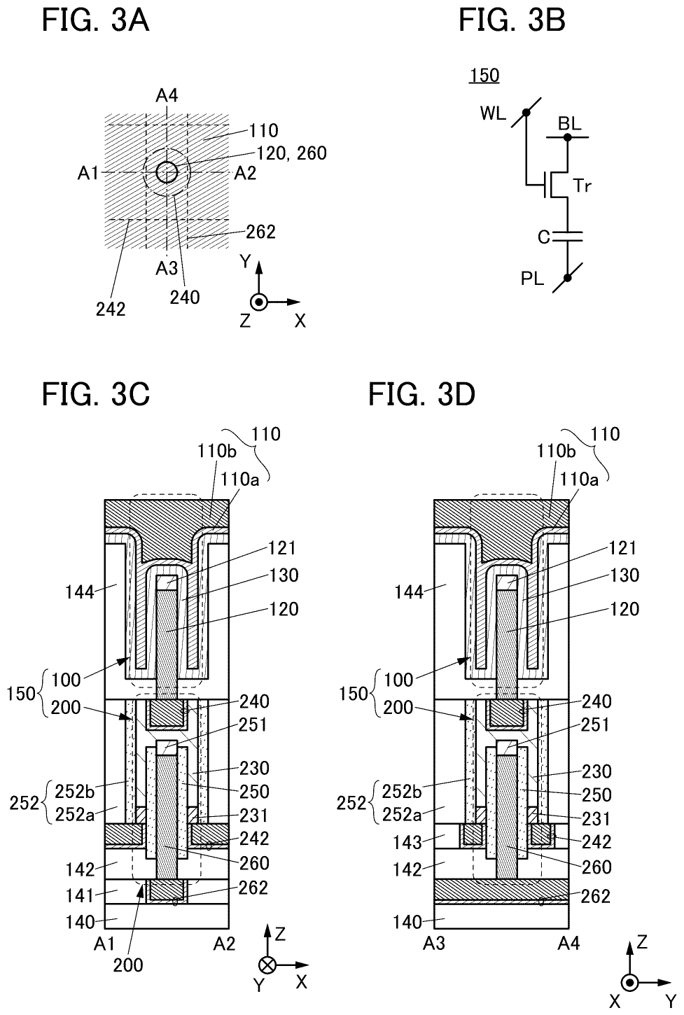

FIG. 3A, FIG. 3C, and FIG. 3D illustrate an example of a structure including the transistor 200 illustrated in FIG. 1D, FIG. 1E, and the like and the capacitor of one embodiment of the present invention.

### Structure Example of Memory Device

A structure of a memory device including a transistor and a capacitor is described with reference to FIG. 3A to FIG. 3D. The memory device of one embodiment of the present invention includes a memory cell. The memory device of one embodiment of the present invention preferably includes a plurality of memory cells arranged in a matrix.

FIG. 3A is a plan view of the memory device including the transistor 200 and a capacitor 100, FIG. 3C is a cross-sectional view of a portion indicated by the dashed-dotted line A1-A2 in FIG. 3A, and FIG. 3D is a cross-sectional view of a portion indicated by the dashed-dotted line A3-A4 in FIG. 3A. Note that in the plan view of FIG. 3A, only a conductor 240, a conductor 242, a conductor 260, and a conductor 262 are illustrated among components included in the transistor 200, and the other components are not illustrated. Note that some components (e.g., an insulator) of the capacitor 100 are also not illustrated in FIG. 3A for clarity of the drawing.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The memory device illustrated in FIG. 3A, FIG. 3C, and FIG. 3D includes an insulator 140 over a substrate (not illustrated), the transistor 200 over the insulator 140, and the capacitor 100 over the transistor 200. The capacitor 100 and the transistor 200 can be combined to form a memory cell 150.

As illustrated in FIG. 3A, FIG. 3C, and FIG. 3D, the transistor 200 is provided to overlap with the capacitor 100. At least one of the components of the transistor 200 includes a region overlapping with at least one of the components of the capacitor 100. For example, a conductor 120 preferably includes a region overlapping with the conductor 260. With such a structure, the transistor 200 and the capacitor 100 can be provided without a great increase in the occupation area in the plan view. Thus, the area occupied by the memory cell 150 can be reduced, so that the memory cells 150 can be arranged densely and the memory capacity of the memory device can be increased. In other words, the memory device can be highly integrated.

When the areas of the conductor 120 and the conductor 260 in the plan view are reduced, the memory cells 150 can be arranged densely and the capacity of the memory device can be increased. How much the areas of the conductor 120 and the conductor 260 can be reduced depends on the light-exposure apparatus resolution limit, processing conditions, deposition conditions, or the like used for fabrication of the memory device. When the area of the conductor 120 in the plan view is, for example, the minimum area that can be achieved in fabrication of the memory device, the area occupied by the capacitor 100 in the plan view is reduced. Thus, the memory cells 150 can be arranged significantly densely in some cases. Furthermore, when the area of the conductor 260 in the plan view is, for example, the minimum area that can be achieved in fabrication of the memory device, the area occupied by the transistor 200 in the plan view is reduced. Thus, the memory cells 150 can be arranged significantly densely in some cases.

In one embodiment of the present invention, the conductor 120 and the conductor 260 each include a columnar (pillar) region (also referred to as a region that is a column or has a columnar shape), for example. FIG. 3A, FIG. 3C, and FIG. 3D illustrate an example in which both the conductor 120 and the conductor 260 are columnar. In FIG. 3A, FIG. 3C, and FIG. 3D, the axes of the conductor 120 and the conductor 260 extend along the Z direction. The conductor 120 and the conductor 260 are each preferably a column whose axis extends along the Z direction, for example. Alternatively, the conductor 120 and the conductor 260 each preferably include a columnar region whose axis extends along the Z direction, for example. The top surface and the bottom surface of the column whose axis extends along the Z direction are perpendicular to the Z direction, for example. Here, the axis of a column that extends along the Z direction is, for example, a line that passes through the center of gravity of the top surface shape of the column and extends along the Z direction. In the case of a cylinder that extends along the Z direction, the center of gravity of the column is a straight line that passes through the center of the top surface circle and extends along the Z direction, for example. Note that the axis of the column extends substantially along the Z direction and may include a curve or the like. FIG. 3A illustrates an example in which the conductor 120 and the conductor 260 are cylindrical. Although FIG. 3A illustrates an example in which the conductor 120 and the conductor 260 both have circular top surface shapes and have substantially the same diameter, the conductor 120 and the conductor 260 may have different diameters. Although FIG. 3A illustrates an example in which the conductor 120 and the conductor 260 both have circular top surface shapes and have substantially identical center positions of the circles, the conductor 120 and the conductor 260 may have different center positions. The conductor 120 and the conductor 260 are each not limited to having a circular top surface shape. The top surface shape can be any of various shapes such as an ellipse, a polygon, and a figure formed of a curve and a straight line. For example, in the case where the conductor is a polygonal prism, the top surface shape is a polygonal shape. Note that the polygonal prism here includes a triangular prism and a quadrangular prism. In the case where the width of the column is 1 in each of the conductor 120 and the conductor 260, the height of the column is preferably larger than 1, for example. Note that the width of the column is, for example, the diameter of a circle corresponding to an area converted and calculated from the area of the top surface. Alternatively, for example, the width of the column is measured at a position where the width of a cross section of the column is the largest.

Alternatively, in one embodiment of the present invention, the conductor 120 and the conductor 260 may each include a conical or pyramidal region (also referred to as a region that is a cone or a pyramid or has a conical or pyramidal shape). A cone or a pyramid, or the conductor 120 and the conductor 260 in one embodiment of the present invention, may include a region that is a cone or a pyramid or a region that is a conical or pyramidal solid, for example.

Here, in this specification and the like, a top surface shape of a component means the contour shape of the component in a plan view. A plan view means that the component is observed from a normal direction of a surface where the component is formed or from a normal direction of a surface of a support (e.g., a substrate) where the component is formed.

FIG. 3B is a circuit diagram related to the memory device described in this embodiment. The memory cell 150 includes a transistor Tr and a capacitor C. Here, the transistor Tr corresponds to the transistor 200 illustrated in FIG. 3A, FIG. 3B, FIG. 3D, and the like, and the capacitor C corresponds to the capacitor 100 illustrated in FIG. 3A, FIG. 3B, FIG. 3D, and the like. That is, the structure illustrated in FIG. 3A, FIG. 3C, and FIG. 3D functions as a memory cell of the memory device.

One of a source and a drain of the transistor Tr is connected to one of a pair of electrodes of the capacitor C. The other of the source and the drain of the transistor Tr is connected to a wiring BL. A gate of the transistor Tr is connected to a wiring WL. The other of the pair of electrodes of the capacitor C is connected to a wiring PL.

Here, the wiring BL corresponds to the conductor 242, the wiring WL corresponds to the conductor 262, and the wiring PL corresponds to a conductor 110. As illustrated in FIG. 3A, FIG. 3C, and FIG. 3D, it is preferable that the conductor 262 be provided to extend in the Y direction and the conductor 242 be provided to extend in the X direction. In this structure, the wiring BL and the wiring WL are provided to intersect with each other. Although the wiring PL (the conductor 110) is provided in a plane shape in FIG. 3A, the present invention is not limited thereto. For example, the wiring PL may be provided parallel to the wiring WL (the conductor 260) or may be provided parallel to the wiring BL (the conductor 240).

### [Transistor 200]

FIG. 1A is a plan view of the transistor 200, and FIG. 1B is an enlarged view illustrating part of the structure illustrated in FIG. 1A. FIG. 1C is a cross-sectional view of a portion indicated by the dashed-dotted line A1-A2 in FIG. 1A, and FIG. 1D is a cross-sectional view of a portion indicated by the dashed-dotted line A3-A4 in FIG. 1A. Note that in the plan view of FIG. 1A and the like, only the conductor 240, the conductor 242, the conductor 260, and the conductor 262 are illustrated among the components included in the transistor 200, and the other components are not illustrated.

As illustrated in FIG. 1A to FIG. 1D, the transistor 200 includes the conductor 260, an oxide semiconductor 230, the conductor 242, the conductor 240, and an insulator 250. The conductor 260 functions as a gate electrode of the transistor 200. The oxide semiconductor 230 functions as a channel formation region of the transistor 200. The conductor 240 functions as one of a source electrode and a drain electrode of the transistor 200, and the conductor 242 functions as the other of the source electrode and the drain electrode of the transistor 200. The insulator 250 functions as a gate insulator of the transistor 200.

The conductor 260 includes a columnar region, for example. In the example of the structure illustrated in FIG. 1A to FIG. 1D, the conductor 260 has a cylindrical shape. The oxide semiconductor 230 includes a region placed to face the side surface of the conductor 260. The insulator 250 preferably includes a region in contact with the side surface of the conductor 260, and the region is interposed between the conductor 260 and the oxide semiconductor 230, for example. The oxide semiconductor 230 is placed to surround the conductor 260 with the insulator 250 therebetween. In the structure illustrated in FIG. 1A to FIG. 1D, the insulator 250 includes a tubular region, and the region surrounds the conductor 260. For example, the insulator 250 can be expressed as being placed to surround the outer side of the columnar region included in the conductor 260. Here, the insulator 250 is placed outside the conductor 260 in a top view, for example. In the structure illustrated in FIG. 1A to FIG. 1D, the oxide semiconductor 230 includes a tubular region, and the region surrounds the conductor 260. For example, the oxide semiconductor 230 can be expressed as being placed to surround the outer side of the columnar region included in the conductor 260. Here, the oxide semiconductor 230 is placed outside the conductor 260 in the top view illustrated in FIG. 1A, for example. In the top view illustrated in FIG. 1A, the conductor 260 is surrounded by the oxide semiconductor 230. In FIG. 1A to FIG. 1D, the oxide semiconductor 230 can be expressed as having a hollow cylindrical shape. Here, a hollow cylinder refers to a structure in which a first cylinder is cut out with a second cylinder, the first cylinder and the second cylinder have the same center, and the second cylinder has a smaller diameter than the first cylinder. The conductor 260 can also be expressed as being placed in a hollow portion in a region having the hollow cylindrical shape of the oxide semiconductor 230. Here, a tubular structure has a structure in which a first column is cut out with a second column, for example. The first column and the second column may have the same axis or different axes.

Here, when seen from above, the column preferably has substantially the same shape at different levels, e.g., the upper portion, the intermediate portion, and the lower portion. However, the column may have different shapes of the top surface (e.g., a cross section seen from the Z direction) depending on the level in the column. For example, the shape may be bulged such that the area seen from above increases toward the intermediate portion and the area decreases toward the upper base. The column may have an uneven side surface.

The insulator 140 is placed over the substrate (not illustrated), and an insulator 141 and the conductor 262 are placed over the insulator 140. The conductor 262 is provided to fill an opening included in the insulator 141, for example. The conductor 260 is placed over the conductor 262. The conductor 260 is preferably provided in contact with the top surface of the conductor 262. As the insulator 140, a single layer or stacked layers of any of the insulators described in the section [Insulator] below can be used.

An insulator 142 is placed over the conductor 262 and the insulator 141, and the conductor 242 and an insulator 143 are placed over the insulator 142. The conductor 242 is provided to fill an opening 142p included in the insulator 143, for example. The conductor 260 includes a region placed in the opening 142p included in the insulator 142, a region placed in an opening 242p included in the conductor 242, and a region surrounded by the oxide semiconductor 230. The conductor 260 can be expressed as penetrating the opening 242p included in the conductor 242.

The insulator 250 includes a region interposed between the conductor 260 and the conductor 242. The conductor 260 and the conductor 242 are preferably electrically insulated from each other by the insulator 250.

Note that the insulator 142 and the insulator 250 may be formed using the same material and may be a continuous layer.

As the insulator 250, a single layer or stacked layers of any of the insulators described in the section [Insulator] below can be used. For the insulator 250, silicon oxide or silicon oxynitride can be used, for example. Silicon oxide and silicon oxynitride are preferable because of being thermally stable.

As the insulator 250, any of the materials with high dielectric constants, that is, high-k materials, described in the section [Insulator] below may be used. For example, hafnium oxide, aluminum oxide, or the like may be used.

The thickness of the insulator 250 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 250 has a region with the above-described thickness.

The concentration of impurities such as water and hydrogen in the insulator 250 is preferably reduced. This can inhibit entry of impurities such as water and hydrogen into the channel formation region of the oxide semiconductor 230.

As the conductor 260, a single layer or stacked layers of any of the conductors described in the section [Conductor] below can be used. For example, a conductive material with high conductivity such as tungsten can be used for the conductor 260.

In addition, a conductive material that is less likely to be oxidized, a conductive material having a function of inhibiting diffusion of oxygen, or the like is preferably used for the conductor 260. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 260.

The conductor 242 includes a region in contact with the oxide semiconductor 230 and thus is preferably formed using any of the conductive materials containing oxygen described in the section [Conductor] below. When a conductive material containing oxygen is used for the conductor 242, the conductor 242 can maintain its conductivity even when absorbing oxygen from the oxide semiconductor 230. As the conductor 242, a single layer or stacked layers of indium tin oxide (also referred to as ITO), indium tin oxide to which silicon is added (also referred to as ITSO), indium zinc oxide (IZO (registered trademark)), or the like can be used, for example.

Since the oxide semiconductor 230 and the conductor 242 are in contact with each other, a metal compound or oxygen vacancies are formed, so that the resistance of the region that is of the oxide semiconductor 230 and is in contact with the conductor 242 and its peripheral region is reduced. The reduction in the resistance of the oxide semiconductor 230 in contact with the conductor 242 can reduce the contact resistance between the oxide semiconductor 230 and the conductor 242.

Although FIG. 1A to FIG. 1D illustrate the example where the conductor 260 has a cylindrical shape, the conductor 260 can have any of various columnar shapes such as an elliptical cylinder and a polygonal prism.

The shape of the region included in the conductor 260 is not limited to the column. For example, the conductor 260 may include a region of a conical or pyramidal shape (sometimes referred to as a region that is a cone or a pyramid or a region that is a conical or pyramidal solid), such as a cone, an elliptical cone, or a polygonal pyramid. The conductor 260 may have, for example, the shape of a cone or a pyramid or a column whose bottom surface is in the shape of a polygon, such as a quadrangle, with rounded corners.

When seen from above, a conical or pyramidal shape has a large area at the bottom surface (here, a surface close to the top surface of the conductor 262), and has a gradually decreasing area toward the upper end. The conical or pyramidal shape may have an uneven side surface. The conductor 260 may have a needle-like shape. Here, the needle-like shape refers to a shape that becomes thinner toward the tip (toward the upper end). Note that the tip of the needle-like shape may have an acute angle or a downwardly convex curved shape. Note that a needle-like shape whose tip has an acute angle may be referred to as a V shape.

The oxide semiconductor 230 is placed over the conductor 242. The conductor 240 is placed over the oxide semiconductor 230. The oxide semiconductor 230 preferably includes a region in contact with the top surface of the conductor 242. The conductor 240 preferably includes a region in contact with the top surface of the oxide semiconductor 230.

FIG. 1A illustrates an example in which the conductor 240 has a circular shape when seen from above. Note that the shape of the conductor 240 when seen from above is not limited to a circle and may be an ellipse, a polygon, or the like. The conductor 240 may extend in the X direction or the Y direction, for example.

As the conductor 240, a single layer or stacked layers of any of the conductors described in the section [Conductor] below can be used. A conductive material that is less likely to be oxidized, a conductive material having a function of inhibiting diffusion of oxygen, or the like is preferably used for the conductor 240. For example, titanium nitride, tantalum nitride, or the like can be used. For example, a structure in which tantalum nitride is stacked over titanium nitride may be used. In that case, titanium nitride is in contact with a component provided over the transistor 200 (e.g., the conductor 120 and an insulator 144 described later), and tantalum nitride is in contact with the oxide semiconductor 230. Such a structure can inhibit excessive oxidation of the conductor 120 due to the oxide semiconductor 230. In the case where an oxide insulator is used as the insulator 144 or the like provided over the transistor 200, excessive oxidation of the conductor 240 due to the insulator 144 or the like can be inhibited. Alternatively, a structure in which tungsten is stacked over titanium nitride may be used for the conductor 240, for example.

The conductor 240 includes a region in contact with the oxide semiconductor 230 and thus is preferably formed using any of the conductive materials containing oxygen described in the section [Conductor] below. When a conductive material containing oxygen is used for the conductor 240, the conductor 240 can maintain its conductivity even when absorbing oxygen. As the conductor 240, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

Since the oxide semiconductor 230 and the conductor 240 are in contact with each other, a metal compound or oxygen vacancies are formed, so that the resistance of the region that is of the oxide semiconductor 230 and is in contact with the conductor 240 and its peripheral region is reduced. The reduction in the resistance of the oxide semiconductor 230 that is in contact with the conductor 240 can reduce the contact resistance between the oxide semiconductor 230 and the conductor 240.

As the conductor 262, a single layer or stacked layers of any of the conductors described in the section [Conductor] below can be used.

In the transistor 200, an insulator 251 is placed between the conductor 260 and the conductor 240. When the insulator 251 is provided, an offset region can be provided in the oxide semiconductor 230, for example. Here, the offset region refers to a region in the oxide semiconductor 230 where a gate electric field is less likely to be applied. For example, a region in the oxide semiconductor 230 in FIG. 1C and FIG. 1D that is at a higher level than the conductor 260 can be an offset region. Alternatively, a region in the oxide semiconductor 230 that has a hollow cylindrical shape and is at a higher level than the conductor 260 can be an offset region.

The insulator 251 has a function of inhibiting electrical leakage between the conductor 240 and the conductor 260. The insulator 251 sometimes functions as a protective layer that inhibits etching of the conductor 260 in the step of forming the oxide semiconductor 230, the conductor 240, or the like.

As the insulator 251, any of the insulators described in the section [Insulator] below can be used. In particular, silicon nitride or silicon nitride oxide can be suitably used. For the insulator 251, hafnium oxide, aluminum oxide, zirconium oxide, magnesium oxide, or the like may be used.

An insulator 252 is placed outside the oxide semiconductor 230. The insulator 252 is preferably provided in contact with the outer side surface of the oxide semiconductor 230.

FIG. 1C and FIG. 1D illustrate an example in which the insulator 252 has a stacked-layer structure of an insulator 252a and an insulator 252b. The insulator 252b can be formed using the same material as the insulator 250, for example. For the insulator 252a, any of the materials with low dielectric constants described in the section [Insulator] below can be used, for example.

Alternatively, the insulator 252 may have a single-layer structure instead of a stacked-layer structure. For example, the transistor 200 may have a structure in which the insulator 252a or the insulator 252b is not provided.

In FIG. 1C and FIG. 1D, the oxide semiconductor 230 includes a region covering the side surface of the conductor 240. The oxide semiconductor 230 preferably includes a region in contact with the side surface of the conductor 240. The insulator 252b includes a region covering the side surface of the conductor 240 with the oxide semiconductor 230 therebetween. When the oxide semiconductor 230 includes the region in contact with the side surface of the conductor 240, the contact area between the oxide semiconductor 230 and the conductor 240 can be increased and the contact resistance can be reduced, for example. Note that the oxide semiconductor 230 does not necessarily cover the side surface of the conductor 240; in such a case, the insulator 252b or the insulator 252a is in contact with the side surface of the conductor 240, for example.

Note that the oxide semiconductor 230 includes, for example, a first region of a tubular shape and a second region of a tubular shape; the first region surrounds the conductor 260 and the second region surrounds the conductor 240.

As an insulator placed in the vicinity of the channel formation region, an insulator containing oxygen that is released by heating (hereinafter sometimes referred to as excess oxygen) is preferably used. By performing heat treatment on the insulator containing excess oxygen, oxygen can be supplied from the insulator to the channel formation region of the oxide semiconductor 230 and oxygen vacancies and VoH can be reduced. Thus, the transistor 200 can have stable electrical characteristics and increased reliability.

A structure illustrated in FIG. 1E and FIG. 1F is different from the structure illustrated in FIG. 1C and FIG. 1D in including a metal oxide 231 between the oxide semiconductor 230 and the conductor 242.

In the example of the structure illustrated in FIG. 1E and FIG. 1F, the conductor 262 has a stacked-layer structure of a conductor 262a and a conductor 262b, the conductor 242 has a stacked-layer structure of a conductor 242a and a conductor 242b, and the conductor 240 has a stacked-layer structure of a conductor 240a and a conductor 240b. Note that in other structure examples in FIG. 1C, FIG. 1D, and the like, the conductor 262, the conductor 242, and the conductor 240 may each have a stacked-layer structure.

The section [Conductor] below can be referred to for materials and the like that can be used for the conductor 262a, the conductor 262b, the conductor 242a, the conductor 242b, the conductor 240a, and the conductor 240b.

The metal oxide 231 preferably has a lower resistance than the oxide semiconductor 230. The metal oxide 231 has a higher resistance than the conductor 242, for example.

The metal oxide 231 has a lower resistance than the oxide semiconductor 230, and the metal oxide 231 does not serve as a channel formation region, for example. Thus, the transistor 200 illustrated in FIG. 1E and FIG. 1F has a shorter effective channel length than the transistor 200 illustrated in FIG. 1C and FIG. 1D, for example.

In the case where the transistor 200 is an n-channel transistor and the conductor 242 functions as a drain electrode, owing to the metal oxide 231, a high electric field is not easily generated in the vicinity of a drain region, and generation of hot carriers and degradation of the transistor can be inhibited.

A material capable of making ohmic contact with the conductor 242 is preferably used for the metal oxide 231. Accordingly, the contact resistance between the metal oxide 231 and the conductor 242 can be reduced, and the on-state current of the transistor 200 can be increased in some cases as compared with the structure in which the oxide semiconductor 230 and the conductor 242 are in contact with each other.

The transistor 200 illustrated in FIG. 1E and FIG. 1F includes the conductor 260, the oxide semiconductor 230, the metal oxide 231, the conductor 242, the conductor 240, and the insulator 250. The oxide semiconductor 230 includes a region placed to face the side surface of the conductor 260 with the insulator 250 therebetween. The metal oxide 231 includes a region placed to face the side surface of the conductor 260 with the insulator 250 therebetween. The insulator 250 includes a region interposed between the conductor 260 and the oxide semiconductor 230 and a region interposed between the conductor 260 and the metal oxide 231. The metal oxide 231 is placed between the oxide semiconductor 230 and the conductor 242. The metal oxide 231 is preferably in contact with the top surface of the conductor 242. The metal oxide 231 is preferably in contact with the oxide semiconductor 230. Note that the metal oxide 231 and the oxide semiconductor 230 are sometimes observed as a continuous film.

The metal oxide 231 and the oxide semiconductor 230 preferably contain a common metal element. As the metal oxide 231, one of the materials given as examples of the oxide semiconductor 230 or a combination thereof can be used, for example. For the metal oxide 231, the section [Metal oxide] below can be referred to, for example. In particular, indium tin oxide, indium tin oxide containing silicon, zinc oxide, tin oxide, titanium oxide, zinc oxide containing gallium, zinc oxide containing aluminum, or the like can be suitably used. Here, in indium tin oxide containing silicon, for example, the number of silicon atoms is preferably greater than or equal to 2 and less than or equal to 25 when the number of indium atoms is 100.

Materials that can be used for the metal oxide 231 are not limited to metal oxides. For example, graphene, a graphene compound, or the like may be used. Graphene, a graphene compound, or the like can also be used in combination with a metal oxide.

The metal oxide 231 is placed to surround the conductor 260 with the insulator 250 therebetween.

Note that an ALD method or a sputtering method can be suitably used to form the metal oxide 231. The details of methods for forming the metal oxide 231 will be described later.

The channel length of the transistor 200 depends on the distance between a source region and a drain region. The channel length of the transistor 200 is, for example, the length of a region where a channel is formed in the oxide semiconductor 230. The region where the channel is formed in the oxide semiconductor 230 is, for example, a region of the oxide semiconductor 230 that faces the conductor 260.

In the oxide semiconductor 230, the offset region is not included in the channel formation region, for example.

FIG. 2A illustrates an enlarged view of part of FIG. 1C. FIG. 2A illustrates an example of regions 230n that are low-resistance regions of the oxide semiconductor 230 and a region 230i that is an i-type region.

The channel length of the transistor 200 can be, for example, a region overlapping with a gate electrode, i.e., the conductor 260 here, in the oxide semiconductor 230 positioned between the conductor 242 and the conductor 240. Thus, as illustrated in FIG. 2A, a channel length Lg of the transistor 200 can be expressed as the length of a region of the oxide semiconductor 230 that overlaps with the conductor 260, for example.

The length of the region 230i in the region of the oxide semiconductor 230 that overlaps with the conductor 260 is referred to as a length Li. For example, the length Li can be regarded as the effective channel length of the transistor 200.

In FIG. 2A, a region Off can be expressed as, for example, a region of the region 230i that does not overlap with the conductor 260. The region Off can be expressed as an offset region. Note that the area of the region Off changes depending on the amount of oxygen or hydrogen diffused from an insulator to the oxide semiconductor 230. For example, in the case where the amount of hydrogen diffused from the insulator 251 is large, the region Off is decreased in area in some cases.

FIG. 2B illustrates an enlarged view of part of FIG. 1E.

In FIG. 2B, the channel length of the transistor 200 can be, for example, a region overlapping with a gate electrode, i.e., the conductor 260 here, in the oxide semiconductor 230 and the metal oxide 231 positioned between the conductor 242 and the conductor 240. Thus, as illustrated in FIG. 2B, the channel length Lg of the transistor 200 can be expressed as the sum of a length Li that is the length of a region of the oxide semiconductor 230 that overlaps with the conductor 260 and a length Lov that is the length of a region of the metal oxide 231 that overlaps with the conductor 260, for example.

The metal oxide 231 preferably has a lower resistance than the oxide semiconductor 230. In the case where the metal oxide 231 has a lower resistance than the oxide semiconductor 230, the metal oxide 231 is not included in the channel formation region in some cases. In such a case, for example, the length of the region of the oxide semiconductor 230 that overlaps with the conductor 260, i.e., the length Li, can be regarded as the effective channel length of the transistor 200.

Note that the regions 230n and the region 230i illustrated in FIG. 2A and FIG. 2B are examples, and the regions change depending on the amount of hydrogen diffused from an insulator, a conductor, or the like in the vicinity of the oxide semiconductor 230, the amount of oxygen diffused from an insulator, or the like. In the case where the amount of hydrogen diffused from the insulator 251 is large, the oxide semiconductor 230 in the vicinity of the insulator 251 is likely to be a low-resistance region; in the case where the amount of hydrogen diffused is small or the amount of oxygen diffused is large, the oxide semiconductor 230 in the vicinity of the insulator 251 may be an i-type region, for example.

The channel length of the transistor 200 changes depending on the distance between the conductor 242 and the conductor 240, for example. The distance between the conductor 242 and the conductor 240 changes depending on the height of the insulator 252 positioned between the two conductors, for example.

The channel length of a conventional transistor is set by the light exposure limit of photolithography, whereas the channel length in the present invention can be set by, for example, the height of the conductor 240, the height of the insulator 252, the distance between the top surface of the conductor 242 and the bottom surface of the conductor 240, or the like. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200 can have higher on-state current and improved frequency characteristics. Accordingly, the read speed and the write speed of the memory cell 150 can be increased, whereby a memory device with a high operation speed can be provided.

The oxide semiconductor 230, the insulator 250, and the conductor 260 are provided concentrically. Therefore, the side surface of the conductor 260 provided at the center faces the side surface of the oxide semiconductor 230 with the insulator 250 therebetween. In other words, in the plan view, all the perimeter of the oxide semiconductor 230 serves as the channel formation region. In this case, for example, the channel width of the transistor 200 is determined by the length of the outer perimeter of the oxide semiconductor 230. In other words, the channel width W of the transistor 200 is determined by the maximum diameter D of the conductor 260 (the maximum diameter in the case where the conductor 260 is circular in the plan view) and the thickness of the insulator 250. By increasing the maximum diameter D of the conductor 260, for example, the channel width per unit area can be increased and the on-state current can be increased.

In the case where the conductor 260 is formed by a photolithography method, the maximum diameter D of the conductor 260 is set by the light exposure limit of photolithography. The maximum diameter D of the conductor 260 is preferably, for example, greater than or equal to 0.5 nm, greater than or equal to 3 nm, or greater than or equal to 10 nm and less than or equal to 45 nm, less than or equal to 20 nm, less than or equal to 10 nm, less than or equal to 5 nm, or less than or equal to 3 nm. In the case where the conductor 260 is circular in the plan view, the maximum diameter D of the conductor 260 corresponds to the diameter of the conductor 260, and the channel width W can be calculated as “D×”.

In the case where the conductor 260 is formed to be circular in a plan view, the oxide semiconductor 230, the insulator 250, and the conductor 260 are formed concentrically. This makes the distance between the conductor 260 and the oxide semiconductor 230 substantially uniform, so that a gate electric field can be substantially uniformly applied to the oxide semiconductor 230.

It is preferable that the channel formation region of the transistor in which an oxide semiconductor is used for the semiconductor layer include fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen has entered (hereinafter sometimes referred to as VoH), which generates an electron serving as a carrier. Therefore, it is preferable that VoH be also decreased in the channel formation region. Thus, the channel formation region of the transistor is a high-resistance region having a low carrier concentration. Thus, the channel formation region of the transistor can be regarded as being i-type (intrinsic) or substantially i-type.

Meanwhile, the source region and the drain region of the transistor in which an oxide semiconductor is used for the semiconductor layer include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

In the case where the conductor 260 includes the columnar region, the sidewall thereof is preferably perpendicular to the top surface of the substrate over which the memory cell 150 is provided. The perpendicular sidewall can reduce the area occupied by the conductor 260 and enables high integration of a circuit using the transistor 200.

Alternatively, the sidewall of the conductor 260 can have a tapered shape. In the case where the conductor 260 includes a conical or pyramidal region, the sidewall of the conductor 260 has a tapered shape, for example. When the sidewall of the conductor 260 has a tapered shape, coverage of the conductor 260 with the insulator 250 and coverage of the insulator 250 with the oxide semiconductor 230 can be improved, for example. Increasing the coverage improves the thickness uniformity of a layer to be formed. Furthermore, defects such as voids in a layer to be formed can be reduced.

For example, in the case where the conductor 260 includes the columnar region, an angle An formed by the side surface of the conductor 260 and the top surface of the conductor 262 or the top surface of the insulator 142 is preferably 90° or close to 90°. For example, the angle An is preferably 90° and preferably greater than or equal to 85° and less than or equal to 95°. Alternatively, the angle An is greater than or equal to 70° and less than 85°, for example.

In the case where the angle An is greater than 90°, the shape of the conductor 260 is sometimes referred to as a tapered shape, and in the case where the angle An is less than 90°, the shape of the conductor 260 is sometimes referred to as an inverse tapered shape.

The band gap of the metal oxide used for the oxide semiconductor 230 is preferably greater than or equal to 2 eV, for example. In particular, the band gap of the oxide semiconductor serving as the channel formation region is preferably greater than or equal to 2 eV, further preferably greater than or equal to 2.5 eV. With the use of a metal oxide having a wide band gap for the oxide semiconductor 230, the off-state current of the transistor can be reduced. When a transistor with a low off-state current is used in a memory cell, stored content can be retained for a long time. In other words, such a memory device does not require refresh operation or has extremely low frequency of the refresh operation, which leads to a sufficient reduction in power consumption of the memory device. Note that the frequency of refresh operation in a general DRAM needs to be approximately once per 60 msec, whereas the frequency of refresh operation in the memory device of one embodiment of the present invention can be approximately once per 10 sec, which is greater than or equal to 10 times or greater than or equal to 100 times that of the general DRAM. In the memory device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 230, a single layer or stacked layers of any of the metal oxides described in the section [Metal oxide] below can be used.

As the oxide semiconductor 230, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof is specifically used. Note that a composition in the neighborhood includes the range of +30% of an intended atomic ratio. Gallium is preferably used as the element M.

When the metal oxide is deposited by a sputtering method, the above atomic ratio is not limited to the atomic ratio of the metal oxide deposited and may be the atomic ratio of a sputtering target used for depositing the metal oxide.

For analysis of the composition of the metal oxide used for the oxide semiconductor 230, for example, energy dispersive X-ray spectroscopy (EDX: Energy Dispersive X-ray Spectrometry), X-ray photoelectron spectroscopy (XPS: X-ray Photoelectron Spectrometry), inductively coupled plasma-mass spectrometry (ICP-MS), or inductively coupled plasma-atomic emission spectroscopy (ICP-AES: Inductively Coupled Plasma-Atomic Emission Spectrometry) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an atomic layer deposition (ALD) method can be suitably used to form the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 230, the CAAC-OS or the nc-OS is preferably used, and the CAAC-OS is particularly preferably used.

CAAC-OS preferably includes a plurality of layered crystal regions and a c-axis is preferably aligned in a normal direction of a surface where the CAAC-OS is formed. For example, the oxide semiconductor 230 preferably includes a layered crystal that is substantially parallel to the sidewall of the insulator 250. With this structure, the layered crystals of the oxide semiconductor 230 are formed substantially parallel to the channel length direction of the transistor 200, so that the on-state current of the transistor can be increased.

The CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor 200 is stable with respect to high temperatures in a manufacturing process (what is called thermal budget).

The crystallinity of the oxide semiconductor 230 can be analyzed with X-ray diffraction (XRD), a transmission electron microscope (TEM), or electron diffraction (ED), for example. Alternatively, such kinds of analysis methods may be performed in combination.

Although the oxide semiconductor 230 being a single layer is illustrated in FIG. 1C and FIG. 1D, the present invention is not limited thereto. The oxide semiconductor 230 may have a stacked-layer structure of a plurality of oxide layers with different chemical compositions. For example, a structure in which a plurality of kinds of metal oxides selected from the above-described metal oxides are stacked as appropriate may be used. Similarly, the metal oxide 231 may have a stacked-layer structure.

Note that the composition of the metal oxide used for the oxide semiconductor 230, the metal oxide 231, or the like may be continuously changed. For example, in the case where a metal oxide is formed by an ALD method, the composition can be changed with the number of times of forming a layer containing a metal element, the formation time, or the like. Thus, the composition may be changed such that the band gap decreases toward the source electrode or the drain electrode, for example.

The conductivity of a material used for the metal oxide 231 is preferably different from the conductivity of a material used for the oxide semiconductor 230.

The metal oxide 231 can be formed using a material having a higher conductivity than the oxide semiconductor 230, for example. When a material having high conductivity is used for the metal oxide 231 that is in contact with the conductor 242 functioning as the source electrode or the drain electrode, the contact resistance between the metal oxide 231 and the conductor 242 can be reduced, so that the transistor can have a high on-state current.

Furthermore, the carrier concentration of the metal oxide 231 is preferably higher than the carrier concentration of the oxide semiconductor 230. When the carrier concentration of the metal oxide 231 is increased, the conductivity is increased and the contact resistance between the metal oxide 231 and the conductor 242 can be reduced, so that the transistor can have a high on-state current. When the carrier concentration of the oxide semiconductor 230 is reduced, the conductivity is reduced, so that the transistor can have normally-off characteristics.

The band gap of a first metal oxide used for the metal oxide 231 and the band gap of a second metal oxide used for the oxide semiconductor 230 are preferably different from each other. For example, a difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the metal oxide 231 can be smaller than the band gap of the second metal oxide used for the oxide semiconductor 230. Thus, the contact resistance between the metal oxide 231 and the conductor 242 can be reduced, so that the transistor can have a high on-state current. Furthermore, the transistor 200 can have high threshold voltage in the case where the transistor 200 is an n-channel transistor, and the transistor 200 can be a normally-off transistor.

Although an example in which the band gap of the first metal oxide is smaller than the band gap of the second metal oxide is described here, one embodiment of the present invention is not limited thereto. The band gap of the first metal oxide can be larger than the band gap of the second metal oxide in some cases.

As described above, the band gap of the first metal oxide can be smaller than the band gap of the second metal oxide. The composition of the first metal oxide is preferably different from the composition of the second metal oxide. When the compositions of the first metal oxide and the second metal oxide are different from each other, the band gap can be controlled. For example, the content percentage of the element M in the first metal oxide is preferably lower than the content percentage of the element M in the second metal oxide. Specifically, in the case where the first metal oxide and the second metal oxide are each an In-M-Zn oxide, the first metal oxide can have a composition of In:M:Zn=1:1:1 [atomic ratio] or in the neighborhood thereof, and the second metal oxide can have a composition of In:M:Zn=1:3:2 [atomic ratio] or in the neighborhood thereof. It is particularly preferable to use one or more of gallium, aluminum, and tin as the element M.

The first metal oxide may have a composition not including the element M. For example, the first metal oxide can be an In—Zn oxide, and the second metal oxide can be an In-M-Zn oxide. Specifically, the first metal oxide can be an In—Zn oxide, and the second metal oxide can be an In—Ga—Zn oxide. More specifically, the first metal oxide can have a composition of In:Zn=1:1 [atomic ratio] or in the neighborhood thereof or a composition of In:Zn=4:1 [atomic ratio] or in the neighborhood thereof, and the second metal oxide can have a composition of In:Ga:Zn=1:1:1 [atomic ratio] or in the neighborhood thereof.

Although an example in which the content percentage of the element M in the first metal oxide is lower than the content percentage of the element M in the second metal oxide is described here, one embodiment of the present invention is not limited thereto. The content percentage of the element M in the first metal oxide is sometimes higher than the content percentage of the element M in the second metal oxide. Note that as long as the compositions of the first metal oxide and the second metal oxide are different from each other, the content percentages of elements other than the element M may be different from each other.

The thickness of each of the oxide semiconductor 230 and the metal oxide 231 is preferably greater than or equal to 0.5 nm, greater than or equal to 1 nm, or greater than or equal to 3 nm and less than or equal to 20 nm, less than or equal to 10 nm, less than or equal to 8 nm, or less than or equal to 5 nm. Here, the thickness of each of the oxide semiconductor 230 and the metal oxide 231 is, for example, the thickness with the side surface of the insulator 250 regarded as a formation surface.

An insulator containing oxygen can be used as at least one of the insulator 252a and the insulator 252b. When the content of oxygen in at least one of the insulator 252a and the insulator 252b is increased, an i-type region can be easily formed in or near a region of the oxide semiconductor 230 that is in contact with the insulator 252.

A film from which oxygen is released by heating is further preferably used as at least one of the insulator 252a and the insulator 252b. When oxygen is released from the insulator 252a or the insulator 252b by heat during the fabrication process of the transistor 200, the oxygen can be supplied to the oxide semiconductor 230. Supply of oxygen from the insulator 252 to the oxide semiconductor 230, particularly to the channel formation region of the oxide semiconductor 230, can reduce oxygen vacancies and VoH in the oxide semiconductor 230, so that the transistor can have favorable electrical characteristics and high reliability.

For example, the insulator 252a or the insulator 252b can be supplied with oxygen when heat treatment in an oxygen-containing atmosphere or plasma treatment in an oxygen-containing atmosphere is performed. Alternatively, an oxide film may be deposited over the top surface of the insulator 252a or the insulator 252b by a sputtering method in an oxygen atmosphere to supply oxygen. After that, the oxide film may be removed.

The insulator 252a and the insulator 252b are preferably formed by a deposition method such as a sputtering method or a plasma-enhanced chemical vapor deposition (PECVD) method. In particular, by a sputtering method as a deposition method that does not use a hydrogen gas for a deposition gas, a film with an extremely low hydrogen content can be formed. In that case, supply of hydrogen to the oxide semiconductor 230 can be inhibited and the electrical characteristics of the transistor 200 can be stabilized.

Particularly in the case where the channel length of the transistor 200 is short, oxygen vacancies and VoH in the channel formation region greatly affect electrical characteristics and reliability. Supply of oxygen from the insulator 252a or the insulator 252b to the oxide semiconductor 230 can inhibit an increase in oxygen vacancies and VoH at least in or near a region of the oxide semiconductor 230 that is in contact with the insulator 252a or the insulator 252b. Thus, the transistor with a small channel length can have favorable electrical characteristics and high reliability.

As at least one of the insulator 252a and the insulator 252b, any of the insulators having a function of capturing or fixing hydrogen described in the section [Insulator] below may be used. With this structure, hydrogen in the oxide semiconductor 230 can be captured or fixed, so that the concentration of hydrogen in the oxide semiconductor 230 can be reduced. As the insulator having a function of capturing or fixing hydrogen, magnesium oxide, aluminum oxide, or the like can be used.

The insulator 252a may further have a stacked-layer structure. For example, a stacked-layer structure of an insulator from which oxygen is released and an insulator having a barrier property against oxygen can be employed. For example, the insulator having a barrier property against oxygen can be placed outside the insulator from which oxygen is released. Thus, outward diffusion of oxygen contained in the insulator from which oxygen is released can be inhibited. Thus, oxygen can be effectively supplied to the oxide semiconductor 230.

The insulator 252a may further have a stacked-layer structure. For example, a stacked-layer structure of an insulator from which oxygen is released and an insulator having a barrier property against hydrogen can be employed. For example, the insulator having a barrier property against hydrogen can be placed outside the insulator from which oxygen is released. In that case, hydrogen can be inhibited from diffusing from outside the transistor into the oxide semiconductor 230 through the insulator 252. A silicon nitride film and a silicon nitride oxide film can be suitably used because they release few impurities (e.g., water and hydrogen) and are less likely to transmit oxygen and hydrogen.

The insulator 252a may further have a stacked-layer structure. For example, a stacked-layer structure of an insulator from which oxygen is released and an insulator having a function of capturing or fixing hydrogen can be employed. For example, the insulator having a function of capturing or fixing hydrogen can be placed outside the insulator from which oxygen is released.

This can inhibit diffusion of hydrogen from outside the insulator 252 into the oxide semiconductor 230, and can also reduce the hydrogen concentration in the oxide semiconductor 230 by capturing or fixing hydrogen of the oxide semiconductor 230. As the insulator having a function of capturing or fixing hydrogen, magnesium oxide, aluminum oxide, hafnium oxide, or the like can be used. Alternatively, for example, a stacked-layer film of aluminum oxide and silicon nitride over the aluminum oxide may be used.

### [Capacitor 100]

The capacitor 100 illustrated in FIG. 3A, FIG. 3C, and FIG. 3D includes the conductor 120, an insulator 130, and the conductor 110. The conductor 120 functions as one of a pair of electrodes (sometimes referred to as a lower electrode), the conductor 110 functions as the other of the pair of electrodes (sometimes referred to as an upper electrode), and the insulator 130 functions as a dielectric. That is, the capacitor 100 forms a MIM (Metal-Insulator-Metal) capacitor.

The conductor 120 is provided over the conductor 240. The conductor 120 preferably includes a region in contact with the top surface of the conductor 240. The conductor 120 is electrically connected to the conductor 240.

The conductor 120 includes a region having a columnar shape such as a cylinder, an elliptical cylinder, or a polygonal prism, for example. The conductor 120 may include a region having a conical or pyramidal shape such as a cone, an elliptical cone, or a polygonal pyramid, for example. The conductor 120 may have, for example, the shape of a cone or a pyramid or a column whose bottom surface is in the shape of a polygon, such as a quadrangle, with rounded corners.

In the case of a trench capacitor, for example, a conductor is formed to cover an inner wall of an opening portion provided in an insulator or the like, and a dielectric is formed to cover the inner side of the conductor. At that time, when the opening diameter of the opening portion provided in the insulator or the like is small, coverage of the bottom portion, a region from the bottom portion to the sidewall, or the like of the opening is lowered in some cases. When a structure is employed in which the conductor 120 has a columnar shape or a conical or pyramidal shape and the outer side of the conductor 120 is covered with the dielectric, miniaturization can be achieved.

Note that the capacitor 100 illustrated in FIG. 3A, FIG. 3B, FIG. 3D, and the like is sometimes referred to as a pillar capacitor.

In the case where the conductor 120 includes the columnar region, the sidewall thereof is preferably perpendicular to the top surface of the substrate over which the memory cell 150 is provided. The perpendicular sidewall can reduce the area occupied by the conductor 120 and enables high integration of the memory cell. In the case where the conductor 120 includes the columnar region, an angle formed by the side surface of the conductor 120 and the top surface of the conductor 240 or the top surface of the insulator 252a is preferably greater than or equal to 60°, further preferably greater than or equal to 70°, still further preferably greater than or equal to 80°, and less than or equal to 90°.

Alternatively, the sidewall of the conductor 120 can have a tapered shape. In the case where the conductor 120 includes a conical or pyramidal region, the sidewall of the conductor 120 has a tapered shape, for example. When the sidewall of the conductor 120 has a tapered shape, coverage of the conductor 120 with the insulator 130 and coverage of the insulator 130 with the conductor 110 can be improved, for example.

As the height of the conductor 120 becomes greater, the capacitance of the capacitor 100 can become larger. Increasing the capacitance per unit area of the capacitor 100 in this manner can stabilize the reading operation of the memory device. This also allows further miniaturization or high integration of the memory device.

As the conductor 120, a single layer or stacked layers of any of the conductors described in the section [Conductor] below can be used. For example, a conductive material with high conductivity such as tungsten can be used for the conductor 120.

In addition, a conductive material that is less likely to be oxidized, a conductive material having a function of inhibiting diffusion of oxygen, or the like is preferably used for the conductor 120. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 260.

The insulator 130 is provided over the conductor 120. The insulator 130 is provided to cover the top surface and the side surface of the conductor 120. The insulator 130 is preferably provided in contact with the side surface of the conductor 120. This can prevent a short circuit between the conductor 110 and the conductor 120.

A structure, a material, and the like that can be used for the insulator 130 will be described later.

In the structure illustrated in FIG. 3C and FIG. 3D, an insulator 121 is provided over the conductor 120. The insulator 121 is positioned between the conductor 120 and the conductor 110. In addition, the insulator 121 is preferably provided in contact with the top surface of the conductor 120. A combined structure of the insulator 121 and the conductor 120 preferably includes a region having a columnar shape, for example. Alternatively, the combined structure of the insulator 121 and the conductor 120 may include a region having a conical or pyramidal shape, for example.

At the end of the columnar shape or the end of the conical or pyramidal shape, an electric field between the conductor 120 and the conductor 110 is likely to be concentrated in some cases, for example. Depending on the formation conditions, thickness, or the like of the insulator 130, for example, the coverage with the insulator 130 might be insufficient at the end of the columnar shape or the end of the conical or pyramidal shape. Providing the insulator 121 between the conductor 120 and the conductor 110 in the capacitor 100 can inhibit current leakage or the like between the conductor 120 and the conductor 110 due to the concentration of an electric field, the insufficient coverage, or the like, thereby improving the reliability of the capacitor 100.

The insulator 121 sometimes functions as a protective layer that inhibits etching of the conductor 120 in the step of forming the insulator 144 or the like.

For example, a material that can be used for the insulator 251 can be used for the insulator 121 as appropriate.

In addition, a structure may be employed in which a side end portion of the insulator 130 and a side end portion of the conductor 110 are aligned with each other. This structure enables the insulator 130 and the conductor 110 to be formed using the same mask, so that the fabrication process of the memory device can be simplified.

The conductor 110 is provided over the insulator 130. The conductor 110 functions as the wiring PL. The conductor 110 may be shared by a plurality of memory cells 150 to which the wiring PL is electrically connected. As the conductor 110, a single layer or stacked layers of any of the conductors described in the section [Conductor] below can be used. For example, a conductive material with high conductivity such as tungsten can be used for the conductor 110. With the use of a conductive material with high conductivity, the conductivity of the conductor 110 can be improved and the wiring PL can function sufficiently.

A single layer or stacked layers of a conductive material that is less likely to be oxidized, a conductive material having a function of inhibiting diffusion of oxygen, or the like is preferably used for the conductor 110. For example, titanium nitride, indium tin oxide to which silicon is added, or the like may be used. Alternatively, a structure in which titanium nitride is stacked over tungsten may be used, for example. Alternatively, for example, a structure in which tungsten is stacked over first titanium nitride and second titanium nitride is stacked over the tungsten may be used. With such a structure, when an oxide insulator is used for the insulator 130, the conductor 110 can be inhibited from being oxidized by the insulator 130.

In the structure illustrated in FIG. 3C and FIG. 3D, the insulator 130 and the conductor 110 include a region provided in an opening portion included in the insulator 144. The insulator 130 is provided to cover the side surface and the top surface of the conductor 120 and the bottom surface and the side surface of the opening provided in the insulator 144. The insulator 130 is provided to cover the top surface of the insulator 144.

The conductor 110 is provided to cover the side surface and the top surface of the conductor 120. The conductor 110 is provided to cover the bottom surface and the side surface of the opening provided in the insulator 144. The conductor 110 is provided to cover the top surface of the insulator 144.

The insulator 130 includes a region provided between the conductor 110 and the insulator 144. The conductor 110 covers the side surface of the conductor 120 with the insulator 130 therebetween, for example. The conductor 110 covers the top surface of the conductor 120 with the insulator 121 and the insulator 130 therebetween, for example. The conductor 110 covers the bottom surface and the side surface of the opening provided in the insulator 144 with the insulator 130 therebetween, for example.

For the insulator 130, any of the materials with high dielectric constants, that is, high-k materials, described in the section [Insulator] below may be used. Using such a high-k material for the insulator 130 allows the insulator 130 to be thick enough to inhibit a leakage current and the capacitor 100 to have a sufficiently high capacitance.

It is preferable to use stacked insulating layers formed of high-k materials for the insulator 130, and it is preferable to use a stacked-layer structure of a high dielectric constant (high-k) material and a material having a higher dielectric strength than the high-k material. As the insulator 130, an insulating film in which zirconium oxide, aluminum oxide, and zirconium oxide are stacked in this order can be used, for example. Alternatively, an insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used, for example. The use of stacked insulators with relatively high dielectric strength, such as aluminum oxide, can increase the dielectric strength and inhibit electrostatic breakdown of the capacitor 100.

Alternatively, a material that can have ferroelectricity may be used for the insulator 130. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element. J1 can be set as appropriate; the atomic ratio of hafnium to the element. J1 is, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a κ-alumina-type structure, and the like.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 130 can have a stacked-layer structure of a plurality of materials selected from the above-listed materials. Note that the crystal structures (properties) of the above-listed materials and the like can be changed depending on the processes as well as the deposition conditions; thus, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being processed into a thin film of several nanometers. Here, the thickness of the insulator 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness is preferably greater than or equal to 8 nm and less than or equal to 12 nm, for example. When a ferroelectric layer that can be thin is used, the capacitor 100 can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupying area) less than or equal to 100 μm², less than or equal to 10 μm², less than or equal to 1 μm², or less than or equal to 0.1 μm² in a plan view. Furthermore, even a ferroelectric layer with an area less than or equal to 10000 nm² or less than or equal to 1000 nm² has ferroelectricity in some cases. With a small-area ferroelectric layer, the area occupied by the capacitor 100 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 130 can exhibit ferroelectricity, the insulator 130 needs to include a crystal. It is particularly preferable that the insulator 130 include a crystal having an orthorhombic crystal structure to exhibit ferroelectricity. Note that a crystal included in the insulator 130 may have one or more selected from cubic, tetragonal, orthorhombic, monoclinic, and hexagonal crystal structures. Alternatively, the insulator 130 may have an amorphous structure. In that case, the insulator 130 may have a composite structure including an amorphous structure and a crystal structure.

The insulator 144, which functions as an interlayer film, preferably has a low dielectric constant. When a material with a low dielectric constant is used for an interlayer film, parasitic capacitance generated between wirings can be reduced. As the insulator 144, a single layer or stacked layers of insulators containing any of the materials with low dielectric constants described in the section [Insulator] below can be used. Silicon oxide and silicon oxynitride are preferable because of being thermally stable. In that case, the insulator 144 contains at least silicon and oxygen.

Note that as the insulator 144, any of the insulators having a barrier property against oxygen, which are described in the section [Insulator] below, can also be used. This can inhibit release of oxygen from the oxide semiconductor 230.

As the insulator 144, any of the insulators having a barrier property against hydrogen, which are described in the section [Insulator] below, is preferably used. This can inhibit diffusion of hydrogen from the insulator 130 and the conductor 110 into the oxide semiconductor 230. Silicon nitride and silicon nitride oxide can be suitably used because the silicon nitride and the silicon nitride oxide release fewer impurities (e.g., water and hydrogen) and are less likely to transmit oxygen and hydrogen. In that case, the insulator 144 contains at least silicon and nitrogen.

As the insulator 144, any of the insulators having a function of capturing or fixing hydrogen, which are described in the section [Insulator] below, is preferably used. With this structure, hydrogen in the insulator 130 can be captured or fixed, whereby the hydrogen concentration in the insulator 130 can be reduced. For example, magnesium oxide, aluminum oxide, hafnium oxide, or the like can be suitably used. Alternatively, for example, a stacked-layer film of aluminum oxide and silicon nitride over the aluminum oxide may be used as the insulator 144.

Note that the insulator 144 may have a stacked structure of two or more layers. Among the stacked layers, for the layer positioned on the oxide semiconductor 240 side, an insulator having a barrier property against oxygen, an insulator having a barrier property against hydrogen, an insulator having a function of capturing or fixing hydrogen, or the like can be used, and for the layer positioned on the insulator 130 side, a material with a low dielectric constant can be used, for example.

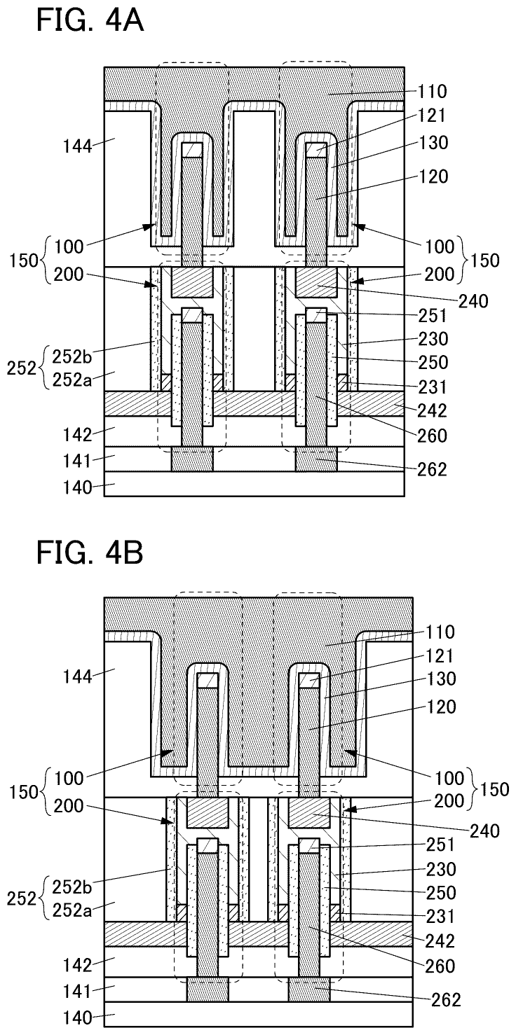

FIG. 4A illustrates a structure example of a memory device in which two transistors 200 are arranged and share the conductor 242. One capacitor 100 is provided over each of the transistors 200, and the two capacitors 100 share the conductor 110.

FIG. 4B illustrates a structure example in which the insulator 144 is not placed between regions of the conductors 110 that cover the side surfaces of the conductors 120 included in the two capacitors 100.

### <Component Materials of Memory Device>

Component materials that can be used for the memory device are described below.

### [Substrate]

As the substrate where the transistor 200 and the capacitor 100 are formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element. Alternatively, these substrates provided with a circuit including a transistor can be used. Alternatively, these substrates provided with a circuit such as a driver circuit can be used.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a low-dielectric-constant material is used for the insulator functioning as an interlayer film, parasitic capacitance generated between wirings can be reduced. Thus, a material is preferably selected depending on the function of the insulator. Note that the low-dielectric-constant material is a material with high dielectric strength.

Examples of the high-dielectric-constant (high-k) material include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the low-dielectric-constant material include inorganic insulating materials such as silicon oxide, silicon oxynitride, and silicon nitride oxide and resins such as polyester, polyolefin, polyamide (e.g., nylon and aramid), polyimide, polycarbonate, and acrylic. Other examples of low-dielectric-constant inorganic insulating materials include silicon oxide to which fluorine is added, silicon oxide to which carbon is added, and silicon oxide to which carbon and nitrogen are added. Another example is porous silicon oxide. Note that these silicon oxides may contain nitrogen.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of the insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of the insulator having a barrier property against hydrogen include aluminum oxide, magnesium oxide, hafnium oxide, gallium oxide, indium gallium zinc oxide, silicon nitride, and silicon nitride oxide.

The insulator having a barrier property against oxygen and the insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond and sometimes has a property of capturing or fixing hydrogen with the dangling bond. Note that these metal oxides preferably have an amorphous structure, but a crystal region may be partly formed.

Note that in this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule and OH-, for example.

Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is less likely to be oxidized, a conductive material having a function of inhibiting oxygen diffusion, or a material maintaining its conductivity even after absorbing oxygen. Note that examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film deposited using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure combining a material containing the above-described metal element and a conductive material containing oxygen may be employed. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

A conductor functioning as a source electrode or a drain electrode includes a region in contact with a semiconductor, for example. In the case where an oxide semiconductor is used as the semiconductor, when the source electrode or the drain electrode is formed using a metal that is likely to be oxidized (e.g., aluminum), an insulating oxide (e.g., aluminum oxide) is formed between the source electrode or the drain electrode and the semiconductor, which might prevent electrical continuity therebetween. Thus, the source electrode and the drain electrode are preferably formed using a conductive material that is less likely to be oxidized or a conductive material that maintains low electric resistance even when oxidized. For example, it is preferable to use one or more of titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, and an oxide containing lanthanum and nickel. These materials are preferable because they are conductive materials that are less likely to be oxidized or conductive materials that maintain low electric resistance even when oxidized. As another example, the source electrode or the drain electrode can be formed using the above-described conductive material containing oxygen. Specifically, one or more of indium oxide, zinc oxide, ITO, In—Zn oxide, In—W oxide, In—W—Zn oxide, In—Ti oxide, In—Ti—Sn oxide, In—Sn oxide containing silicon, and zinc oxide to which gallium is added can be used.

The above-described conductive material containing nitrogen can be used for the conductor 262a, a conductor 110a, the conductor 240a, the conductor 242a, and the like, and the above-described conductive material containing a metal element as its main component can be used for the conductor 262b, a conductor 110b, the conductor 240b, the conductor 242b, and the like. The conductive material containing nitrogen has a barrier property against water and hydrogen in some cases, and thus can improve the reliability of a memory device using an oxide semiconductor in which water and hydrogen cause a change in electrical characteristics. The conductive material containing a metal element as its main component has high conductivity in some cases, and thus can suitably lower the resistances of a wiring and a plug and improve the characteristics of the memory device.

For the conductor 240a, any of the above-described materials that can be used for the source electrode and the drain electrode can be used as appropriate.

For the conductor 242b, any of the above-described materials that can be used for the source electrode and the drain electrode can be used as appropriate.

Alternatively, the conductor 242 may have a stacked-layer structure of three layers including a third conductor in addition to the conductor 242a and the conductor 242b. In that case, for example, any of the above-described materials that can be used for the source electrode and the drain electrode can be used for the third conductor as appropriate.

### [Metal Oxide]

A metal oxide sometimes has a lattice defect. Examples of the lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor might lead to unstable electrical characteristics of the transistor. Hence, a metal oxide used in a semiconductor layer, especially a channel formation region, of a transistor preferably has a small number of lattice defects.

A transistor using a metal oxide is likely to change its electrical characteristics especially in the case where oxygen vacancies (Vo) and impurities exist in a channel formation region in the metal oxide, which might degrade the reliability. In some cases, a defect that is an oxygen vacancy into which hydrogen in the vicinity of the oxygen vacancy has entered (VOH) is formed, which generates an electron serving as a carrier. Therefore, when the channel formation region in the metal oxide includes oxygen vacancies, the transistor is likely to have normally-on characteristics. Therefore, oxygen vacancies and impurities are preferably reduced as much as possible in the channel formation region in the metal oxide. In other words, the channel formation region in the metal oxide is preferably an i-type (intrinsic) or substantially i-type region with a reduced carrier concentration.

Meanwhile, in a low-resistance region such as an n-type region in the metal oxide, the amount of Vo is larger, the amount of VoH is larger, and the concentrations of impurities such as hydrogen, nitrogen, and a metal element are higher than in the channel formation region, for example.

The kind of lattice defect that is likely to exist in a metal oxide and the number of lattice defects that exist vary depending on the structure of the metal oxide, a method for depositing the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, a transistor with high reliability can be achieved.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three kinds selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

For example, as the metal oxide semiconductor of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be given as an example.

Here, the above-described oxide can be used as the metal oxide that can be used for the low-resistance region. The above oxide to which an element, a compound, or the like functioning as a dopant is added may be used. Examples of the element added to the oxide include one or more selected from aluminum, scandium, titanium, vanadium, gallium, yttrium, zirconium, niobium, molybdenum, indium, tin, antimony, tellurium, hafnium, tantalum, tungsten, germanium, silicon, arsenic, boron, and fluorine.

In particular, as the metal oxide that can be used for the low-resistance region, indium tin oxide, indium tin oxide containing silicon, zinc oxide, tin oxide, titanium oxide, zinc oxide containing gallium, zinc oxide containing aluminum, or the like can be suitably used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

The metal oxide of one embodiment of the present invention can be suitably formed by an ALD method.

Examples of the ALD method include a thermal ALD method, in which a precursor and a reactant react with each other only by a thermal energy, and a plasma ALD (PEALD: Plasma Enhanced ALD) method, in which a reactant excited by plasma is used.

The ALD method enables atomic layers to be deposited one by one, and has advantages such as deposition of an extremely thin film, deposition on a component with a high aspect ratio, deposition of a film with few defects such as pinholes, deposition with excellent coverage, and low-temperature deposition. The use of plasma in a PEALD method is sometimes preferable because it enables deposition at a lower temperature. Note that a precursor used in the ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or SIMS. Note that the deposition method of the metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, an ALD method is a deposition method in which a film is formed by reaction at a surface of an object to be processed. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as a sputtering method or a CVD method, in some cases. For example, a method in which a sputtering method is used to deposit a first metal oxide, and an ALD method is used to deposit a second metal oxide over the first metal oxide can be given. For example, in the case where the first metal oxide has a crystal part, crystal growth occurs in the second metal oxide with the use of the crystal part as a nucleus.

In the ALD method, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be deposited. In the case where the film is deposited while the source gas is changed, as compared to the case where the film is deposited using a plurality of deposition chambers, the time taken for the deposition can be shortened because the time taken for transfer and pressure adjustment is not required. Thus, the productivity of the memory device can be increased in some cases.

By increasing the proportion of the number of zinc atoms in the total number of atoms of all the metal elements contained in the metal oxide, the metal oxide has high crystallinity, so that diffusion of impurities in the metal oxide can be inhibited. Accordingly, when such a metal oxide is used for the channel formation region, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, when such a metal oxide is used for the channel formation region, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide in the channel formation region or the like, a high on-state current and high frequency characteristics of the transistor can be achieved.

Here, the metal oxide contained in the transistor of one embodiment of the present invention may have high crystallinity. It is particularly preferable to use a metal oxide with high crystallinity for a metal oxide including a channel formation region. The crystal further preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS, and the like.

The c-axis of the above crystal is preferably aligned in the normal direction with respect to the formation surface or film surface of the metal oxide. This enables the plurality of layers to be placed parallel or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

[Transistor including metal oxide]

Next, the case where a metal oxide (oxide semiconductor) is used for a transistor will be described. Hereinafter, a transistor with a semiconductor layer of an oxide semiconductor is sometimes referred to as an OS transistor, and a transistor with a semiconductor layer of silicon is sometimes referred to as a Si transistor.

The use of the metal oxide (oxide semiconductor) of one embodiment of the present invention for a transistor enables the transistor to have high field-effect mobility. In addition, a transistor with high reliability can be achieved. Furthermore, a miniaturized or highly integrated transistor can be achieved. For example, a transistor with a channel length of greater than or equal to 2 nm and less than or equal to 30 nm can be fabricated.

An oxide semiconductor having a low carrier concentration is preferably used for a channel formation region of a transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that impurities in an oxide semiconductor refer to, for example, elements other than the main components of the oxide semiconductor. For example, an element with a concentration lower than 0.1 atomic % can be regarded as an impurity.

The band gap of the oxide semiconductor used for the channel formation region is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, an OS transistor includes an oxide semiconductor that is a semiconductor material having a wide band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. The smaller the characteristic length is, the more sharply the potential rises; thus, a smaller characteristic length indicates higher resistance to the short-channel effect.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure where the channel formation region is an n⁻-type region and the source region and the drain region are n⁺-type regions.

The OS transistor with the above structure can have favorable electrical characteristics even when a memory device is miniaturized or highly integrated. For example, the OS transistor can have favorable electrical characteristics even when the channel length or gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

[Impurity in metal oxide]

Here, the influence of each impurity in the metal oxide (oxide semiconductor) will be described.

When silicon or carbon, which is one of Group 14 elements, is contained in the oxide semiconductor, defect states are formed in the oxide semiconductor. Accordingly, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### [Other Semiconductor Materials]

The oxide semiconductor 230 can be rephrased as a semiconductor layer including a channel formation region of the transistor. A semiconductor material that can be used for the semiconductor layer is not limited to the above metal oxides. A semiconductor material that has a band gap (a semiconductor material that is not a zero-gap semiconductor) may be used for the semiconductor layer. For example, a single-element semiconductor, a compound semiconductor, or a layered substance (also referred to as an atomic layer substance or a two-dimensional material) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon, nitrogen, and boron atoms arranged in a hexagonal lattice structure on a plane. Chalcogenide is a compound containing chalcogen. Chalcogen is a general term for elements belonging to Group 16, which includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a memory device with a high on-state current to be provided.

Next, a method for fabricating a memory device of one embodiment of the present invention will be described.

### Example of Method for Fabricating Transistor

First, a method for fabricating the transistor 200 is described.

Hereinafter, an insulating material for forming an insulator, a conductive material for forming a conductor, or a semiconductor material for forming a semiconductor can be deposited by a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a memory device may be charged up by receiving electric charge from plasma. In that case, accumulated electric charge may break the wiring, the electrode, the element, or the like included in the memory device. In contrast, such plasma damage is not caused in the case of the thermal CVD method, which does not use plasma, and thus the yield of the memory device can be increased. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are deposition methods that enable favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the memory device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

First, a substrate (not illustrated) is prepared, and the insulator 140 is formed over the substrate. Any of the above-described insulating materials can be used for the insulator 140 as appropriate.

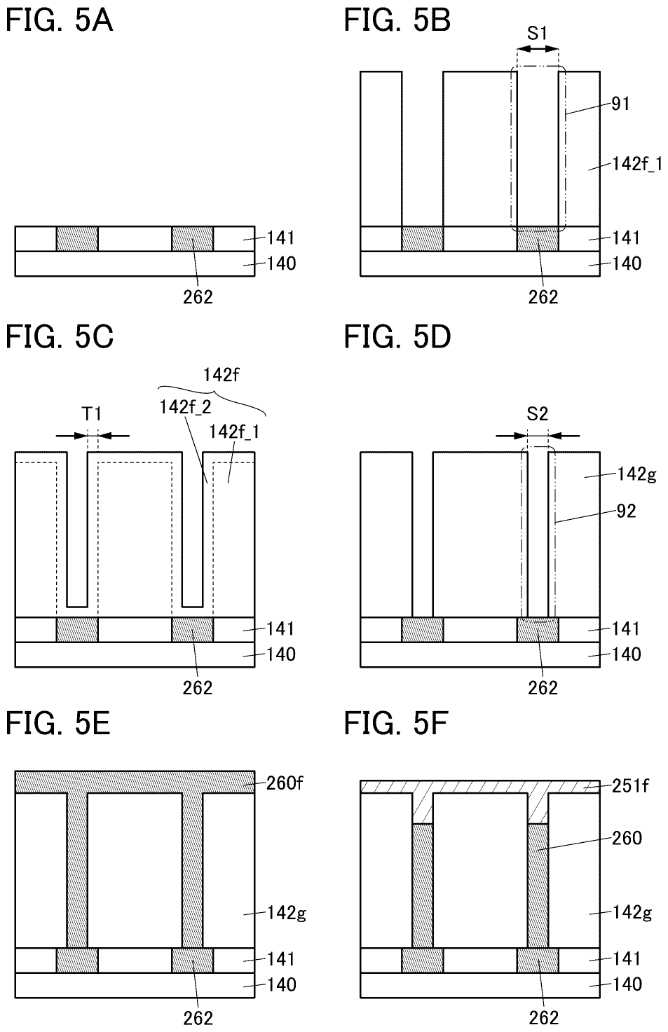

Next, the insulator 141 including an opening is formed over the insulator 140, and the conductor 262 is formed to fill the opening (see FIG. 5A). Any of the above-described conductive materials can be used for the conductor 262 as appropriate. For example, a stacked-layer film in which the conductor 262a and the conductor 262b are deposited in this order is used as the conductor 262, and tungsten as the conductor 262a and titanium nitride as the conductor 262b are formed by a CVD method. The conductor 262 can be formed in such a manner that a conductor to be the conductor 262 is formed in the opening in the insulator 141 and over the insulator 141 and the conductor over the insulator 141 is removed by CMP or the like, for example.

Next, an insulator 142f_1 including an opening 91 is formed over the insulator 141 and the conductor 262 (see FIG. 5B). For the insulator 142f_1, the materials that can be used for the insulator 142 can be referred to. The width of the opening 91 is referred to as a width S1. The opening in the insulator 142f_1 can be processed by a lithography method, for example. A dry etching method or a wet etching method can be used for the processing. Processing by a dry etching method is suitable for microfabrication.

Note that in the lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. For formation of the opening, it is preferable to use a multi-patterning technique including double patterning such as LELE (Litho-Etch-Litho-Etch) and SADP (Self-Aligned Double Patterning), quadruple patterning such as SAQP (Self-Aligned Quadruple Patterning), and octuple patterning. With use of a multi-patterning technique, a fine depressed portion or a fine opening can be formed.

As the multi-patterning, patterning or patterning and etching using a hard mask may be repeated a plurality of times to form a fine pattern. Alternatively, self-aligned multi-patterning may be employed in which an ALD film is deposited on a resist pattern, a sidewall is formed on the side surface of the resist by anisotropic etching, the resist is removed, and the ALD film is used as a mask.

A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

Note that the opening formed in the insulator 142f_1 includes a region overlapping with the conductor 262 in a plan view. Note that the conductor 262 is preferably placed to enclose the opening formed in the insulator 142f_1. Specifically, for example, the opening is preferably positioned inside the conductor 262 in a plan view. Alternatively, part of the opening is sometimes positioned outside the conductor 262 in a plan view. Alternatively, the opening formed in the insulator 142f_1 may be formed to enclose the conductor 262.

Next, an insulator 142f_2 is deposited to cover the sidewall of the opening 91 formed in the insulator 142f_1, the top surface of the insulator 142f_1, and the top surface of the conductor 262 that is exposed at the bottom of the opening 91 included in the insulator 142f_1 (see FIG. 5C). Here, the thickness of the insulator 142f_2 formed on the sidewall of the opening 91 is referred to as a thickness T1. For the insulator 142f_2, the materials that can be used for the insulator 142 can be referred to. The insulator 142f_2 is preferably formed using the same material as the insulator 142f_1. Note that the insulator 142f_1 and the insulator 142f_2 are collectively denoted as an insulator 142f in FIG. 5C.

Next, the insulator 142f is processed to form an insulator 142g. Specifically, at least part of a region of the insulator 142f_2 that covers the top surface of the conductor 262 is removed by anisotropic etching to expose the surface of the conductor 262. Thus, the insulator 142g including an opening 92 can be formed, for example (see FIG. 5D). The width of the opening 92 is referred to as a width S2. The width S2 of the opening 92 can be expressed as S2=S1−(2×T1) using the width S1 of the opening 91 and the thickness T1 of the insulator 142f_2 formed on the sidewall of the opening 91. Here, in the case where the conductor 260 includes a cylindrical region, the width S2 is the diameter of a circle as the top surface shape of the cylinder, for example.

In the case where the width S1 is the minimum value of the opening size by a lithography method, the width S2 can be smaller than the minimum size. Thus, in the formation of the conductor 260 described later, the width of the conductor 260 can be made small, so that the transistor 200 can be miniaturized. Although a method for reducing the opening size by forming the insulator 142f_2 is described here, the opening size may be reduced by attaching a reaction product or the like to the side wall of the opening in etching for the opening 91.

Note that the angle of the side surface of the conductor 260 is determined by the angle of the side surface of the opening 92. The angle of the side surface of the opening 92 is preferably substantially perpendicular.

Next, a conductor 260f is formed in the opening 92 in the insulator 142g and over the insulator 142g (see FIG. 5E). The conductor 260f is preferably formed to fill the opening 92 and to be in contact with the top surface of the conductor 262. For the conductor 260f, the materials that can be used for the conductor 260 can be referred to.

Next, part of the conductor 260f is removed by etching to form the conductor 260. By this etching, a region of the conductor 260f that covers the top surface of the insulator 142g is preferably removed to form the conductor 260 having a columnar shape. Furthermore, the conductor 260 having a columnar shape is preferably formed by this etching such that the top surface of the column is lower than the top surface of the insulator 142g.

The etching of the conductor 260f can be performed by a dry etching method, for example. Since the height of the conductor 260 is determined by this etching, etching distribution is preferably favorable within the substrate plane. Note that in the etching of the conductor 260f, only the upper region is removed and some part remains. Such etching treatment for making some part remain is sometimes referred to as half-etching treatment.

Next, an insulator 251f is formed over the top surface of the insulator 142g, over the top surface of the conductor 260, and in a region of the opening 92 included in the insulator 142g from which the conductor 260f has been removed (see FIG. 5F). The insulator 251f is formed to be in contact with the top surface of the conductor 260, for example. Here, the insulator 142g can be deposited by an ALD method, for example. For the insulator 142g, the materials that can be used for the insulator 142 can be referred to.

An ALD method is a method for suitably obtaining a dense film with high coverage. When the thickness of the insulator 142g is larger than half of the width S2 of the opening 92 (S2×0.5) in the deposition of the insulator 142g, for example, a region over the conductor 260 in the opening 92 can be favorably filled with the insulator 142g.

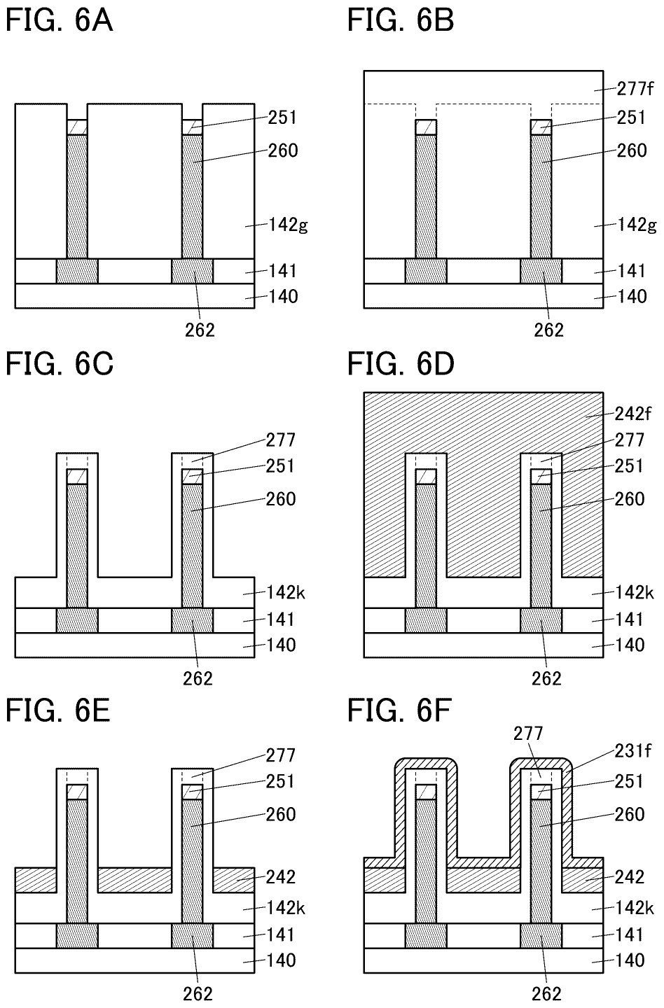

Next, part of the insulator 251f is removed by etching to form the insulator 251 (see FIG. 6A). By this etching, a region of the insulator 251f that is positioned over the top surface of the insulator 142g is preferably removed to form the insulator 251 having a columnar shape. Furthermore, the insulator 251 is preferably formed by this etching such that the top surface of the column is lower than the top surface of the insulator 142g. Note that the insulator 251f may be removed by planarization treatment using CMP.

The etching of the insulator 251f can be performed by a dry etching method, for example. Note that the etching treatment on the insulator 251f is sometimes referred to as half-etching treatment.

Note that the height of the insulator 251 formed can be suitably less than the height of the insulator 142g when the insulator 251f is etched using a condition where the amount of etching of the insulator 142g is small, i.e., a condition where selectivity with respect to the insulator 142g is high. For example, the insulator 251 can be suitably formed when silicon nitride or silicon nitride oxide is used for the insulator 251 and silicon oxide or silicon oxynitride is used for the insulator 142g. Alternatively, for example, silicon oxide or silicon oxynitride may be used for the insulator 142g, and hafnium oxide, aluminum oxide, zirconium oxide, magnesium oxide, or the like may be used for the insulator 251.

Next, an insulator 277f is formed over the insulator 251, in the opening in the insulator 142g, and over the insulator 142g (see FIG. 6B). Here, the insulator 277f can be formed using the same material as the insulator 142g, for example.

Next, the insulator 142g and the insulator 277f are processed to form an insulator covering the top surface of the conductor 260 and an insulator covering the side surface of the conductor 260 (see FIG. 6C). Specifically, for example, the top surface of the insulator 142g is exposed by planarization treatment using CMP, etch back, or the like, and then the insulator 142 is processed using a mask to form an insulator 142k. Here, the thickness of the insulator covering the side surface of the conductor 260 corresponds to the thickness of the insulator 250 functioning as the gate insulator of the transistor 200 later; thus, the thickness thereof is preferably substantially uniform on the side surface of the conductor 260.

Although FIG. 6C illustrates a structure in which an insulator 277 formed by processing the insulator 277f covers the top surface of the conductor 260 and the insulator 142k formed by processing the insulator 142g covers the side surface of the conductor 260, the insulator 277 may include a region covering the side surface of the conductor 260, for example. In the case where the insulator 277f is formed using the same material as the insulator 142g, the boundary between the insulator 277 and the insulator 142k is sometimes difficult to determine in observation of the transistor 200, and the insulator 277 and the insulator 142k are sometimes observed as a continuous film. The insulator 277f and the insulator 142g can each be processed by, for example, forming a mask by a lithography method and performing dry etching using the mask.

Here, a cross section of the transistor 200 can be exposed by processing and can be observed with a transmission electron microscope (TEM), a scanning transmission electron microscope (TEM), or the like.

Next, a conductor 242f is formed over the insulator 142k and the insulator 277 (see FIG. 6D). For the conductor 242f, the materials that can be used for the conductor 242 can be referred to.

Next, part of the conductor 242f is removed by etching to form the conductor 242 (see FIG. 6E). The conductor 242f can be processed by performing etching substantially uniformly on the top surface of the conductor 242f, for example. Such an etching step is referred to as etch-back treatment in some cases. In the case where the top surface of the conductor 242f has unevenness, etching may be performed after the surface of the conductor 242 is planarized. For the planarization, CMP (Chemical Mechanical Polishing) treatment can be used.

Next, a metal oxide 231f is formed to cover the conductor 242, the insulator 142k, and the insulator 277 (see FIG. 6F). For the metal oxide 231f, the materials that can be used for the metal oxide 231 can be referred to. The metal oxide 23 If includes a region overlapping with the conductor 260 with the insulator 142k therebetween.

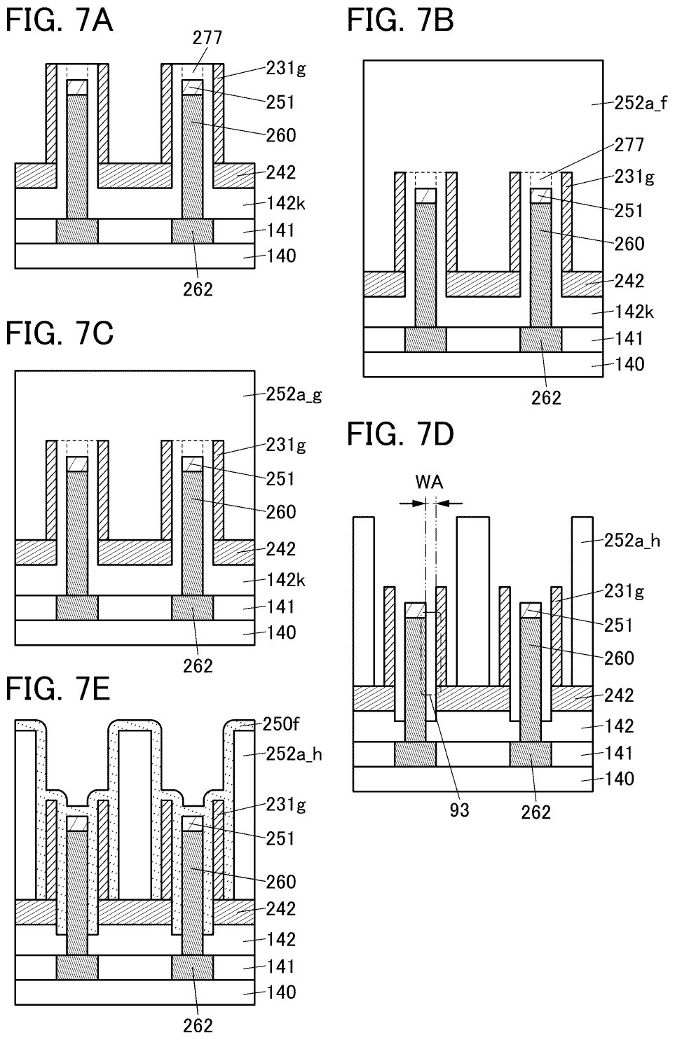

Next, regions of the metal oxide 231f that cover the top surface of the conductor 242 and the top surface of the insulator 277 and the like are removed by etching to form a metal oxide 231g (see FIG. 7A). The metal oxide 231g includes a region overlapping with the conductor 260 with the insulator 142k therebetween.

Next, an insulator 252a_f is formed to cover the conductor 242, the metal oxide 231g, the insulator 277, the insulator 142k, and the like (see FIG. 7B). For the insulator 252a_f, the materials that can be used for the insulator 252a can be referred to.

Next, the top surface of the insulator 252a_f is planarized and partly removed to form an insulator 252a_g (see FIG. 7C). Although not illustrated in FIG. 7B, the surface of the insulator 252a_f sometimes has unevenness due to unevenness of its formation surface. In such a case, planarization can be performed to make the surface substantially flat or reduce unevenness of the surface. For the planarization, CMP treatment can be used.

The planarization of the insulator 252a_f enables a conductor 240f formed later to have a uniform thickness and reduces variation in size or the like in processing of the conductor 240, thereby facilitating fabrication.

Next, part of the insulator 252a_g is removed to form an insulator 252a_h (see FIG. 7D). The insulator 252a_h is formed to isolate each region to be the transistor 200, for example. A removed region of the insulator 252a_g includes a region overlapping with the conductor 260 and a region overlapping with the metal oxide 231g. Part of the removed region of the insulator 252a_g is a region where the insulator 252b is formed later. For example, a region of the insulator 252a_g that is positioned in a region between the conductor 260 and the metal oxide 231g is removed, and such a region is a region where the insulator 250 is formed later.

An insulator 250f is formed over the insulator 252a_h and in a region where a space is formed by removal of the insulator 252a_g (see FIG. 7E). For the insulator 250f, the materials that can be used for the insulator 250 can be referred to. The region where the insulator 250f is formed includes a space 93 formed in the region between the conductor 260 and the metal oxide 231g. A width WA of the space 93 is a width that roughly corresponds to the thickness of the gate insulator of the transistor 200, and a deposition method with favorable coverage is preferably employed for such a relatively narrow region. In view of this, an ALD method can be suitably used to form the insulator 250f.

Note that the space 93 can be filled with the insulator 250f when the thickness of the insulator 250f is larger than half of the width WA (WA×0.5).

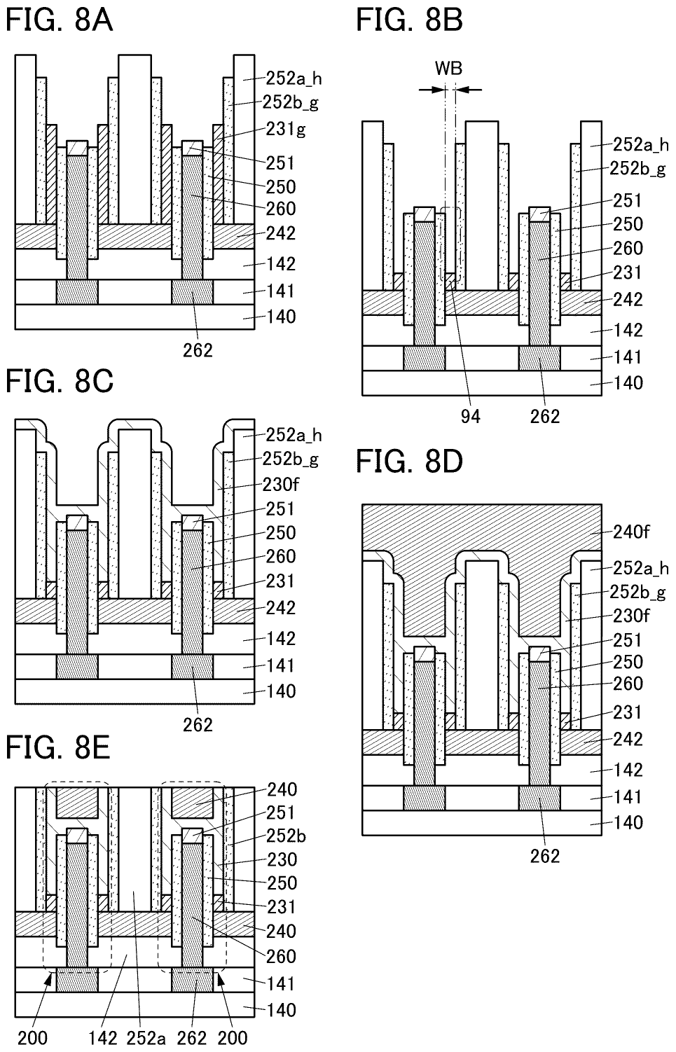

Next, part of the insulator 250f is removed by etching to form the insulator 250 and an insulator 252b_g (see FIG. 8A). At least a region of the insulator 250f over the metal oxide 231g is preferably removed by this etching. The region removed by this etching includes, for example, a region covering the top surface of the insulator 252a_h. Note that the etching treatment on the insulator 250f is sometimes referred to as half-etching treatment.

Next, part of the metal oxide 231g is removed by etching to form the metal oxide 231 (see FIG. 8B). By this etching, a space 94 is formed in a region between the insulator 250 and the insulator 252b_g. The height of a region where the oxide semiconductor 230 overlaps with the conductor 260 changes with the height of the metal oxide 231. The height of the metal oxide 231 is determined in accordance with the characteristics and reliability required for the transistor 200. Note that the etching treatment on the metal oxide 231g is sometimes referred to as half-etching treatment.

Next, an oxide semiconductor 230f is formed in a region including the space formed by removal of the metal oxide 231g (see FIG. 8C). For the oxide semiconductor 230f, the materials that can be used for the oxide semiconductor 230 can be referred to. The oxide semiconductor 230f is formed to cover the metal oxide 231, the insulator 250, the insulator 251, the insulator 252b_g, and the insulator 252a_h. A width WB of the space 94 is a width that roughly corresponds to the thickness of the oxide semiconductor 230, and a deposition method with favorable coverage is preferably employed for such a relatively narrow region. In view of this, an ALD method can be suitably used to form the oxide semiconductor 230f.

Note that the space 94 can be filled with the oxide semiconductor 230f when the thickness of the oxide semiconductor 230f is larger than half of the width WB (WB×0.5).

Next, the conductor 240f is formed over the oxide semiconductor 230f (see FIG. 8D). For the conductor 240f, the materials that can be used for the conductor 240 can be referred to.

Next, the conductor 240f, the oxide semiconductor 230f, the insulator 252a_h, and the insulator 252b_g are partly removed and planarized to form the conductor 240, the oxide semiconductor 230, the insulator 252a, and the insulator 252b such that the top surfaces thereof are substantially level with each other (see FIG. 8E). By this planarization, a structure can be fabricated in which the conductor 240 included in each of the adjacent transistors 200 is isolated by the insulator 252a. For the planarization, CMP treatment can be used.

Through the above process, the transistor of one embodiment of the present invention can be fabricated.

### Example 2 of Method for Fabricating Transistor

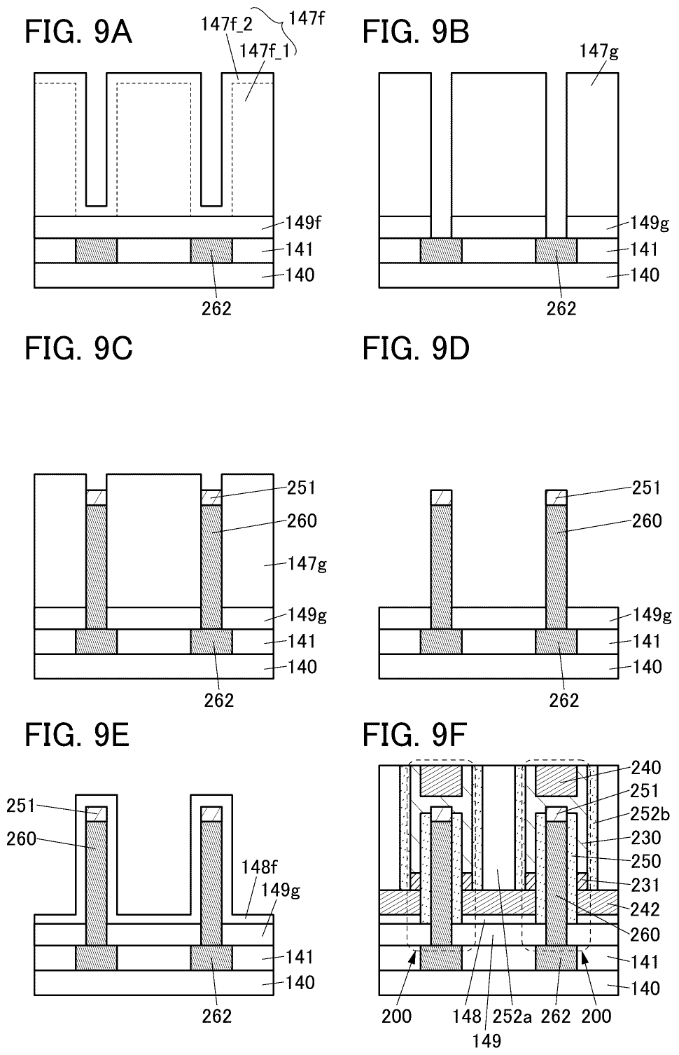

Note that a structure may be employed in which the insulator 121 in the transistor 200 illustrated in FIG. 8E is replaced with a stacked-layer structure of an insulator 149 and an insulator 148 over the insulator 149 as illustrated in FIG. 9F. A method for fabricating the structure illustrated in FIG. 9F is described with reference to FIG. 9A to FIG. 9E.

First, an insulator 149f is formed over the insulator 141 and the conductor 262, and an insulator 147f_1 including an opening is formed over the insulator 149f. Furthermore, an insulator 147f_2 is formed over the insulator 147f_1 (see FIG. 9A). Here, the width of the opening included in the insulator 147f_1 can be narrowed by forming the insulator 147f_2. Note that the insulator 147f_1 and the insulator 147f_2 are collectively denoted as an insulator 147f in FIG. 9A.

Next, the insulator 147f is processed to form an insulator 147g. Specifically, at least part of a region of the insulator 147f_2 that is in contact with the top surface of the insulator 149f is removed to form the insulator 147g. Furthermore, an opening is provided in the insulator 149f using the insulator 147g as a mask to form an insulator 149g (see FIG. 9B).

Next, the conductor 260 is formed in the openings included in the insulator 147g and the insulator 149g. Then, the insulator 251 is formed in the opening in the insulator 147g (see FIG. 9C).

Next, the insulator 147g is removed to expose the surface of the insulator 149g (see FIG. 9D). Here, the insulator 149g preferably remains after the etching of the insulator 147g. Thus, as the insulator 149g, a film having high etching selectivity with respect to the insulator 147g is preferably used. For example, silicon nitride or silicon nitride oxide can be used for the insulator 149g, and silicon oxide or silicon oxynitride can be used for the insulator 147g. By providing the insulator 149g, an insulator provided between the conductor 262 and the conductor 242 can be formed without half-etching treatment. This can inhibit variation in the insulator or the like due to variation in the amount of etching within the substrate plane in the etching step. Next, an insulator 148f is formed to cover the insulator 149g, the conductor 260, and the insulator 251 (see FIG. 9E). After that, the structure illustrated in FIG. 9F is fabricated with reference to the steps in FIG. 6D to FIG. 8E.

### Example of Method for Fabricating Memory Device

An example of a method for fabricating the memory device of one embodiment of the present invention is described below.

First, the insulator 140 is formed over a substrate (not illustrated), and the transistor 200 is formed over the insulator 140 by the method illustrated in FIG. 5A to FIG. 8E.

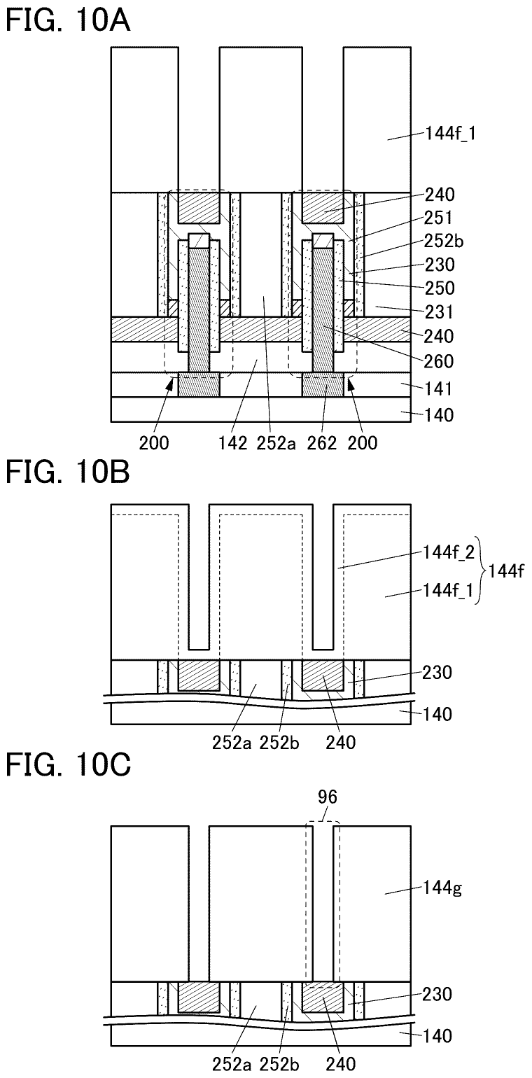

Next, an insulator to be an insulator 144f_1 is formed over the transistor 200. After that, an opening is formed in a region of the insulator that overlaps with the conductor 240 to form the insulator 144f_1 (see FIG. 10A). For the insulator 144f, the materials that can be used for the insulator 144 can be referred to.

Next, an insulator 144f_2 is deposited to cover the sidewall of the opening formed in the insulator 144f_1, the top surface of the insulator 144f_1, and the top surface of the conductor 240 that is exposed at the bottom of the opening included in the insulator 144f_1 (see FIG. 10B). The insulator 144f_2 is preferably formed using the same material as the insulator 144f_1. Note that the insulator 144f_1 and the insulator 144f_2 are collectively denoted as an insulator 144f in FIG. 10B.

Next, the insulator 144f is processed to form an insulator 144g. Specifically, at least part of a region of the insulator 144f_2 that covers the top surface of the conductor 240 is removed. Thus, the insulator 144g including an opening 96 can be formed, for example (see FIG. 10C). By providing the insulator 144f_2, the insulator 144g including an opening having a width smaller than the minimum value of the opening size by a lithography method can be formed. The above-described multi-patterning technique can be used as appropriate for the formation of the opening. Note that the angle of the side surface of the conductor 120 is determined by the angle of the side surface of the opening 96. The angle of the side surface of the opening 96 is preferably substantially perpendicular.

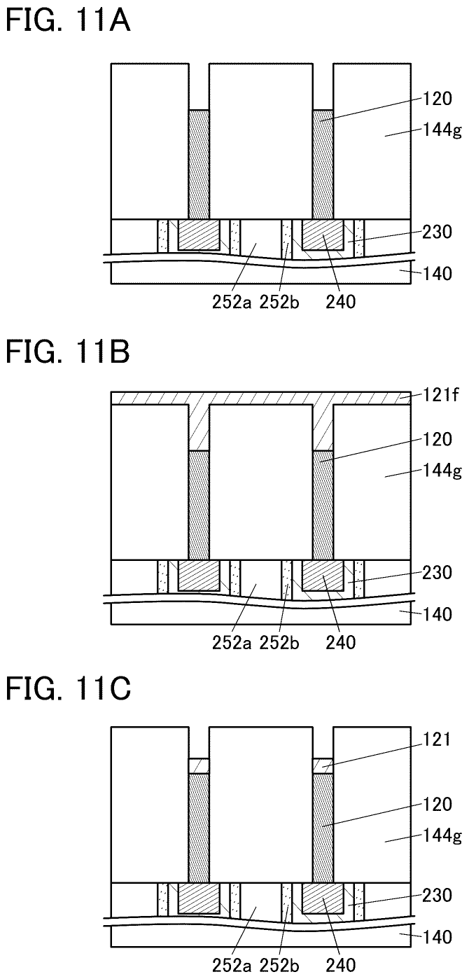

Next, a conductor to be the conductor 120 is formed to fill the opening provided in the insulator 144g, and the conductor is processed such that the level of the top surface of the conductor 120 is lower than the level of the top surface of the insulator 144g, whereby the conductor 120 having a columnar shape is obtained (see FIG. 11A). The conductor 120 can be formed by an ALD method, for example. Here, for example, titanium nitride is formed by an ALD method as the conductor to be the conductor 120.

Next, an insulator 121f is formed over the top surface of the insulator 144g, over the top surface of the conductor 120, and in a region of the opening 96 included in the insulator 144g that is not filled with the conductor 120 (see FIG. 11B). For the insulator 121f, the materials that can be used for the insulator 121 can be referred to.

Here, the insulator 121f can be deposited by an ALD method, for example. The thickness of the insulator 121f is, for example, larger than half of the width of the opening 96.

Next, part of the insulator 121f is removed by etching to form the insulator 121 (see FIG. 11C). By this etching, a region of the insulator 251f that is positioned over the top surface of the insulator 144g is preferably removed to form the insulator 121 having a columnar shape. Furthermore, the insulator 121 is preferably formed by this etching such that the top surface of the column is lower than the top surface of the insulator 144g.

The etching of the insulator 121f can be performed by a dry etching method, for example.

Note that the height of the insulator 121 formed can be suitably lower than the height of the insulator 144g when the insulator 121f is etched using a condition where selectivity with respect to the insulator 144g is high. For example, the insulator 121 can be suitably formed when silicon nitride or silicon nitride oxide is used for the insulator 121 and silicon oxide or silicon oxynitride is used for the insulator 144g.

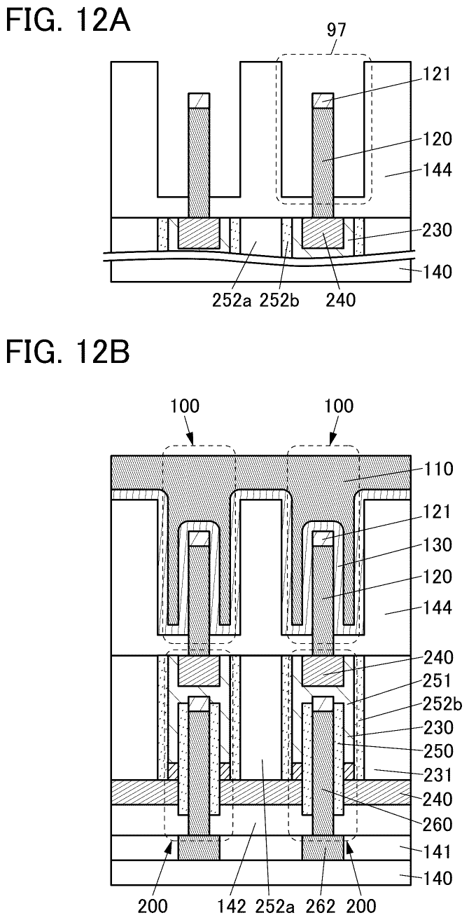

Next, part of the insulator 144g is removed by etching to form the insulator 144 including an opening 97 (see FIG. 12A). By this etching, a region of the insulator 144g that surrounds the conductor 120 is removed to expose the side surface of the conductor 120. The opening 97 is provided in the region surrounding the conductor 120, and the insulator 144 remains at the bottom portion of the opening 97. Thus, the top surface of the conductor 240 is not exposed even after the opening 97 is provided.

The opening 97 can be formed by, for example, a dry etching method or the like with a resist mask covering a region over the insulator 144g other than the region where the opening is to be provided. At that time, the region of the insulator 144g that is not covered with the resist mask is not entirely etched, and the etching is stopped during the step such that part of the insulator 144g remains. The etching treatment on the insulator 144g is sometimes referred to as half-etching treatment.

Note that FIG. 12A illustrates the structure in which the bottom portion of the opening 97 does not reach the top surface of the conductor 240. Accordingly, the insulator 144 is placed in addition to the insulator 130 between the conductor 110 formed in a later step and the conductor 240, and the conductor 110 and the layer where the transistor 200 is formed can be away from each other. Thus, even in the case where the insulator 130 is formed thin at the bottom portion of the opening 97 or the like, leakage between the conductor 240 and the conductor 110 can be inhibited. Since the capacitance value of the capacitor 100 depends on the depth of the opening 97, the capacitance value of the capacitor 100, variation in capacitance among elements, and the like can also be controlled by controlling the depth.

It is preferable that, by this etching, the insulator 121 remain, the insulator 144g in the region surrounding the insulator 121 be removed, and the side surface of the insulator 121 be exposed. Thus, as the insulator 121, a film having high etching selectivity with respect to the insulator 144g is preferably used. For example, silicon nitride or silicon nitride oxide can be used for the insulator 121, and silicon oxide or silicon oxynitride can be used for the insulator 144g. Note that in the case where etching selectivity with respect to the conductor 120 can be sufficiently high in the etching of the insulator 144g, a structure may be employed in which the insulator 121 is not provided in the capacitor 100.

Next, the insulator 130 is formed to cover the exposed side surface of the conductor 120. In addition to the side surface of the conductor 120, the insulator 130 covers the bottom portion of the opening 97 in the insulator 144g, the side surface of the opening 97, and the top surface of the insulator 144g, for example.

For example, a stacked-layer film in which zirconium oxide, aluminum oxide, and zirconium oxide are deposited in this order by an ALD method is formed as the insulator 130. Here, the thickness of the insulator 130 corresponds to the capacitance of the capacitor 100. The thickness of the insulator 130 can be set as appropriate in accordance with the design value of the capacitance of the capacitor 100. Leakage current between the conductor 120 and the conductor 110 might be generated with a reduction in the thickness of the insulator 130. The thickness of the insulator 130, the height of the conductor 120, and the like are controlled as appropriate so that the capacitance value can be sufficient for inhibiting the influence of such leakage current in operation of the memory device.

Next, the conductor 110 is formed over the insulator 130 (see FIG. 12B). Note that the surface of the conductor 110 is preferably planarized by being subjected to treatment. For the planarization, for example, a CMP method or the like can be used.

In the case where the conductor 110 has the stacked-layer structure of the conductor 110a and the conductor 110b illustrated in FIG. 3C, FIG. 3D, and the like, titanium nitride and tungsten are used for the conductor 110a and the conductor 110b, respectively, for example. The conductor 110 can be formed by a CVD method, for example.

Through the above process, the memory device of one embodiment of the present invention similar to that illustrated in FIG. 4A or the like can be fabricated.

### Example 2 of Method for Fabricating Memory Device

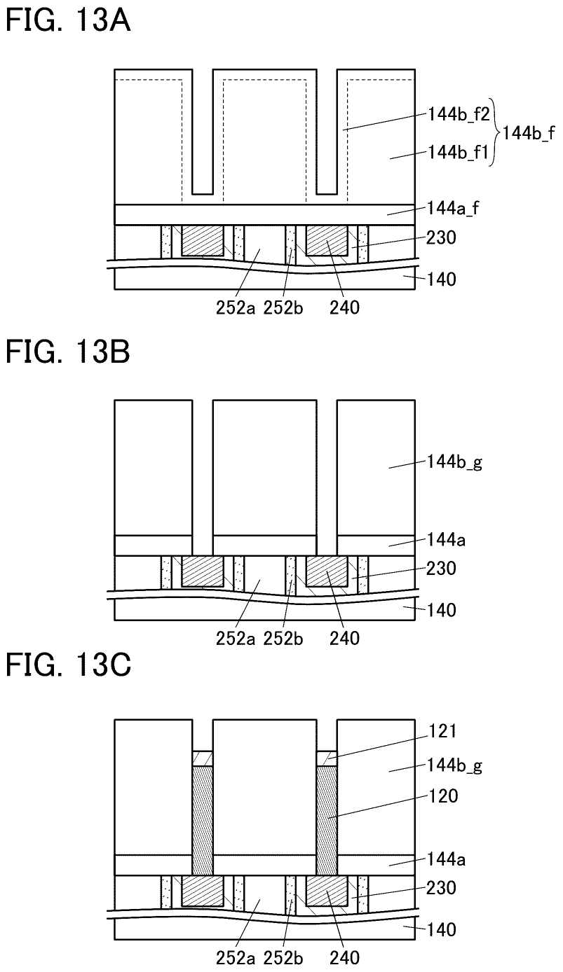

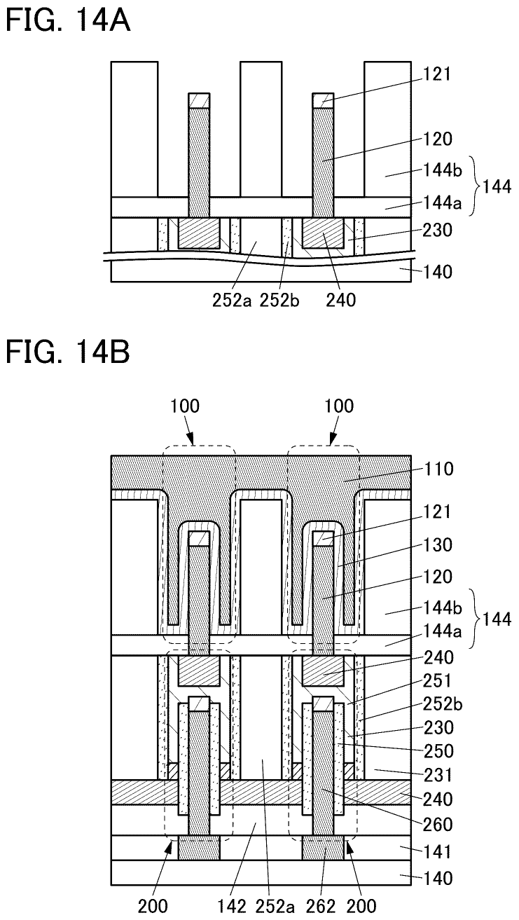

Note that a structure may be employed in which the insulator 144 in the memory device illustrated in FIG. 12B is replaced with a stacked-layer structure of an insulator 144a and an insulator 144b over the insulator 144a as illustrated in FIG. 14B. A method for fabricating the structure illustrated in FIG. 14B is described with reference to FIG. 13A to FIG. 14B.

First, an insulator 144a_f is formed over the transistor 200, and an insulator 144b_f1 including an opening is formed over the insulator 144a_f. Furthermore, an insulator 144b_f2 is formed over the insulator 144b_f1 (see FIG. 13A). Here, the width of the opening included in the insulator 144b_f1 can be narrowed by forming the insulator 144b_f2. Note that the insulator 144b_f1 and the insulator 144b_f2 are collectively denoted as an insulator 144b_f in FIG. 13A.

Next, the insulator 144b_f is processed to form an insulator 144b_g. Specifically, at least part of a region of the insulator 144b_f2 that is in contact with the top surface of the insulator 144a_f is removed to form the insulator 144b_g. Furthermore, an opening is provided in the insulator 144a_f using the insulator 144b_g as a mask to form the insulator 144a (see FIG. 13B).

Next, the conductor 120 is formed in the openings included in the insulator 144a and the insulator 144b_g. Next, the insulator 121 is formed in the opening in the insulator 144b_g (see FIG. 13C).

Next, part of the insulator 144b_g is removed to form the insulator 144b including an opening (see FIG. 14A). Here, the insulator 144a preferably remains after the etching of the insulator 144b_g. Thus, as the insulator 144a, a film having high etching selectivity with respect to the insulator 144b_g is preferably used. For example, silicon nitride or silicon nitride oxide can be used for the insulator 144a. By providing the insulator 144a, an opening to be filled with the insulator 130 and the conductor 110 can be formed without half-etching treatment. This can inhibit variation in opening depth or the like due to variation in the amount of etching within the substrate plane in the etching step.

Next, the insulator 130 is formed to cover the exposed side surface of the conductor 120. In addition to the side surface of the conductor 120, the insulator 130 covers the top surface of the insulator 144a, the side surface of the opening included in the insulator 144b, and the top surface of the insulator 144b, for example.

Next, the conductor 110 is formed over the insulator 130, whereby the memory device of one embodiment of the present invention can be fabricated (see FIG. 14B).

When the insulator in the memory device of one embodiment of the present invention is deposited by a sputtering method in an oxygen-containing atmosphere, the insulator containing excess oxygen can be formed. By using a sputtering method that does not need to use a molecule containing hydrogen as a deposition gas, the hydrogen concentration in the insulator can be reduced.

The formation of the insulator containing oxygen may be followed by heat treatment.

The heat treatment can suitably diffuse oxygen contained in the insulator into the oxide semiconductor 230.

### Modification Example 1 of Transistor 200

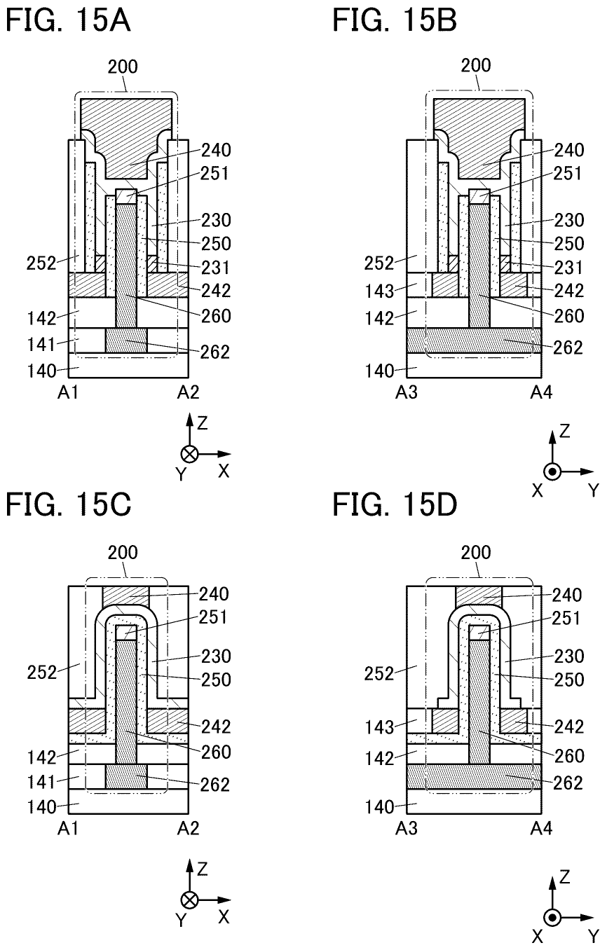

A structure illustrated in FIG. 15A and FIG. 15B is different from the structure illustrated in FIG. 1C and FIG. 1D in that the oxide semiconductor 230 does not cover the side surface of the conductor 240, for example.

### Modification Example 2 of Transistor 200

A structure illustrated in FIG. 15C and FIG. 15D is different from the structure illustrated in FIG. 1C and FIG. 1D in the shape of the insulator 250, the shape of the oxide semiconductor 230, and the like.

In FIG. 15C and FIG. 15D, the insulator 250 includes a region covering the side surface of the conductor 260, a region covering the side surface and the top surface of the insulator 251, a region interposed between the insulator 142 and the conductor 242, and the like. The oxide semiconductor 230 includes a region covering the top surface of the conductor 242, a region covering the side surface and the top surface of the insulator 250, and the like. The conductor 240 includes a region covering the top surface of the oxide semiconductor 230, a region covering the top surface of the insulator 252, and the like. The insulator 252 is provided to surround the oxide semiconductor 230, and the conductor 240 and the conductor 242 are insulated from each other by the insulator 252 or the like.

Note that the conductor 240 may cover part of the side surface in addition to the top surface of the oxide semiconductor 230.

### Modification Example 1 of Memory Device

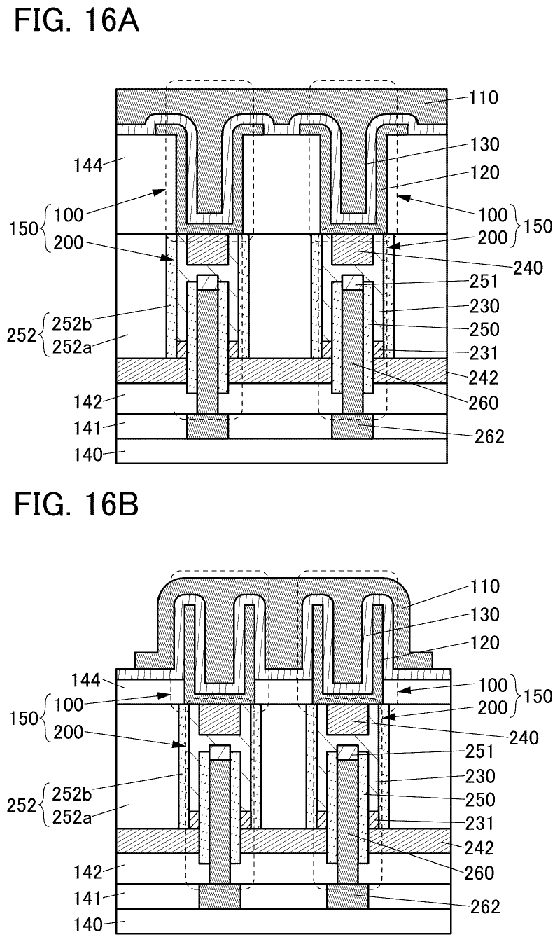

A memory device illustrated in FIG. 16A includes the transistor 200 and the capacitor 100 over the transistor 200. The capacitor 100 illustrated in FIG. 16A differs in structure from the capacitor illustrated in FIG. 3C or the like.

The capacitor 100 illustrated in FIG. 16A includes the conductor 120 over the conductor 240, the insulator 130 over the conductor 120, and the conductor 110 over the insulator 130.

An opening reaching the conductor 240 is provided in the insulator 144, and at least part of the conductor 120 is placed in the opening. The conductor 120 includes a region in contact with the top surface of the conductor 240 and a region in contact with the side surface of the insulator 144, in the opening. The conductor 120 includes a region in contact with the top surface of the insulator 144.

The insulator 130 is provided to cover the top surface and the side surface of the conductor 120 and the top surface of the insulator 144. The insulator 130 is provided to cover the side surface of the conductor 120 in the opening included in the insulator 144, and the conductor 120 includes a region interposed between the insulator 144 and the insulator 130. The conductor 110 is provided to fill a depressed portion included in the insulator 144 with the insulator 130 therebetween.

The capacitor 100 illustrated in FIG. 16A can be fabricated through a simple process in which an opening is provided in the insulator 144, a film to be the conductor 120 is formed over the insulator 144 and then processed to form the conductor 120, the insulator 130 is formed to cover the conductor 120, and the conductor 110 is formed in a depressed portion of the insulator 144 with the insulator 130 therebetween, for example.

### Modification Example 2 of Memory Device

A memory device illustrated in FIG. 16B includes the transistor 200 and the capacitor 100 over the transistor 200. The capacitor 100 illustrated in FIG. 16B is different from the capacitor illustrated in FIG. 16A or the like in that the conductor 110 includes a region positioned on the outer side surface side of the conductor 120 with the insulator 130 therebetween, for example. In FIG. 16B, the conductor 120 includes a region where both the outer side surface and the inner side surface thereof are covered with the insulator 130.

The structure illustrated in FIG. 16B can provide a larger capacitance value than the structure illustrated in FIG. 16A because the capacitor can be formed also on the outer side surface side of the conductor 120.

At least part of the structure, method, and the like described in this embodiment can be implemented in appropriate combination with any of the other embodiments described in this specification.

### Embodiment 2

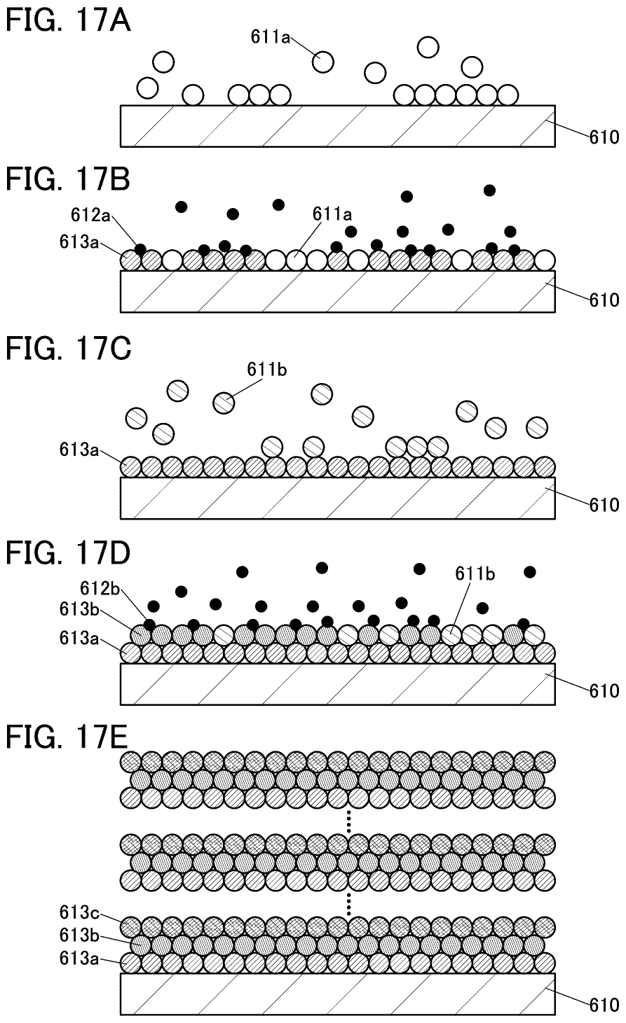

In this embodiment, a metal oxide (hereinafter also referred to as an oxide semiconductor or an oxide in some cases) that can be used for the semiconductor layer of the transistor in the memory device described in the above embodiment and a deposition method thereof are described with reference to FIG. 17 to FIG. 20.

In the memory device of one embodiment of the present invention, it is preferable to use a metal oxide with high crystallinity for a metal oxide including a channel formation region. The crystal further preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked.

For the formation of a metal oxide having the layered crystal structure, atomic layers are preferably deposited one by one. For example, an ALD (Atomic Layer Deposition) method can be used as the formation method of the metal oxide.

The ALD method enables atomic layers to be deposited one by one, and has advantages such as deposition of an extremely thin film, deposition on a component with a high aspect ratio, deposition of a film with a small number of defects such as pinholes, deposition with excellent coverage, and low-temperature deposition. The ALD method includes a thermal ALD method, which is a deposition method using heat, and a plasma ALD (PEALD: Plasma Enhanced ALD) method, which is a deposition method using plasma. The use of plasma is sometimes preferable because it enables deposition at a lower temperature. Note that a precursor used in the ALD method sometimes contains an element such as carbon or chlorine. Thus, in some cases, a film provided by an ALD method contains a larger amount of an element such as carbon or chlorine than a film provided by another deposition method. Note that these elements can be quantified by X-ray photoelectron spectroscopy (XPS) or secondary ion mass spectrometry (SIMS).

Unlike a deposition method in which particles ejected from a target or the like are deposited, an ALD method is a deposition method in which a film is formed by reaction at a surface of an object to be processed. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example.

### <Deposition Method of Metal Oxide by ALD Method>

Here, a method for depositing a metal oxide by an ALD method that can be used in one embodiment of the present invention is described.

An example of a method employing an ALD method for depositing a metal oxide is described with reference to FIG. 17A to FIG. 17E. First, a precursor 611a is introduced into a chamber and the precursor 611a is adsorbed onto a surface of a substrate 610 (see FIG. 17A; hereinafter, the step is referred to as a first step in some cases). Here, as illustrated in FIG. 17A, the precursor 611a is adsorbed onto the surface of the substrate 610, whereby a self-limiting mechanism of surface chemical reaction works and no more precursor 611a is adsorbed onto a layer of the precursor 611a over the substrate 610. Note that the proper range of substrate temperatures at which the self-limiting mechanism of surface chemical reaction works is also referred to as an ALD Window. The ALD Window is determined by the adsorption rate relative to temperature, the decomposition temperature, and the like of a precursor and is sometimes set to higher than or equal to 100° C. and lower than or equal to 600° C., preferably higher than or equal to 200° C. and lower than or equal to 400° C., for example.

Next, an inert gas (e.g., argon, helium, or nitrogen) or the like is introduced into the chamber, so that a surplus of the precursor 611a, a reaction product, and the like are released from the chamber (hereinafter, the step is referred to as a second step in some cases). Instead of introduction of an inert gas into the chamber, vacuum evacuation may be performed to release a surplus precursor, a reaction product, and the like from the chamber. The second step is also called purge.

Next, a reactant 612a (e.g., an oxidizer (ozone (O₃), oxygen (O₂), water (H₂O), and plasma, a radical, and an ion thereof)) is introduced into the chamber to react with the precursor 611a adsorbed onto the surface of the substrate 610, whereby part of components contained in the precursor 611a is released while the component molecules of the precursor 611a are kept adsorbed onto the substrate 610 (see FIG. 17B; hereinafter, the step is referred to as a third step in some cases). Thus, a layer of an oxide 613a, which is formed by oxidation of part of the precursor 611a, is formed on the surface of the substrate 610.

Next, introduction of an inert gas or vacuum evacuation is performed, whereby a surplus of the reactant 612a, a reaction product, or the like is released from the chamber (hereinafter, the step is referred to as a fourth step in some cases).

Then, a precursor 611b containing a metal element different from that in the precursor 611a is introduced and a step similar to the first step is performed, so that the precursor 611b is adsorbed onto a surface of the layer of the oxide 613a (see FIG. 17C). Here, as illustrated in FIG. 17C, the precursor 611b is adsorbed onto the layer of the oxide 613a, whereby a self-limiting mechanism of surface chemical reaction works and no more precursor 611b is adsorbed onto a layer of the precursor 611b over the substrate 610.

Next, as in the second step, introduction of an inert gas or vacuum evacuation is performed, whereby a surplus of the precursor 611b, a reaction product, and the like are released from the chamber.

Next, as in the third step, a reactant 612b is introduced into the chamber. Here, the reactant 612b that is the same as or different from the reactant 612a may be used (see FIG. 17D). Thus, a layer of an oxide 613b, which is formed by oxidation of part of the precursor 611b, is formed over the layer of the oxide 613a.

Then, as in the fourth step, introduction of an inert gas or vacuum evacuation is performed, whereby a surplus of the reactant 612b, a reaction product, and the like are released from the chamber.

Furthermore, the first to fourth steps are performed in a similar manner, whereby a layer of an oxide 613c can be formed over the layer of the oxide 613b. As described above, by performing the steps for forming the oxide 613a to the oxide 613c repeatedly, a metal oxide having a layered crystal structure in which the stacked-layer structure including the oxide 613a to the oxide 613c is repeated can be formed (see FIG. 17E).

Note that the thickness of the layered metal oxide is greater than or equal to 1 nm and less than 100 nm, preferably greater than or equal to 3 nm and less than 20 nm.

In the formation of a metal oxide having a layered crystal structure, it is preferable that the steps illustrated in FIG. 17 be performed while the substrate is being heated. The substrate temperature is higher than or equal to 200° C. and lower than or equal to 600° C., preferably higher than or equal to 300° C. and lower than or equal to the precursor decomposition temperature. In the case where deposition is performed by an ALD method with use of a plurality of different kinds of precursors, the substrate temperature is preferably lower than or equal to the lowest precursor decomposition temperature among the plurality of precursors. Accordingly, in deposition by an ALD method, the plurality of precursors that are used can be adsorbed onto an object (e.g., a substrate) without being decomposed.

By performing the deposition while the substrate is being heated in such a temperature range, an impurity such as hydrogen or carbon contained in the precursor, the reactant, and the like can be removed from the metal oxide in each of the step 1 to the step 4. For example, carbon in the metal oxide can be released as CO₂ and CO, and hydrogen in the metal oxide can be released as H₂O. Furthermore, metal atoms and oxygen atoms are rearranged concurrently with removal of the impurity, so that layers of oxides can be arranged orderly. Thus, a metal oxide having a layered crystal structure with high crystallinity can be formed.

In order to perform deposition while the substrate is being heated in the above temperature range, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, a precursor formed of an inorganic material (hereinafter referred to as an inorganic precursor) is preferably used. In general, an inorganic precursor tends to have a higher decomposition temperature than a precursor formed of an organic material (hereinafter referred to as an organic precursor); thus, some inorganic precursors have the ALD Window in the above temperature range. Moreover, an inorganic precursor does not contain an impurity such as hydrogen or carbon, which can prevent an increase in the concentration of an impurity such as hydrogen or carbon in a metal oxide to be deposited.

Furthermore, after the deposition of the metal oxide, heat treatment is preferably performed. In particular, the heat treatment is preferably performed without exposure to the air successively after the deposition by an ALD method. The heat treatment is performed at a temperature higher than or equal to 100° C. and lower than or equal to 1200° C., preferably higher than or equal to 200° C. and lower than or equal to 1000° C., further preferably higher than or equal to 250° C. and lower than or equal to 650° C., still further preferably higher than or equal to 300° C. and lower than or equal to 600° C., yet further preferably higher than or equal to 400° C. and lower than or equal to 550° C., still yet further preferably higher than or equal to 420° C. and lower than or equal to 480° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which can improve crystallinity. Thus, a metal oxide having a layered crystal structure with high crystallinity can be formed.

After the deposition of the metal oxide, microwave treatment is preferably performed in an oxygen-containing atmosphere so that the impurity concentration in the metal oxide can be reduced. Specific examples of the impurity include hydrogen and carbon. Here, the microwave treatment refers to, for example, treatment using an apparatus including a power source that generates high-density plasma with use of a microwave.

The microwave treatment in an oxygen-containing atmosphere converts an oxygen gas into plasma using a high-frequency wave such as a microwave or RF and activates the oxygen plasma. The oxygen that works on the metal oxide has any of a variety of forms such as an oxygen atom, an oxygen molecule, an oxygen ion, and an oxygen radical (also referred to as O radical, which is an atom, a molecule, or an ion having an unpaired electron). Note that the oxygen that works on the metal oxide preferably has any one or more of the above forms, particularly preferably an oxygen radical.

The aforementioned microwave treatment in an oxygen-containing atmosphere is preferably performed while the substrate is heated, in which case the impurity concentration in the metal oxide can be further reduced. The substrate heating temperature is higher than or equal to 100° C. and lower than or equal to 650° C., preferably higher than or equal to 200° C. and lower than or equal to 600° C., further preferably higher than or equal to 300° C. and lower than or equal to 450° C.

When the microwave treatment in an oxygen-containing atmosphere is performed while the substrate is heated, the carbon concentration in the metal oxide, which is measured by SIMS, can be lower than 1×10²⁰ atoms/cm³, preferably lower than 1×10¹⁹ atoms/cm³, further preferably lower than 1×10¹⁸ atoms/cm³.

The above-described example in which the microwave treatment in an oxygen-containing atmosphere is performed on the metal oxide is a non-limiting example. For example, the microwave treatment in an oxygen-containing atmosphere may be performed on an insulating film, specifically a silicon oxide film, which is positioned in the vicinity of the metal oxide. For example, microwave treatment may be performed after the deposition of the insulator 250. When the silicon oxide film is subjected to microwave treatment in an oxygen-containing atmosphere, hydrogen contained in the silicon oxide film can be released as H₂O to the outside. Release of hydrogen from the silicon oxide film positioned in the vicinity of the metal oxide can offer a highly reliable memory device.

Note that FIG. 17 illustrates the structure in which the stacked-layer structure including the oxide 613a to the oxide 613c is repeated; however, the present invention is not limited thereto. For example, one, two, or four or more oxides may be repeatedly formed in a metal oxide.

In the description of this specification and the like, in the case of using ozone, oxygen, and water as a reactant or an oxidizer, not only those in gas or molecular states but also those in a plasma state, a radical state, and an ion state are included, unless otherwise specified. In the case where a film is deposited using an oxidizer in a plasma state, a radical state, or an ion state, a radical ALD apparatus or a plasma ALD apparatus, which will be described later, may be used.

In order to remove an impurity such as carbon or hydrogen contained in a precursor, the precursor is preferably made to react with an oxidizer sufficiently. For example, pulse time for introducing an oxidizer may be made longer. Alternatively, an oxidizer may be introduced a plurality of times. In the case where an oxidizer is introduced multiple times, the same kind of oxidizer may be introduced or different kinds of oxidizers may be introduced. For example, after water is introduced as a first oxidizer to the chamber, vacuum evacuation may be performed, ozone or oxygen which does not contain hydrogen may be introduced as a second oxidizer to the chamber, and vacuum evacuation may be performed.

In this manner, the introduction of an oxidizer and the introduction of an inert gas (or vacuum evacuation) in the chamber are repeated a plurality of times in a short time, whereby excess hydrogen atoms, carbon atoms, chlorine atoms, and the like can be more certainly removed from the precursor adsorbed onto the substrate surface, and can be released to the outside of the chamber. When the number of the kinds of the oxidizer is increased to two, more excess hydrogen atoms and the like can be removed from the precursor adsorbed onto the substrate surface. In this manner, hydrogen atoms are prevented from being taken into the film during the deposition, so that water, hydrogen, and the like contained in the formed film can be reduced.

An ALD method is a method in which deposition is performed through reaction of a precursor and a reactant using thermal energy. A temperature required for the reaction between the precursor and the reactant is determined by their temperature characteristics, vapor pressure, decomposition temperature, and the like and is set to higher than or equal to 100° C. and lower than or equal to 600° C., preferably higher than or equal to 200° C. and lower than or equal to 600° C., further preferably higher than or equal to 300° C. and lower than or equal to 600° C.

Moreover, an ALD method in which treatment is performed by introducing a plasma-excited reactant into the chamber as a third source gas in addition to the precursor and the reactant which react with each other is referred to as a plasma ALD method in some cases. In this case, a plasma generation apparatus is provided in the introduction portion of the third source gas. Inductively coupled plasma can be used for plasma generation. On the other hand, an ALD method in which reaction between the precursor and the reactant is performed using thermal energy is sometimes referred to as a thermal ALD method.

In a plasma ALD method, deposition is performed by introducing a plasma-excited reactant in the third step. Alternatively, deposition is performed in such a manner that the first step to the fourth step are repeated while a plasma-excited reactant (a second reactant) is introduced. In this case, the reactant introduced in the third step is referred to as a first reactant. In the plasma ALD method, the same material as the above-described oxidizer can be used for the second reactant used as the third source gas. In other words, plasma-excited ozone, oxygen, and water can be used as the second reactant. Other than the oxidizer, a nitriding agent may be used as the second reactant. As the nitriding agent, nitrogen (N₂) or ammonia (NH₃) can be used. A mixed gas of nitrogen (N₂) and hydrogen (H₂) can also be used as the nitriding agent. For example, a mixed gas of nitrogen (N₂) of 5% and hydrogen (H₂) of 95% can be used as the nitriding agent. Deposition is performed while plasma-excited nitrogen or ammonia is introduced, whereby a nitride film such as a metal nitride film can be formed.

Argon (Ar), helium (He), or nitrogen (N₂) may be used as a carrier gas for the second reactant. The use of a carrier gas such as argon, helium, or nitrogen is preferable because plasma is easily discharged and the plasma-excited second reactant is easily generated. Note that in the case where an oxide film such as a metal oxide film is formed by a plasma ALD method and nitrogen is used as a carrier gas, nitrogen enters the film and a desired film quality cannot be obtained in some cases. In this case, argon or helium is preferably used as the carrier gas.

By an ALD method, an extremely thin film can be deposited to have a uniform thickness. In addition, the coverage of an uneven surface with the film is high.

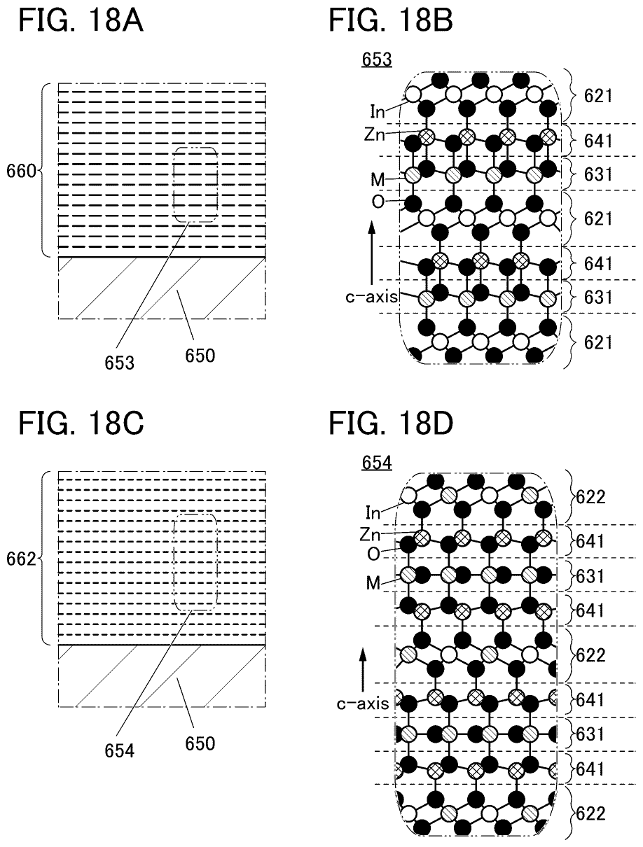

Here, atomic arrangement in the crystal when the metal oxide having a layered crystal structure is an In-M-Zn oxide is described with reference to FIG. 18A to FIG. 18D. In FIG. 18B and FIG. 18D, an atom is represented by a sphere (a circle) and a bond between a metal atom and an oxygen atom is represented by a line. In FIG. 18B and FIG. 18D, the c-axis direction in the crystal structure of the In-M-Zn oxide is indicated by the arrows in the diagrams. The a-b plane direction in the crystal structure of the In-M-Zn oxide is the direction perpendicular to the c-axis direction indicated by the arrows in FIG. 18B and FIG. 18D.

FIG. 18A is a diagram illustrating an oxide 660 including an In-M-Zn oxide formed on a structure body 650. Here, the structure body refers to a component included in a semiconductor device such as a transistor. The structure body 650 includes a substrate, conductors such as a gate electrode, a source electrode, and a drain electrode, insulators such as a gate insulating film, an interlayer insulating film, and a base insulating film, semiconductors such as a metal oxide and silicon, and the like. In FIG. 18A, a deposition surface of the structure body 650 is placed parallel to a substrate (or a base, not illustrated).

FIG. 18B is an enlarged view illustrating the atomic arrangement in the crystal in a region 653, which is part of the oxide 660 in FIG. 18A. The composition of the oxide 660 illustrated in FIG. 18A and FIG. 18B is In:M:Zn=1:1:1 [atomic ratio], and the crystal structure is a YbFe₂O₄ type structure. The element M is a metal element having a valence of +3.

As illustrated in FIG. 18B, the crystal included in the oxide 660 has repetitive stacking of a layer 621 containing indium (In) and oxygen, a layer 631 containing the element M and oxygen, and a layer 641 containing zinc (Zn) and oxygen in this order. The layer 621, the layer 631, and the layer 641 are placed substantially parallel to the deposition surface of the structure body 650. That is, the a-b plane of the oxide 660 is substantially parallel to the deposition surface of the structure body 650, and the c-axis of the oxide 660 is substantially parallel to the normal direction of the deposition surface of the structure body 650.

When the layer 621, the layer 631, and the layer 641 included in the above crystal are each composed of one metal element and oxygen as illustrated in FIG. 18B, arrangement with favorable crystallinity is achieved to increase the mobility of the metal oxide.

Note that the In-M-Zn oxide with In:M:Zn=1:1:1 [atomic ratio] is not limited to the structure illustrated in FIG. 18B. The stacking order of the layer 621, the layer 631, and the layer 641 may be changed. For example, the layer 621, the layer 641, and the layer 631 may be stacked repeatedly in this order. Alternatively, the layer 621, the layer 631, the layer 641, the layer 621, the layer 641, and the layer 631 may be stacked repeatedly in this order. Part of the element M in the layer 631 may be replaced with zinc and part of zinc in the layer 641 may be replaced with the element M.

Although an example of forming the In-M-Zn oxide whose composition is In:M:Zn=1:1:1 [atomic ratio] is described above, a crystalline In-M-Zn oxide whose composition formula is represented by In_{(1+α)}M_{(1-α)}O₃(ZnO)ₘ (is a real number greater than 0 and less than 1 and m is a positive number) can have a layered crystal structure in a similar manner. As an example, an In-M-Zn oxide with In:M:Zn=1:3:4 [atomic ratio] is described with reference to FIG. 18C and FIG. 18D.

FIG. 18C is a diagram illustrating an oxide 662 including an In-M-Zn oxide formed on the structure body 650. FIG. 18D is an enlarged view illustrating the atomic arrangement in the crystal in a region 654, which is part of the oxide 662 in FIG. 18C.

As illustrated in FIG. 18D, the crystal included in the oxide 662 includes a layer 622 containing indium (In), the element M, and oxygen, the layer 641 containing zinc (Zn) and oxygen, and the layer 631 containing the element M and oxygen. In the oxide 662, the plurality of layers are stacked repeatedly in the order of the layer 622, the layer 641, the layer 631, and the layer 641. The layer 622, the layer 631, and the layer 641 are placed substantially parallel to the deposition surface of the structure body 650. That is, the a-b plane of the oxide 662 is substantially parallel to the deposition surface of the structure body 650, and the c-axis of the oxide 662 is substantially parallel to the normal direction of the deposition surface of the structure body 650.

Note that the In-M-Zn oxide with In:M:Zn=1:3:4 [atomic ratio] is not limited to the structure illustrated in FIG. 18D, and the structure may change within a range where In:M:Zn=1:3:4 [atomic ratio] is maintained. The stacking order of the layer 622, the layer 631, and the layer 641 may be changed, for example. Part of the element M in the layer 631 may be replaced with zinc and part of zinc in the layer 641 may be replaced with the element M. The layer 621 or the layer 631 may be formed instead of the layer 622.

### <In-M-Zn Oxide>

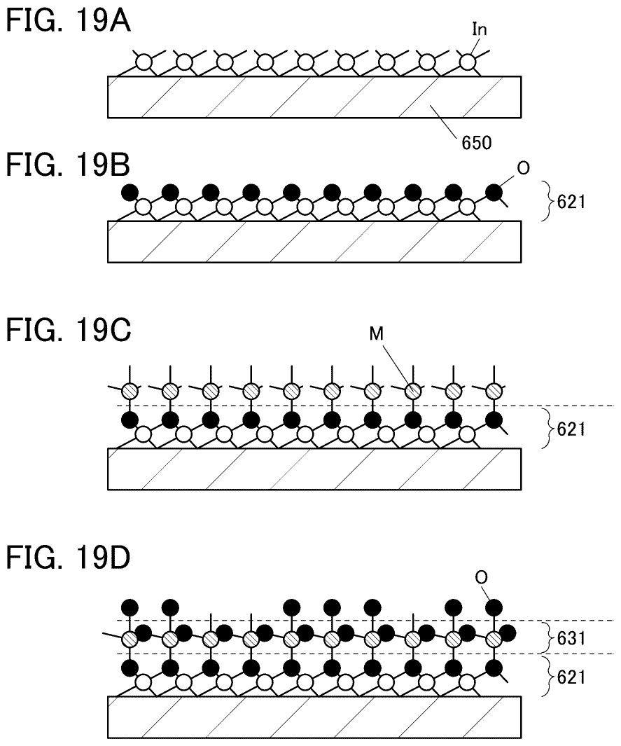

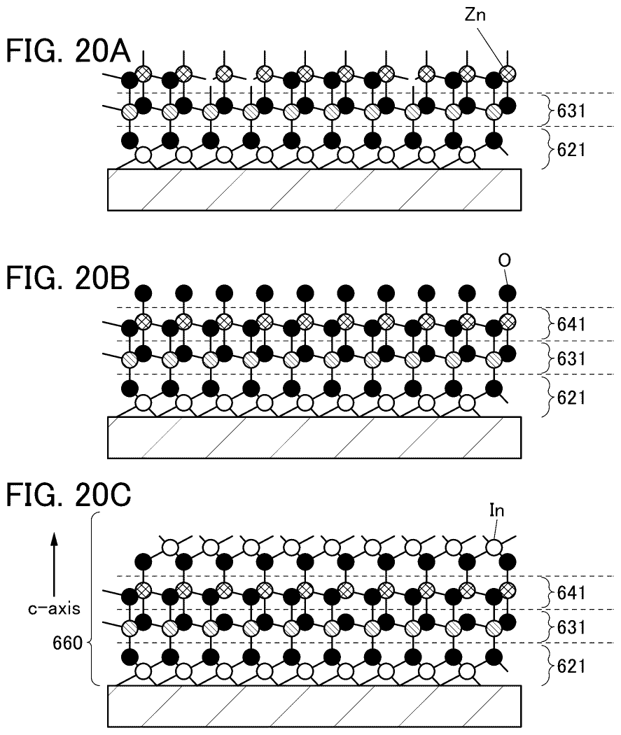

Next, details of a method for forming the oxide 660 including the In-M-Zn oxide illustrated in FIG. 18A and FIG. 18B are described with reference to FIG. 19A to FIG. 20C.

First, a source gas that contains a precursor containing indium is introduced into a chamber, so that the precursor is adsorbed onto the surface of the structure body 650 (see FIG. 19A). Here, the source gas contains a carrier gas such as argon, helium, or nitrogen in addition to the precursor. As the precursor containing indium, trimethylindium, triethylindium, tris(2,2,6,6-tetramethyl-3,5-heptanedionato)indium, cyclopentadienylindium, indium(III)acetylacetonate, (3-(dimethylamino)propyl)dimethylindium, or the like can be used.

As the precursor containing indium, an inorganic precursor not containing hydrocarbon may be used. As an inorganic precursor containing indium, a halogen-based indium compound such as indium trichloride, indium tribromide, or indium triiodide can be used. The decomposition temperature of indium trichloride is approximately higher than or equal to 500° C. and lower than or equal to 700° C. Thus, with use of indium trichloride, deposition can be performed by an ALD method while a substrate is being heated at approximately higher than or equal to 400° C. and lower than or equal to 600° C., for example, at 500° C.

Next, introduction of the source gas is stopped and the chamber is purged, whereby a surplus precursor, a reaction product, and the like are released from the chamber.

Then, an oxidizer is introduced as a reactant into the chamber to react with the adsorbed precursor, and components other than indium are released while indium is adsorbed onto the substrate, so that the layer 621 in which indium and oxygen are bonded to each other is formed (see FIG. 19B). Ozone, oxygen, water, or the like can be used as the oxidizer. Then, introduction of the oxidizer is stopped and the chamber is purged, whereby a surplus reactant, a reaction product, and the like are released from the chamber.

Subsequently, a source gas that contains a precursor containing the element M is introduced into the chamber, so that the precursor is adsorbed onto the layer 621 (see FIG. 19C). The source gas contains a carrier gas such as argon, helium, or nitrogen in addition to the precursor. In the case where gallium is used as the element M, trimethylgallium, triethylgallium, tris(dimethylamido)gallium, gallium(III) acetylacetonate, tris(2,2,6,6-tetramethyl-3,5-heptanedionato)gallium, dimethylchlorogallium, diethylchlorogallium, dimethyl gallium isopropoxide, or the like can be used as the precursor containing gallium.

As the precursor containing gallium, an inorganic precursor not containing hydrocarbon may be used. As an inorganic precursor containing gallium, a halogen-based gallium compound such as gallium trichloride, gallium tribromide, or gallium triiodide can be used. The decomposition temperature of gallium trichloride is approximately higher than or equal to 550° C. and lower than or equal to 700° C. Thus, with use of gallium trichloride, deposition can be performed by an ALD method while a substrate is being heated at approximately higher than or equal to 450° C. and lower than or equal to 650° C., for example, at 550° C.

Next, introduction of the source gas is stopped and the chamber is purged, whereby a surplus precursor, a reaction product, and the like are released from the chamber.

Then, an oxidizer is introduced as a reactant into the chamber to react with the adsorbed precursor, and components other than the element M are released while the element Mis adsorbed onto the substrate, so that the layer 631 in which the element M and oxygen are bonded to each other is formed (see FIG. 19D). At this time, part of oxygen included in the layer 641 may be adsorbed onto the layer 631. Then, introduction of the oxidizer is stopped and the chamber is purged, whereby a surplus reactant, a reaction product, and the like are released from the chamber.

Subsequently, a source gas that contains a precursor containing zinc is introduced into the chamber, so that the precursor is adsorbed onto the layer 631 (see FIG. 20A). At this time, part of the layer 641 in which zinc is bonded to oxygen is formed in some cases. The source gas contains a carrier gas such as argon, helium, or nitrogen in addition to the precursor. Dimethylzinc, diethylzinc, bis(2,2,6,6-tetramethyl-3,5-heptanedionato) zinc, zinc acetate, or the like can be used as the precursor containing zinc.

As the precursor containing zinc, an inorganic precursor not containing hydrocarbon may be used. As an inorganic precursor containing zinc, a halogen-based zinc compound such as zinc dichloride, zinc dibromide, or zinc diiodide can be used. The decomposition temperature of zinc dichloride is approximately higher than or equal to 450° C. and lower than or equal to 700° C. Thus, with use of zinc dichloride, deposition can be performed by an ALD method while a substrate is being heated at approximately higher than or equal to 350° C. and lower than or equal to 550° C., for example, at 450° C.

Next, introduction of the source gas is stopped and the chamber is purged, whereby a surplus precursor, a reaction product, and the like are released from the chamber.

Then, an oxidizer is introduced as a reactant into the chamber to react with the adsorbed precursor, and components other than zinc are released while zinc is adsorbed onto the substrate, so that the layer 641 in which zinc and oxygen are bonded to each other is formed (see FIG. 20B). Then, introduction of the oxidizer is stopped and the chamber is purged, whereby a surplus reactant, a reaction product, and the like are released from the chamber.

Next, the layer 621 is formed again over the layer 641 by the above-described method (see FIG. 20C). By repeating the above-described method, the oxide 660 can be formed over the substrate or the structure body.

Some of the above-described precursors each containing the metal element further contain one or both of carbon and chlorine. A film that is formed using a precursor containing carbon may contain carbon. A film that is formed using a precursor containing a halogen such as chlorine may contain a halogen such as chlorine.

As described above, the oxide 660 is formed by an ALD method, whereby the metal oxide in which the c-axis is aligned substantially parallel to the normal direction of the deposition surface can be formed. For example, in the oxide semiconductor 230 illustrated in FIG. 1B and FIG. 1C according to the above embodiment, a layered crystal substantially parallel to the sidewall of the insulator 250 can be formed. With this structure, the layered crystals of the oxide semiconductor 230 are formed substantially parallel to the channel length direction of the transistor 200, so that the on-state current of the transistor can be increased.

The steps illustrated in FIG. 19A to FIG. 20C are preferably performed while the substrate is being heated. For example, the substrate temperature is higher than or equal to 200° C. and lower than or equal to 600° C., preferably higher than or equal to 300° C. and lower than or equal to the precursor decomposition temperature.

In order to perform deposition while the substrate is being heated in the above temperature range, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, an inorganic precursor is preferably used. In general, an inorganic precursor tends to have a higher decomposition temperature than an organic precursor, so that even when deposition is performed while the substrate is being heated as described above, the precursor is hardly decomposed.

As the inorganic precursor, for example, the above indium trichloride, gallium trichloride, or zinc dichloride can be used. As described above, the decomposition temperature of each of these precursors is approximately higher than or equal to 350° C. and lower than or equal to 700° C., which is much higher than the decomposition temperature of a common organic precursor. Note that as described above, the decomposition temperatures of indium trichloride, gallium trichloride, and zinc dichloride are different from each other. In the case where deposition is performed by an ALD method with use of a plurality of different kinds of precursors, the substrate temperature is preferably lower than or equal to the lowest precursor decomposition temperature among the plurality of precursors. In the above example, the substrate temperature may be set within a range where zinc dichloride having the lowest precursor decomposition temperature is not decomposed. Accordingly, indium trichloride and gallium trichloride can also be adsorbed onto an object (e.g., a substrate) without being decomposed.

FIG. 19A to FIG. 20C illustrate an example in which the layer 621 is formed as a layer containing indium, the layer 631 is formed thereover as a layer containing the element M, and further the layer 641 is formed thereover as a layer containing zinc; however, this embodiment is not limited to the example. One of the layer 631 and the layer 641 may be formed, the layer 621 may be formed thereover, and further the other of the layer 631 and the layer 641 may be formed thereover. Alternatively, one of the layer 631 and the layer 641 may be formed, the other of the layer 631 and the layer 641 may be formed thereover, and further the layer 621 may be formed thereover.

In the case of forming a metal oxide with an atomic ratio that is different from In:M:Zn=1:1:1 [atomic ratio], the above-described layer 621, layer 631, and layer 641 may be formed as appropriate in accordance with the atomic ratio. For example, the formation of the layer 641 may be repeated a plurality of times before and after the formation of the layer 631 illustrated in FIG. 20A so that a stack including the layers 631 and the layers 641 and having the desired number of atoms and layers and a desired thickness is formed between two layers 621.

### <Oxide Containing in and Sn>

Next, a method for forming an oxide containing indium and tin is described.

First, a source gas that contains a precursor containing indium is introduced into a chamber, so that the precursor is adsorbed onto the surface of a formation surface. Here, the source gas contains a carrier gas such as argon, helium, or nitrogen in addition to the precursor.

As the precursor containing indium, trimethylindium, triethylindium, tris(2,2,6,6-tetramethyl-3,5-heptanedionato)indium, cyclopentadienylindium, indium(III)acetylacetonate, (3-(dimethylamino)propyl)dimethylindium, or the like can be used.

As the precursor containing indium, an inorganic precursor not containing hydrocarbon may be used. As an inorganic precursor containing indium, a halogen-based indium compound such as indium trichloride, indium tribromide, or indium triiodide can be used. The decomposition temperature of indium trichloride is approximately higher than or equal to 500° C. and lower than or equal to 700° C. Thus, with use of indium trichloride, deposition can be performed by an ALD method while a substrate is being heated at approximately higher than or equal to 400° C. and lower than or equal to 600° C., for example, at 500° C.

Next, introduction of the source gas is stopped and the chamber is purged, whereby a surplus precursor, a reaction product, and the like are released from the chamber.

Then, an oxidizer is introduced as a reactant into the chamber to react with the adsorbed precursor, and components other than indium are released while indium is adsorbed onto the substrate, so that a layer in which indium and oxygen are bonded to each other is formed. Ozone, oxygen, water, or the like can be used as the oxidizer. Then, introduction of the oxidizer is stopped and the chamber is purged, whereby a surplus reactant, a reaction product, and the like are released from the chamber.

Subsequently, a source gas that contains a precursor containing tin is introduced into the chamber, so that the precursor is adsorbed on the layer in which indium and oxygen are bonded to each other. The source gas contains a carrier gas such as argon, helium, or nitrogen in addition to the precursor.

As the precursor containing tin, tetrakis(dimethylamido)tin, tin(II) acetylacetonate, tin tetrachloride, or the like can be used.

Next, introduction of the source gas is stopped and the chamber is purged, whereby a surplus precursor, a reaction product, and the like are released from the chamber.

Then, an oxidizer is introduced as a reactant into the chamber to react with the adsorbed precursor, and components other than tin are released while tin is adsorbed onto the substrate, so that a layer in which tin and oxygen are bonded to each other is formed. Part of oxygen contained in the layer formed at this time is sometimes adsorbed on the layer formed earlier in which indium and oxygen are bonded to each other. Then, introduction of the oxidizer is stopped and the chamber is purged, whereby a surplus reactant, a reaction product, and the like are released from the chamber.

By repeatedly forming the layer in which indium and oxygen are bonded to each other and the layer in which tin and oxygen are bonded to each other, an oxide containing indium and tin can be formed over the substrate or the structure body.

The formation of the layer in which indium and oxygen are bonded to each other and the formation of the layer in which tin and oxygen are bonded to each other are not necessarily repeated alternately; the formation of one of the layers may be repeated a plurality of times and then the formation of the other may be performed once or repeated a plurality of times. For example, in the case where a metal oxide having an atomic ratio different from In:Sn=1:1 [atomic ratio] is formed, the layer in which indium and oxygen are bonded to each other and the layer in which tin and oxygen are bonded to each other are formed as appropriate in accordance with the atomic ratio.

The metal oxide may be formed to contain another element in addition to indium and tin. A metal oxide containing indium, tin, and silicon is described below.

### <Oxide Containing in, Sn, and Si>

As a precursor containing silicon, an aminosilane-based precursor can be used. Examples of the aminosilane-based precursor include BTBAS (bistertiarybutylaminosilane), BDMAS (bisdimethylaminosilane), BDEAS (bisdiethylaminosilane), DMAS (dimethylaminosilane), DEAS (diethylaminosilane), DPAS (dipropylaminosilane), BAS (butylaminosilane), DIPAS (diisopropylaminosilane), BEMAS (bisethylmethylaminosilane), and TDMAS (tridimethylaminosilane).

Examples of the precursor containing silicon include an ethoxysilane-based precursor such as TEOS (tetraethoxysilane).

Examples of the precursor containing silicon include a silicon compound having an isocyanate group, such as “CH₃ₙ—Si—(NCO)₄₋ₙ (n is greater than or equal to 0 and less than or equal to 3)” or “H—Si—(NCO)₃”. Alternatively, as the precursor, a gas containing silicon and no hydrocarbon (also referred to as an inorganic precursor), such as SiH₄, Si₂H₆, SiF₄, SiCl₄, SiBr₄, SiH₂Cl₂, or SiH₂I₂ may be used.

After silicon is adsorbed onto the formation surface with use of the precursor containing silicon, a layer in which silicon and oxygen are bonded to each other can be formed with use of an oxidizer. Thus, by repeatedly forming the layer in which indium and oxygen are bonded to each other, the layer in which tin and oxygen are bonded to each other, and the layer in which silicon and oxygen are bonded to each other, a metal oxide containing indium, tin, and silicon can be formed.

### <Silicon Oxide>

After silicon is adsorbed onto the formation surface with use of the above-described precursor containing silicon, a silicon oxide layer can be formed by an ALD method with use of an oxidizer.

At least part of the structure, method, and the like described in this embodiment can be implemented in appropriate combination with any of the other embodiments described in this specification.

### Embodiment 3

In this embodiment, a structure example of the memory device of one embodiment of the present invention and the like are described.

### Structure Example of Memory Cell Array

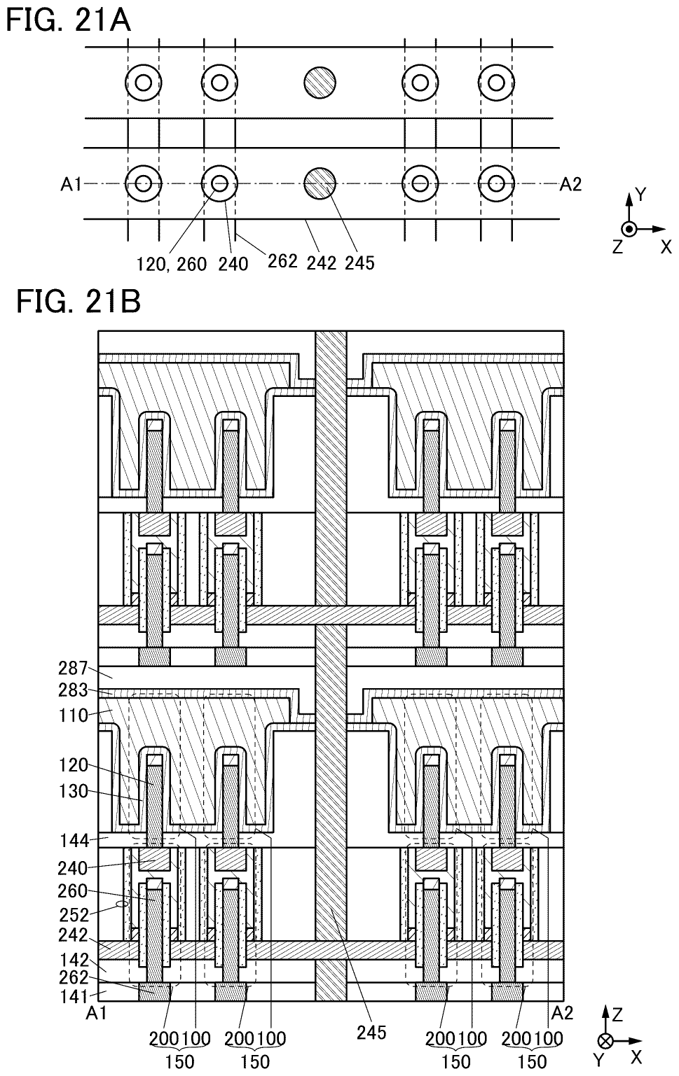

The memory cells 150 can be three-dimensionally arranged in a matrix to form a memory cell array. As an example of the memory cell array, FIG. 21A and FIG. 21B illustrate an example of a memory device in which 4×2×2 memory cells 150 are arranged in the X direction, the Y direction, and the Z direction. FIG. 21A is a plan view of the memory device. FIG. 21B is a cross-sectional view of a portion indicated by the dashed-dotted line A1-A2 in FIG. 21A. Note that some components are not illustrated in the plan view of FIG. 21A for clarity of the drawing.

The conductor 260 functioning as the wiring WL is provided in each memory cell 150. The conductor 242 functioning as part of the wiring BL is shared by adjacent memory cells 150 in the X direction. That is, the conductor 242 is in contact with the oxide semiconductors 230 included in two adjacent memory cells 150. Since the conductor 242 is shared by the adjacent memory cells 150, integration of the memory device can be achieved.

The conductor 242 of the memory cell 150 is electrically connected to a conductor 245 functioning as a plug (which can also be referred to as a connection electrode). The conductor 245 is placed in an opening formed in the insulator 252, the insulator 144, the insulator 130, an insulator 283, and an insulator 287 and in the insulator 141 and the insulator 142 of a layer where the upper memory cell is provided, and is in contact with the top surface of the conductor 242. Note that a conductive material or the like that can be used for the conductor 240 can be used for the conductor 245.

The insulator 283 preferably has a barrier property against oxygen. The insulator 283 preferably has a barrier property against hydrogen. As the insulator 283, a single layer or stacked layers of the insulator having a barrier property against oxygen, the insulator having a barrier property against hydrogen, or the like described in the section [Insulator] above can be used as appropriate.

The insulator 287, which functions as an interlayer film, preferably has a low dielectric constant. When a material with a low dielectric constant is used for an interlayer film, parasitic capacitance generated between wirings can be reduced. As the insulator 287, a single layer or stacked layers of the insulator containing any of the materials with low dielectric constants described in the section [Insulator] above can be used.

The concentration of impurities such as water and hydrogen in the insulator 287 is preferably reduced. This can inhibit entry of impurities such as water and hydrogen into the channel formation region of the oxide semiconductor 230.

The conductor 245 functions as a plug or a wiring for electrically connecting the memory cell 150 to a circuit element such as a switch, a transistor, a capacitor, an inductor, a resistor, or a diode, a wiring, an electrode, or a terminal. For example, a structure can be employed in which the conductor 245 is electrically connected to a sense amplifier (not illustrated) provided below the memory device.

The conductor 245 is electrically connected to the upper stacked memory cell and can function as part of the wiring BL.

Two of the memory cells 150 adjacent to each other with the conductor 245 therebetween have a line-symmetric structure with respect to the perpendicular bisector of the dashed-dotted line A1-A2 as the symmetric axis. Thus, the transistors 200 included in the memory cells 150 are also placed in line-symmetric positions with the conductor 245 therebetween.

Note that the conductor 110 functioning as the wiring PL may be provided for each memory cell 150 or may be shared by a plurality of memory cells 150. However, the conductor 110 is provided to be apart from the conductor 245 so that the conductor 110 and the conductor 245 are not short-circuited.

When a plurality of memory cells are stacked as illustrated in FIG. 21, cells can be placed in an integrated manner without increasing the area occupied by the memory cell array. In other words, a 3D memory cell array can be formed. Although FIG. 21 illustrates a structure in which four layers each including two memory units are stacked, the present invention is not limited thereto. The memory device may include one layer or two or more stacked layers each including at least one memory cell 150.

FIG. 21 illustrates a structure in which the conductor 245 functioning as a plug is placed between the adjacent memory cells 150. Note that the present invention is not limited thereto. FIG. 21 illustrates the conductor 245 functioning as a plug that penetrates the insulator 252, the insulator 144, the insulator 130, the insulator 283, the insulator 287, and the insulator 141 and the insulator 142 where the upper memory cell is formed; however, the conductors 242 included in the upper and lower memory cells may be connected using a plurality of plugs. For example, a plug may be provided in each insulator, or a plurality of plugs each penetrating two or more insulators can be used to connect the conductors 242 included in the upper and lower memory cells.

### Structure Example of Memory Device

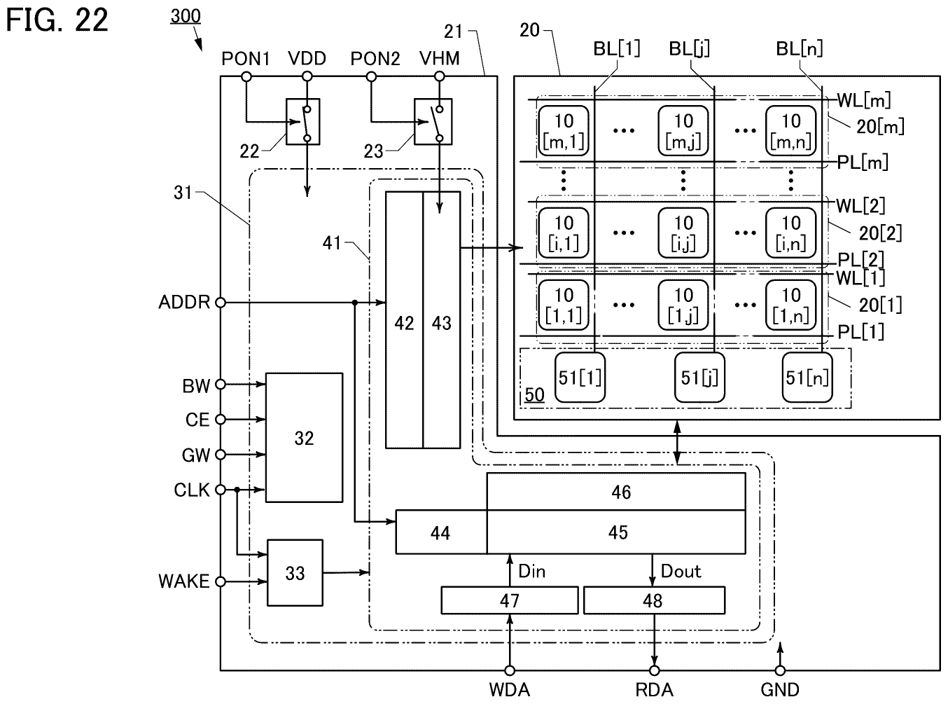

FIG. 22 is a block diagram illustrating a structure example of a memory device 300 of one embodiment of the present invention. The memory device 300 illustrated in FIG. 22 includes a driver circuit 21 and a memory array 20. The memory array 20 includes a plurality of memory cells 10 and a functional layer 50 including a plurality of functional circuits 51.

FIG. 22 illustrates an example in which the memory array 20 includes the plurality of memory cells 10 arranged in a matrix of m rows and n columns (each of m and n is an integer greater than or equal to 2). The functional circuit 51 is provided for each wiring BL functioning as a bit line, for example. The plurality of functional circuits 51 corresponding to n of the wirings BL are provided in the example illustrated in FIG. 22.

In FIG. 22, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is referred to as a memory cell 10[i,j]. Note that in this embodiment and the like, “i+α” (α is a positive or negative integer) is not below 1 and does not exceed m. Similarly, “j+α” is not below 1 and does not exceed n.

The memory array 20 includes m wirings WL extending in the row direction, m wirings PL extending in the row direction, and n wirings BL extending in the column direction. In this embodiment and the like, an i-th (i-th row) wiring WL is referred to as a wiring WL[i]. A first (first row) wiring WL can be referred to as a wiring WL[1], a second (second row) wiring WL can be referred to as a wiring WL[2], and an m-th (m-th row) wiring WL can be referred to as a wiring WL[m]. Similarly, an i-th (i-th row) wiring PL is referred to as a wiring PL[i]. A first (first row) wiring PL can be referred to as a wiring PL[1], a second (second row) wiring PL can be referred to as a wiring PL[2], and an m-th (m-th row) wiring PL can be referred to as a wiring PL[m]. Similarly, a j-th (j-th column) wiring BL is referred to as a wiring BL[j]. A first (first column) wiring BL can be referred to as a wiring BL[1], a second (second column) wiring BL can be referred to as a wiring BL[2], and an n-th (n-th column) wiring BL can be referred to as a wiring BL[n].

The plurality of memory cells 10 provided in the i-th row are electrically connected to the wiring WL in the i-th row (wiring WL[i], not illustrated) and the wiring PL in the i-th row (wiring PL[i], not illustrated). The plurality of memory cells 10 provided in the j-th column are electrically connected to the wiring BL in the j-th column (wiring BL[j]).

A DOSRAM (registered trademark) (Dynamic Oxide Semiconductor Random Access Memory) can be used for the memory array 20. A DOSRAM is a RAM including a 1T (transistor) 1C (capacitor) type memory cell and refers to a memory in which an access transistor is a transistor containing an oxide semiconductor in its channel formation region (hereinafter also referred to as an “OS transistor”). An OS transistor has extremely low current that flows between a source and a drain in an off state, that is, leakage current. A DOSRAM can retain electric charges corresponding to data stored in a capacitor for a long time by turning off an access transistor (a non-conduction state). For this reason, the refresh operation frequency of a DOSRAM can be lower than that of a DRAM formed with a transistor containing silicon in its channel formation region (hereinafter also referred to as a “Si transistor”). As a result, power consumption can be reduced.

The memory cells 10 can be provided in stacked layers by stacking OS transistors as described in Embodiment 1 and the like. For example, in the memory array 20 illustrated in FIG. 22, a plurality of memory arrays 20[1] to 20[m] can be provided in stacked layers. When the memory arrays 20[1] to 20[m] included in the memory array 20 are provided in a direction perpendicular to a surface of the substrate provided with the driver circuit 21, the memory density of the memory cells 10 can be increased. The memory array 20 can be fabricated by repeating the same manufacturing process in the perpendicular direction. The manufacturing cost of the memory array 20 in the memory device 300 can be reduced.

The wiring BL functions as a bit line for writing and reading data. The wiring WL functions as a word line for controlling on and off states (conduction and non-conduction states) of an access transistor serving as a switch. The wiring PL has a function of a constant potential line connected to a capacitor.

The memory cell 10 included in each of the memory arrays 20[1] to 20[m] is connected to the functional circuit 51 through the wiring BL. The wiring BL can be provided in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced, so that power consumption and signal delays can be reduced. Moreover, even when the capacitance of the capacitors included in the memory cells 10 is reduced, operation is possible.

The functional circuit 51 has functions of amplifying a data potential retained in the memory cell 10 and outputting the amplified data potential to a sense amplifier 46 included in the driver circuit 21 through a wiring GBL (not illustrated) described later. With this structure, a slight difference in the potential of the wiring BL can be amplified at the time of data reading. Like the wiring BL, the wiring GBL can be provided in the direction perpendicular to the surface of the substrate provided with the driver circuit 21. Since the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

Note that the wiring BL is provided in contact with the semiconductor layer of the transistor included in the memory cell 10. Alternatively, the wiring BL is provided in contact with the region functioning as the source or the drain in the semiconductor layer of the transistor included in the memory cell 10. Alternatively, the wiring BL is provided in contact with the conductor provided in contact with the region functioning as the source or the drain in the semiconductor layer of the transistor included in the memory cell 10. That is, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, resistance and parasitic capacitance between the driver circuit 21 and the memory array 20 are reduced, so that power consumption and signal delays can be reduced. In addition, the memory device 300 can be downsized.

The functional circuit 51 can be provided in any desired position, e.g., over a circuit that is formed using Si transistors in a manner similar to that of the memory arrays 20[1] to 20[m] when the functional circuit 51 is formed with an OS transistor like the transistor included in the memory cell 10 of the DOSRAM, whereby integration can be easily performed. With the structure in which a signal is amplified by the functional circuit 51, a circuit in a subsequent stage, such as the sense amplifier 46, can be downsized, so that the memory device 300 can be downsized.

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 300. For example, the control circuit performs a logical operation on the signal CE, the signal GW, and the signal BW to determine an operation mode (e.g., a writing operation or a reading operation) of the memory device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 is a circuit which outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data

(Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 300, a high power supply voltage is VDD and a low power supply voltage is GND (a ground potential). In addition, VHM is a high power supply voltage used to set a word line at a high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 22 but can be more than one. In that case, a power switch is provided for each power domain.

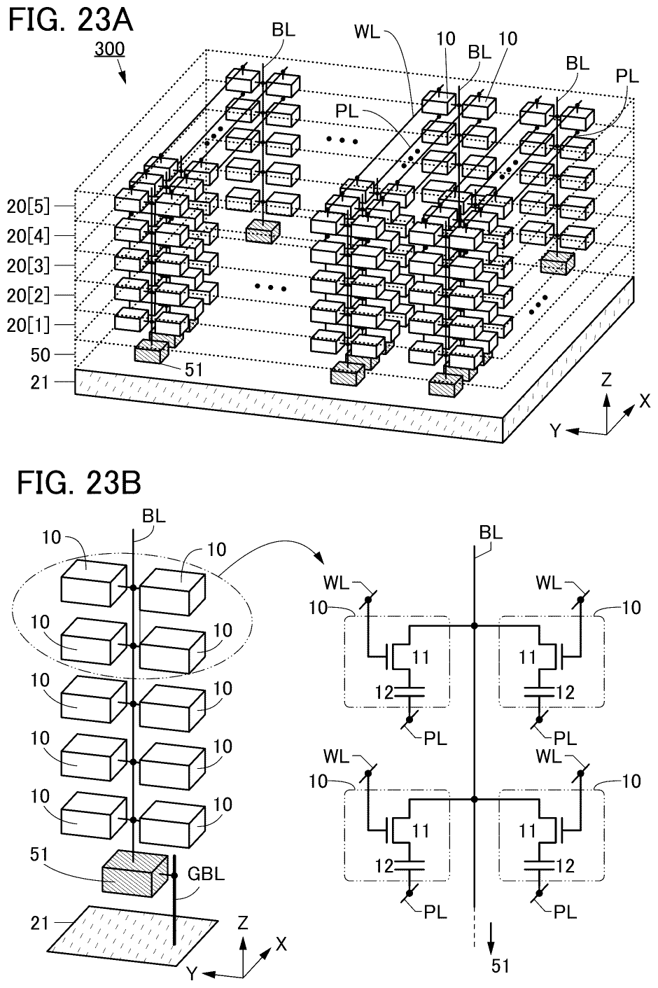

In the memory array 20 including the memory arrays 20[1] to 20[m] (m is an integer greater than or equal to 2) and the functional layer 50, the memory arrays 20 can be provided in stacked layers over the driver circuit 21. Stacking the memory arrays 20 in the plurality of layers can increase the memory density of the memory cells 10. FIG. 23A illustrates a perspective view of the memory device 300 which shows that five layers (m=5) of memory arrays 20[1] to 20[5] and the functional layer 50 are provided to overlap with each other over the driver circuit 21.

In FIG. 23A, the memory array 20 in the first layer is denoted as the memory array 20[1], the memory array 20 in the second layer is denoted as the memory array 20[2], and the memory array 20 in the fifth layer is denoted as the memory array 20[5]. FIG. 23A also illustrates the wiring WL and the wiring PL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 20 are not illustrated. Although FIG. 23A illustrates the structure in which the wiring PL extends in the X direction, the present invention is not limited thereto. For example, the wiring PL may extend in the Y direction, or the wiring PL may extend in the X direction and the Y direction; for example, the wiring PL may be provided in a planar shape.

FIG. 23B illustrates a schematic view for describing a structure example of the functional circuit 51, which is connected to the wiring BL, and the memory cells 10 included in the memory arrays 20[1] to 20[5], which are connected to the wiring BL, illustrated in FIG. 23A. FIG. 23B also illustrates the wiring GBL provided between the functional circuit 51 and the driver circuit 21. Note that a structure in which a plurality of memory cells (memory cells 10) are electrically connected to one wiring BL is also referred to as “memory string”. In the drawings, the wiring GBL in some cases is represented by a bold line for increasing visibility.

FIG. 23B illustrates an example of a circuit structure of the memory cell 10 connected to the wiring BL. The memory cell 10 includes a transistor 11 and a capacitor 12. As for the transistor 11, the capacitor 12, and the wirings (e.g., BL and WL), for example, the wiring BL[1] and the wiring WL[1] are referred to as the wiring BL and the wiring WL in some cases.

In the memory cell 10, one of a source and a drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL.

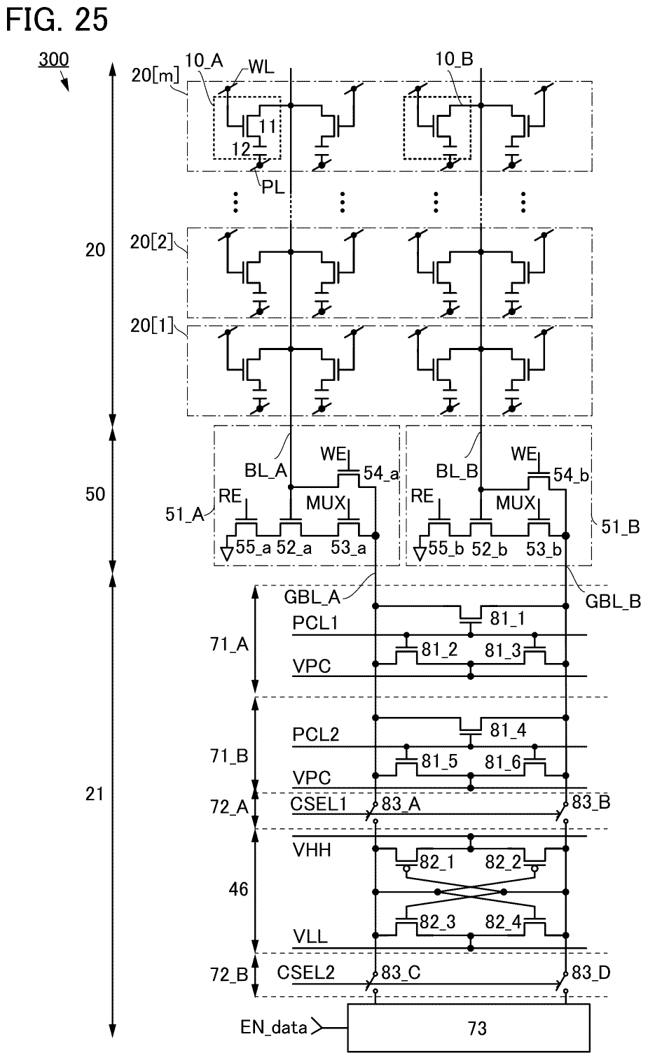

For example, the two memory cells 10 connected to the common wiring BL in the same layer can have the structure illustrated in FIG. 25 according to Embodiment 1.

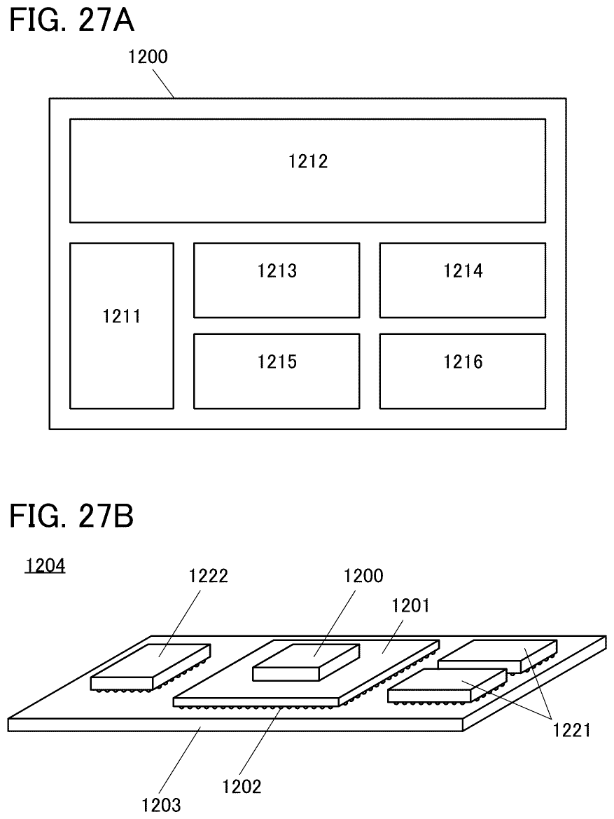

Although FIG. 23B and the like illustrate the structure in which two memory cells 10 are connected to the common wiring BL in the same layer, the present invention is not limited thereto. For example, four memory cells 10 may be connected to the common wiring BL in the same layer or eight memory cells 10 may be connected to the common wiring BL in the same layer. For example, in the case where four memory cells 10 connected to the common wiring BL in the same layer are provided, the structure illustrated in FIG. 27 according to Embodiment 1 can be employed.

The wiring PL is a wiring for supplying a constant potential for retaining the potential of the capacitor 12.

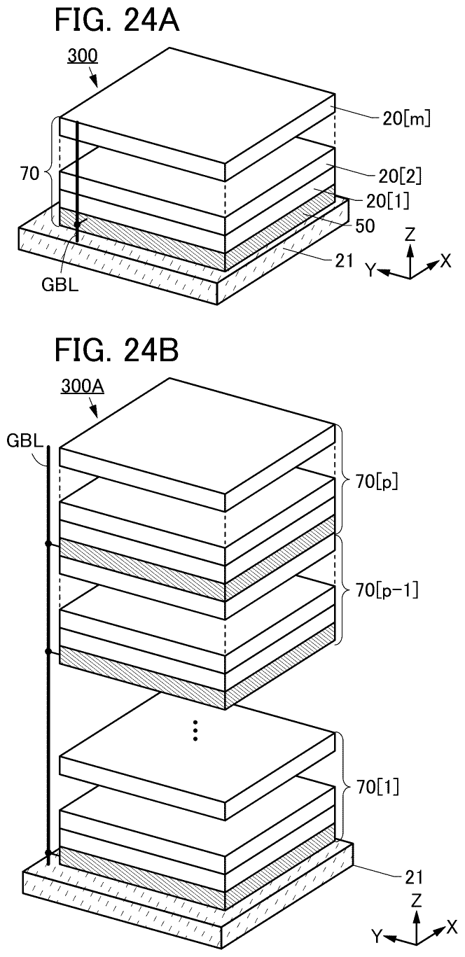

The wiring GBL illustrated in FIG. 23B is provided to electrically connect the driver circuit 21 and the functional circuit 51. FIG. 24A illustrates a schematic view of the memory device 300 in which the functional layer 50 and the memory arrays 20[1] to 20[m] are regarded as a repeating unit 70. Note that although FIG. 24A illustrates one wiring GBL, the wiring GBL is provided as appropriate depending on the number of functional circuits 51 provided in the functional layer 50.

Note that the wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. That is, the wiring GBL can be regarded as a wiring for electrically connecting the driver circuit 21 and one of the source and the drain of the transistor included in the functional circuit 51 in the functional layer 50 in the perpendicular direction.

The repeating unit 70 including the functional circuit 51 and the memory arrays 20[1] to 20[m] may have a stacked-layer structure. A memory device 300A of one embodiment of the present invention can include repeating units 70[1] to 70[p] (p is an integer greater than or equal to 2) as illustrated in FIG. 24B. The wiring GBL is connected to the functional layers 50 included in the repeating unit 70. The wiring GBL is provided as appropriate depending on the number of functional circuits 51.

In one embodiment of the present invention, OS transistors are provided in stacked layers and a wiring functioning as a bit line is provided in the direction perpendicular to the surface of the substrate provided with the driver circuit 21. Since the wiring provided to extend from the memory array 20 and function as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the memory device 300 can be downsized. Moreover, even when the capacitance of the capacitors 12 included in the memory cells 10 is reduced, operation is possible.

### Structure Examples of Memory Array 20 and Functional Circuit 51

A structure example of the functional circuit 51 and structure examples of the memory array 20 and the sense amplifier 46 included in the driver circuit 21, which are described with reference to FIG. 22 to FIG. 24, are described with reference to FIG. 25. FIG. 25 illustrates the driver circuit 21 connected to the wirings GBL (GBL_A and GBL_B) connected to the functional circuits 51 (51_A and 51_B) connected to the memory cells 10 (10_A and 10_B) connected to different wirings BL (BL_A and BL_B). FIG. 25 also illustrates, as the driver circuit 21, a precharge circuit 71_A, a precharge circuit 71_B, a switch circuit 72_A, a switch circuit 72_B, and a write/read circuit 73 in addition to the sense amplifier 46.

As the functional circuit 51_A and the functional circuit 51_B, a transistor 52_a, a transistor 52_b, a transistor 53_a, a transistor 53_b, a transistor 54_a, a transistor 54_b, a transistor 55_a, and a transistor 55_b are illustrated. The transistors 52_a, 52_b, 53_a, 53_b, 54_a, 54_b, 55_a, and 55_b illustrated in FIG. 25 are OS transistors like the transistor 11 included in the memory cell 10. The functional layer 50 including the functional circuits 51 can be provided in stacked layers like the memory array 20[1] to the memory array 20[m].

The wirings BL_A and BL_B are connected to gates of the transistors 52_a and 52_b. One of a source and a drain of each of the transistors 53_a, 53_b, 54_a, and 54_b is connected to the wiring GBL_A or GBL_B. The wirings GBL_A and GBL_B are provided in the perpendicular direction like the wirings BL_A and BL_B and connected to transistors included in the driver circuit 21. As illustrated in FIG. 25, a control signal WE, a control signal RE, and a selection signal MUX are supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B illustrated in FIG. 25 are Si transistors. Switches 83_A to 83_D included in the switch circuit 72_A and the switch circuit 72_B can also be Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to 81_3. The precharge circuit 71_A is a circuit for precharging the wirings BL_A and BL_B with an intermediate potential VPC corresponding to a potential VDD/2 between VDD and VSS in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes the p-channel transistor 82_1, the p-channel transistor 82_2, the n-channel transistor 82_3, and the n-channel transistor 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged are charged by selecting the memory cell 10_A and the memory cell 10_B, and the potentials of the wiring GBL_A and the wiring GBL_B are set to the high power supply potential VDD or the low power supply potential VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on and off states of the switch circuit 72_A are switched under the control of a switch signal CSEL1. In the case where the switch 83_A and the switch 83_B are n-channel transistors, the switch 83_A and the switch 83_B are turned on and off when the switch signal CSEL1 is at a high level and a low level, respectively. The switch circuit 72_B is a circuit for controlling electrical continuity between the write/read circuit 73 and the bit line pair connected to the sense amplifier 46. The on and off states of the switch circuit 72_B are switched under the control of a switching signal CSEL2. The switches 83_C and 83_D are similar to the switches 83_A and 83_B.

As illustrated in FIG. 25, the memory device 300 can have a structure where the memory cell 10, the functional circuit 51, and the sense amplifier 46 are connected to each other through the wiring BL and the wiring GBL provided in the perpendicular direction which is the shortest distance. With such a structure, the load of the wiring BL is reduced, so that the writing time can be shortened and data reading can be facilitated.

As illustrated in FIG. 25, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can function as a sense amplifier formed with OS transistors. With this structure, a slight difference in the potential of the wiring BL can be amplified at the time of reading to drive the sense amplifier 46 formed using Si transistors.

When a plurality of memory cell arrays and a driver circuit are stacked as described above, high integration and large memory capacity of the memory device can be achieved.

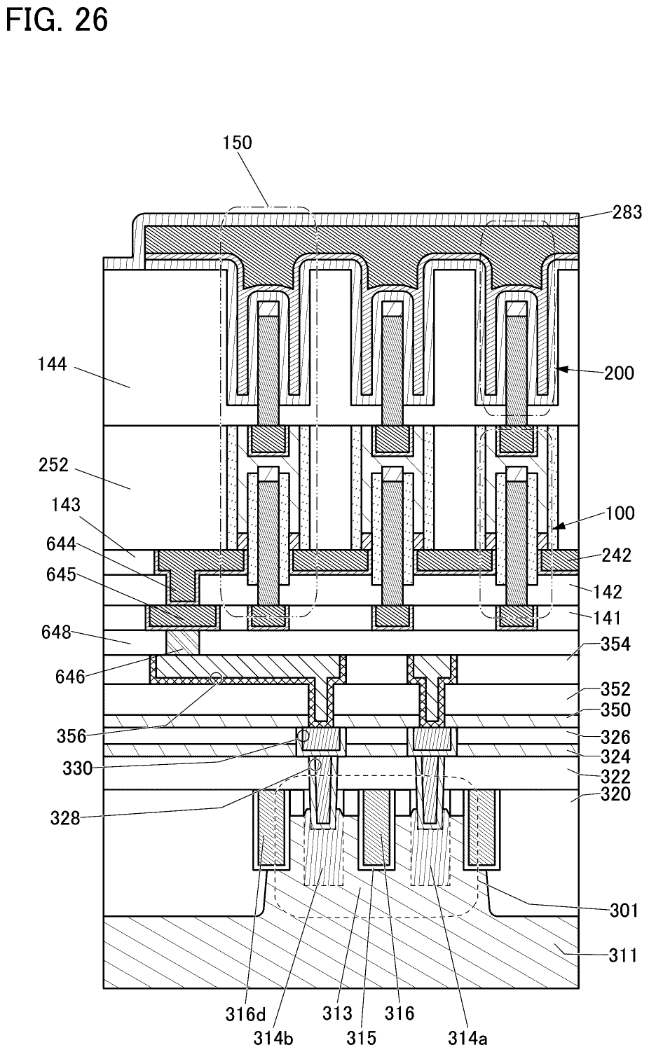

FIG. 26 illustrates a cross-sectional structure example of a memory device in which a layer including a memory cell is stacked over a layer where a driver circuit including a sense amplifier is provided.

In FIG. 26, the capacitor 100 is provided above a transistor 301, and the transistor 200 is provided above the transistor 301 and the capacitor 100.

The transistor 301 is one of the transistors included in the sense amplifier.

The structure of the memory cell 150 (the transistor 200 and the capacitor 100) illustrated in FIG. 26 is described above.

With the structure in which the sense amplifier is provided to overlap with the memory cell 150 as illustrated in FIG. 26, the bit line can be shortened. This reduces bit line capacitance, which can reduce the storage capacitance of the memory cell.

When the transistor 200 is provided above the capacitor 100, the transistor 200 is not affected by thermal budget in fabricating the capacitor 100. Thus, in the transistor 200, degradation of the electrical characteristics such as variation in threshold voltage or an increase in parasitic resistance, and an increase in variation in electrical characteristics due to the degradation of the electrical characteristics can be inhibited.

In the memory device illustrated in FIG. 26, the transistor 301 corresponds to the transistor included in the sense amplifier 46, for example. The memory cell 150 corresponds to the memory cell 10, the transistor 200 corresponds to the transistor 11, and the capacitor 100 corresponds to the capacitor 12.

The transistor 301 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 301 may be a p-channel transistor or an n-channel transistor. A conductor 316d is a dummy gate.

Here, in the transistor 301 illustrated in FIG. 26, the semiconductor region 313 (part of the substrate 311) where a channel is formed has a protruding shape. The conductor 316 is provided to cover the side surface and the top surface of the semiconductor region 313 with the insulator 315 therebetween. Note that the conductor 316 may be formed using a material for adjusting the work function. Such a transistor 301 is also referred to as a FIN-type transistor because it utilizes the protruding portion of the semiconductor substrate. Note that an insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI substrate.

Note that the transistor 301 illustrated in FIG. 26 is an example and the structure is not limited thereto; an appropriate transistor can be used in accordance with a circuit structure or a driving method.

A wiring layer provided with an interlayer film, a wiring, a plug, and the like may be provided between components. A plurality of wiring layers can be provided in accordance with the design. Here, a plurality of conductors functioning as a plug or a wiring are collectively denoted by the same reference numeral in some cases. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 301 as an interlayer film. A conductor 328 is embedded in the insulator 320 and the insulator 322, and a conductor 330 is embedded in the insulator 324 and the insulator 326. Note that the conductor 328 and the conductor 330 function as a plug or a wiring.

The insulator functioning as an interlayer film may function as a planarization film that covers an uneven shape thereunder. For example, the top surface of the insulator 322 may be planarized through planarization treatment using a CMP method or the like to increase the level of planarity.

A wiring layer may be provided over the insulator 326 and the conductor 330. For example, in FIG. 26, an insulator 350, an insulator 352, and an insulator 354 are stacked sequentially. Furthermore, a conductor 356 is formed in the insulator 350, the insulator 352, and the insulator 354. The conductor 356 functions as a plug or a wiring.

As the insulator 352, the insulator 354, and the like functioning as interlayer films, any of the above-described insulators that can be used for the memory device can be used.

As the conductor functioning as a plug or a wiring, such as the conductor 328, the conductor 330, and the conductor 356, any of the conductors described in [Conductor] above can be used. It is preferable to use a high-melting-point material that has both heat resistance and conductivity, such as tungsten or molybdenum, and it is preferable to use tungsten. Alternatively, it is preferable to form the conductor with a low-resistance conductive material such as aluminum or copper. The use of a low-resistance conductive material can reduce wiring resistance.

The conductor 240 included in the transistor 200 is electrically connected to the low-resistance region 314b functioning as the source region or the drain region of the transistor 301 through a conductor 644, a conductor 645, a conductor 646, the conductor 356, the conductor 330, and the conductor 328.

The conductor 644 is embedded in the insulator 142. The conductor 645 is embedded in the insulator 141. The conductor 645 and the conductor 242 can be formed using the same material in the same step. The conductor 646 is embedded in an insulator 648. The transistor 301 and the conductor 242 of the transistor 200 are electrically insulated from each other by the insulator 648. Note that the conductor 245 provided in the insulator 141 and the conductor 242 provided in the insulator 142 may be connected to each other through a conductor provided in an upper insulator. For example, a conductor provided in the insulator 141 is electrically connected to an upper plug provided in the insulator 142, the insulator 143, the insulator 252, the insulator 144, and the like, and a lower plug connected to the conductor 242 provided in the insulator 142 is sequentially provided from the upper plug.

According to one embodiment of the present invention, a novel transistor, semiconductor device, and memory device can be provided. Alternatively, a transistor, a semiconductor device, and a memory device that can be miniaturized or highly integrated can be provided. Alternatively, a transistor, a semiconductor device, and a memory device with high reliability can be provided. Alternatively, a transistor with a high on-state current and a semiconductor device and a memory device including the transistor can be provided. Alternatively, a semiconductor device and a memory device with a small variation in transistor characteristics can be provided. Alternatively, a transistor with favorable electrical characteristics and a semiconductor device and a memory device including the transistor can be provided. Alternatively, a semiconductor device and a memory device with low power consumption can be provided. Alternatively, a memory device with favorable frequency characteristics can be provided. Alternatively, a memory device with a high operation speed can be provided.

This embodiment can be combined as appropriate with any of the other embodiments and the like described in this specification.

### Embodiment 4

In this embodiment, an example of a chip 1200 on which the memory device of the present invention is mounted is described with reference to FIG. 27A and FIG. 27B. A plurality of circuits (systems) are mounted on the chip 1200. A technique for integrating a plurality of circuits (systems) into one chip is referred to as system on chip (SoC) in some cases.

As illustrated in FIG. 27A, the chip 1200 includes a CPU 1211, a GPU 1212, one or more analog arithmetic units 1213, one or more memory controllers 1214, one or more interfaces 1215, one or more network circuits 1216, and the like.

The chip 1200 is provided with a bump (not illustrated) and is connected to a first surface of a package substrate 1201 as illustrated in FIG. 27B. In addition, a plurality of bumps 1202 are provided on a rear side of the first surface of the package substrate 1201, and the package substrate 1201 is connected to a motherboard 1203.

Memory devices such as a DRAM 1221 and a flash memory 1222 may be provided over the motherboard 1203. For example, the DOSRAM described in the above embodiment can be used as the DRAM 1221. This can make the DRAM 1221 achieve lower power consumption, higher speed, and higher capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a number of data and thus can be used for image processing or product-sum operation. When an image processing circuit and a product-sum operation circuit using an oxide semiconductor of the present invention are provided in the GPU 1212, image processing and product-sum operation can be performed with low power consumption.

In addition, since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit for a LAN (Local Area Network) or the like. The network circuit may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be fabricated at low cost.

The motherboard 1203 provided with the package substrate 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in appropriate combination with any of the other embodiments and the like described in this specification.

### Embodiment 5

In this embodiment, examples of electronic components and electronic appliances in which the memory device or the like described in the above embodiment is incorporated are described. When the memory device described in the above embodiment is used for the following electronic components and electronic appliances, the electronic components and electronic appliances can achieve lower power consumption and higher speed.

### <Electronic Component>

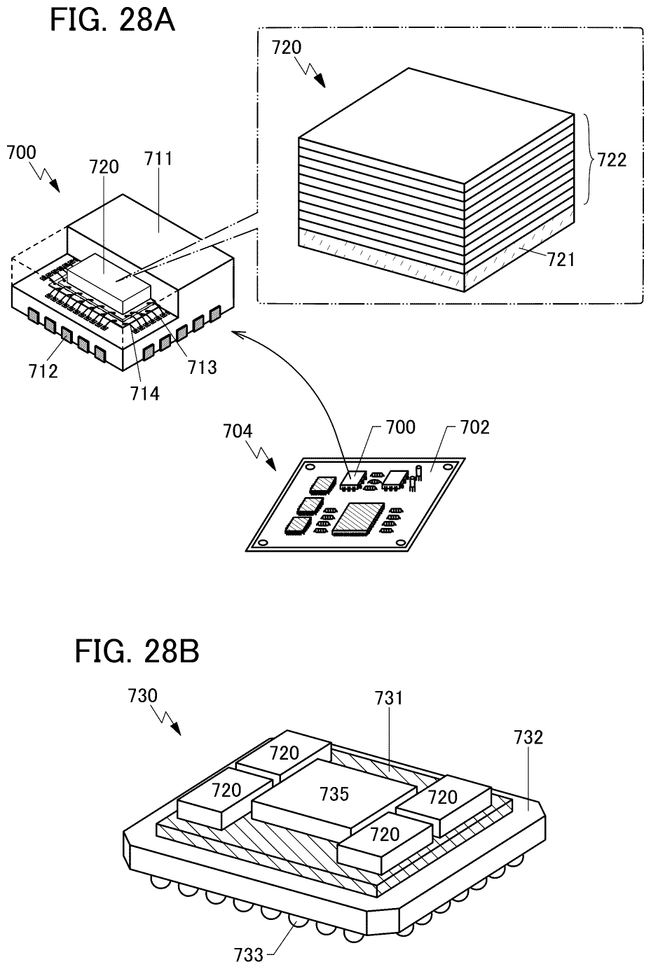

First, examples of electronic components in which a memory device 720 is incorporated are described with reference to FIG. 28A and FIG. 28B.

FIG. 28A illustrates a perspective view of an electronic component 700 and a substrate (a mounting board 704) on which the electronic component 700 is mounted. The electronic component 700 illustrated in FIG. 28A includes the memory device 720 in a mold 711. FIG. 28A omits illustrations of some parts to show the inside of the electronic component 700. The electronic component 700 includes a land 712 outside the mold 711. The land 712 is electrically connected to an electrode pad 713, and the electrode pad 713 is electrically connected to the memory device 720 via a wire 714. The electronic component 700 is mounted on a printed circuit board 702, for example. A plurality of such electronic components are combined and electrically connected to each other on the printed circuit board 702, whereby the mounting board 704 is completed.

The memory device 720 includes a driver circuit layer 721 and a memory circuit layer 722.

FIG. 28B illustrates a perspective view of an electronic component 730. The electronic component 730 is an example of a SiP (System in package) or an MCM (Multi Chip Module). In the electronic component 730, an interposer 731 is provided over a package substrate 732 (a printed circuit board) and a semiconductor device 735 and a plurality of memory devices 720 are provided over the interposer 731. When the memory device described in the above embodiment is used as the memory device 720, lower power consumption and higher speed can be achieved.

An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV (Through Silicon Via) can also be used as the through electrode.

A silicon interposer is preferably used as the interposer 731. The silicon interposer can be fabricated at lower cost than an integrated circuit because it is not necessary to provide an active element. Moreover, since wirings of the silicon interposer can be formed through a semiconductor process, the formation of minute wirings, which is difficult for a resin interposer, is easily achieved.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (a radiator plate) may be provided to overlap with the electronic component 730. In the case of providing a heat sink, the levels of integrated circuits provided on the interposer 731 are preferably equal to each other. In the electronic component 730 of this embodiment, the levels of the memory device 720 and the semiconductor device 735 are preferably equal to each other, for example.

An electrode 733 may be provided on the bottom portion of the package substrate 732 to mount the electronic component 730 on another substrate. FIG. 28B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in appropriate combination with any of other structures, methods, and the like described in this embodiment or any of structures, methods, and the like described in the other embodiments.

### Embodiment 6

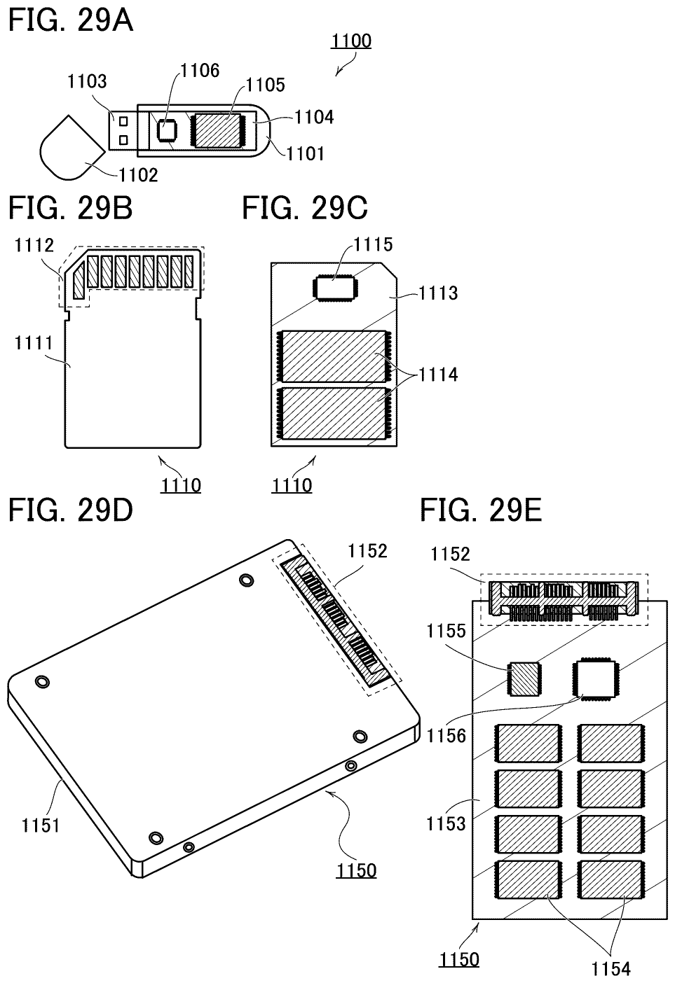

In this embodiment, application examples of memory devices using the memory device described in the above embodiment are described. The memory device described in the above embodiment can be used for, for example, memory devices of a variety of electronic appliances (e.g., information terminals, computers, smartphones, e-book readers, digital cameras (including video cameras), video recording/reproducing devices, and navigation systems). When the memory device described in the above embodiment is used for the memory devices of the above electronic appliances, the electronic appliances can achieve lower power consumption and higher speed. Note that, here, the computers refer not only to tablet computers, notebook computers, and desktop computers but also to large computers such as server systems. Alternatively, the memory device described in the above embodiment is used for a variety of removable storage devices such as memory cards (e.g., SD cards), USB memories, and SSDs (solid state drives). FIG. 29A to FIG. 29E schematically illustrate some structure examples of removable memory devices. The memory device described in the above embodiment is processed into a packaged memory chip and used in a variety of storage devices and removable memories, for example.

FIG. 29A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The memory device described in the above embodiment can be incorporated in the memory chip 1105 or the like.

FIG. 29B is a schematic external view of an SD card, and FIG. 29C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. With this, data can be read from and written to the memory chip 1114 by radio communication between a host device and the SD card 1110. The memory device described in the above embodiment can be incorporated in the memory chip 1114 or the like.

FIG. 29D is a schematic external view of an SSD, and FIG. 29E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip is used, for example. When the memory chip 1154 is also provided on the back side of the substrate 1153, the capacity of the SSD 1150 can be increased. The memory device described in the above embodiment can be incorporated in the memory chip 1154 or the like.

At least part of the structure, method, and the like described in this embodiment can be implemented in appropriate combination with any of the other embodiments and the like described in this specification.

### Embodiment 7

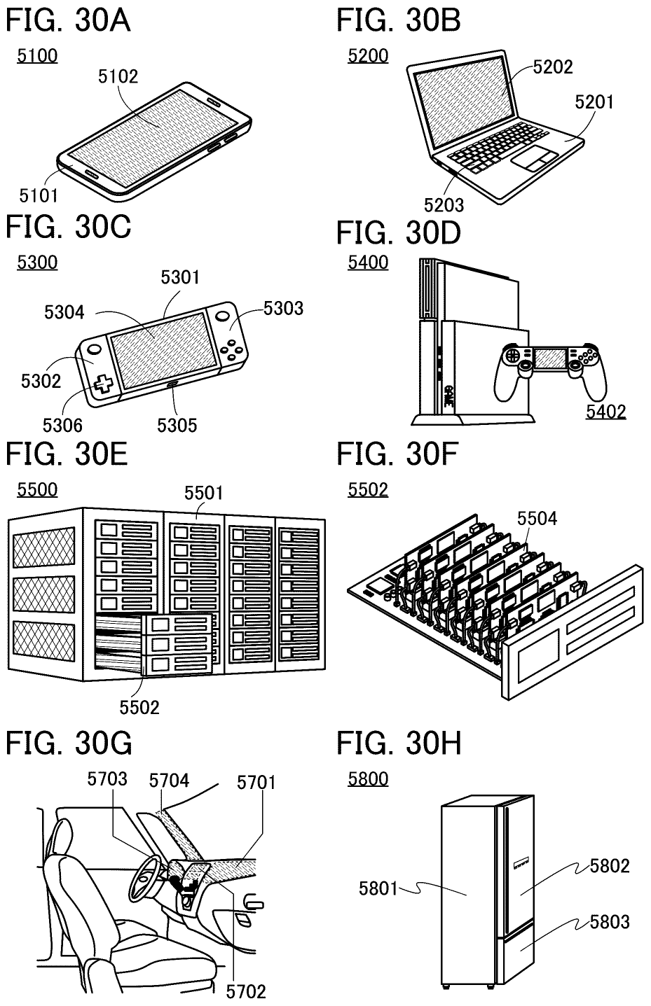

The memory device of one embodiment of the present invention can be used for a processor, e.g., a CPU or a GPU, or a chip. When such a processor, e.g., a CPU or a GPU, or such a chip is used for an electronic appliance, the electronic appliance can achieve lower power consumption and higher speed. FIG. 30A to FIG. 30H illustrate specific examples of the electronic appliance provided with the processor, e.g., the CPU or the GPU, or the chip that includes the memory device.

### <Electronic Appliance and System>

The GPU or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic device includes the antenna and a secondary battery, the antenna may be used for contactless power transmission.

The electronic appliance of one embodiment of the present invention may include a sensor (a sensor having a function of detecting, sensing, or measuring force, displacement, position, speed, acceleration, angular velocity, rotational frequency, distance, light, liquid, magnetism, temperature, a chemical substance, sound, time, hardness, an electric field, current, voltage, electric power, radioactive rays, flow rate, humidity, a gradient, oscillation, odor, or infrared rays).

The electronic appliance of one embodiment of the present invention can have a variety of functions. For example, the electronic appliance can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 30A to FIG. 30H illustrate examples of electronic appliances.

### [Information Terminal]

FIG. 30A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

The use of the chip of one embodiment of the present invention enables lower power consumption and higher speed of the information terminal 5100.

FIG. 30B illustrates a notebook information terminal 5200. The notebook information terminal 5200 includes a main body 5201 of the information terminal, a display portion 5202, and a keyboard 5203.

The use of the chip of one embodiment of the present invention enables lower power consumption and higher speed of the notebook information terminal 5200, like the information terminal 5100 described above.

Note that although the smartphone and the notebook information terminal are respectively illustrated in FIG. 30A and FIG. 30B as examples of the electronic appliance, an information terminal other than the smartphone and the notebook information terminal can be used. Examples of information terminals other than the smartphone and the notebook information terminal include a PDA (Personal Digital Assistant), a desktop information terminal, and a workstation.

### [Game Machine]

FIG. 30C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), a video to be output to the display portion 5304 can be output to another video device (not illustrated). In that case, the housing 5302 and the housing 5303 can each function as an operation portion. Thus, a plurality of players can play a game at the same time. The chip described in the above embodiment can be incorporated into the chip or the like provided on a substrate in each of the housing 5301, the housing 5302, and the housing 5303.

FIG. 30D illustrates a stationary game machine 5400, which is an example of a game machine. A controller 5402 is connected to the stationary game machine 5400 with or without a wire.

The use of the GPU or the chip of one embodiment of the present invention in a game machine such as the portable game machine 5300 or the stationary game machine 5400 can achieve a low-power-consumption game machine. Moreover, heat generation from a circuit can be reduced owing to low power consumption; thus, the influence of heat generation on the circuit, a peripheral circuit, and a module can be reduced.

Furthermore, the use of the GPU or the chip of one embodiment of the present invention in the portable game machine 5300 enables lower power consumption and higher speed.

Although the portable game machine and the stationary game machine are illustrated as examples of game machines in FIG. 30C and FIG. 30D, the game machine using the GPU or the chip of one embodiment of the present invention is not limited thereto. Examples of the game machine using the GPU or the chip of one embodiment of the present invention include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 30E illustrates a supercomputer 5500 as an example of a large computer. FIG. 30F illustrates a rack-mount computer 5502 included in the supercomputer 5500.

The supercomputer 5500 includes a rack 5501 and a plurality of rack-mount computers 5502. Note that the plurality of computers 5502 are stored in the rack 5501. The computer 5502 includes a plurality of substrates 5504 on which the GPU or the chip described in the above embodiment can be mounted.

The supercomputer 5500 is a large computer mainly used for scientific computation. In scientific computation, an enormous amount of arithmetic operation needs to be processed at high speed; hence, power consumption is high and chips generate a large amount of heat. For example, the amount of digital data used in a data center including a plurality of supercomputers 5500 is quite voluminous. Specifically, the amount of digital data in the world is expected to exceed 1024 (yota) bytes or 1030 (quetta) bytes.

The use of the GPU or the chip of one embodiment of the present invention in the supercomputer 5500 can achieve a low-power-consumption supercomputer. Moreover, heat generation from a circuit can be reduced owing to low power consumption; thus, the influence of heat generation on the circuit, a peripheral circuit, and a module can be reduced. The use of the GPU or the chip including the memory device of one embodiment of the present invention can achieve a low-power-consumption supercomputer. This can be expected to reduce the amount of digital data in the world to make a significant contribution to global warming countermeasures.

Although a supercomputer is illustrated as an example of a large computer in FIG. 30E and FIG. 30F, a large computer using the GPU or the chip of one embodiment of the present invention is not limited thereto. Other examples of large computers using the GPU or the chip of one embodiment of the present invention include a computer that provides service (a server) and a large general-purpose computer (a mainframe).

### [Moving Vehicle]

The GPU or the chip of one embodiment of the present invention can be used in an automobile, which is a moving vehicle, and the periphery of a driver's seat in the automobile.

FIG. 30G illustrates an area around a windshield inside an automobile, which is an example of a moving vehicle. FIG. 30G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an image capturing device (not illustrated) provided for the automobile. That is, displaying an image taken by the image capturing device provided outside the automobile leads to compensation for the blind spot and an increase in safety. In addition, displaying a video to compensate for a portion that cannot be seen makes it possible for the driver to confirm the safety more naturally and comfortably. The display panel 5704 can also be used as a lighting device.

Since the GPU or the chip of one embodiment of the present invention can be used as a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Although the automobile is described above as an example of a moving vehicle, the moving vehicle is not limited to the automobile. Examples of the moving vehicle include a train, a monorail train, a ship, and a flying vehicle (a helicopter, an unmanned aircraft (a drone), an airplane, and a rocket), and these moving vehicles can each have a system utilizing artificial intelligence when the chip of one embodiment of the present invention is used in each of these moving vehicles.

### [Household Appliance]

FIG. 30H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is used in the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like.

Although the electric refrigerator-freezer is described as an example of a household appliance, other examples of household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described in this embodiment can be implemented in appropriate combination with any of the other embodiments and the like described in this specification.

### Embodiment 8

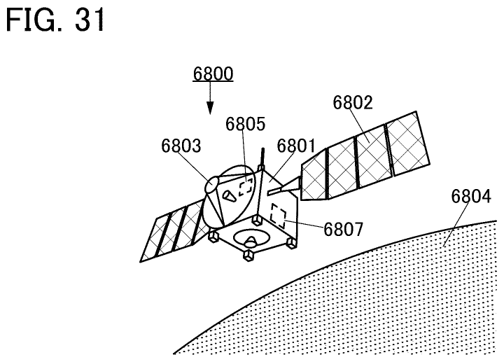

The memory device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space. In this embodiment, a specific example of a case where the memory device of one embodiment of the present invention is used in a device for space is described with reference to FIG. 31.

FIG. 31 illustrates an artificial satellite 6800 as an example of a device for space. The artificial satellite 6800 includes a body 6801, a solar panel 6802, an antenna 6803, a secondary battery 6805, and a control device 6807. Note that FIG. 31 illustrates a planet 6804 in outer space, for example. Note that outer space refers to, for example, space at an altitude greater than or equal to 100 km, and outer space in this specification may also include thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the memory device including the OS transistor, which is one embodiment of the present invention, is suitably used for the control device 6807. A change in electrical characteristics due to exposure to radiation is smaller in the OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The memory device of one embodiment of the present invention can be suitably used also for a device for space such as a spacecraft, a space capsule, or a space probe, for example.

### REFERENCE NUMERALS

ADDR: signal, An: angle, BL[1]: wiring, BL[j]: wiring, BL[n]: wiring, BL_A: wiring, BL_B: wiring, BL: wiring, BW: wiring, CE: signal, CLK: signal, EN_data: signal, GBL_A: wiring, GBL_B: wiring, GBL: wiring, GW: signal, Lg: channel length, Li: length, Lov: length, MUX: selection signal, Off: region, PL[1]: wiring, PL[i]: wiring, PL[m]: wiring, PL: wiring, RDA: signal, RE: control signal, Tr: transistor, VDD: high power supply potential, VHH: wiring, VLL: wiring, VPC: intermediate potential, VSS: low power supply potential, WA: width, WAKE: signal, WB: width, WDA: signal, WE: control signal, WL[1]: wiring, WL[i]: wiring, WL[m]: wiring, WL: wiring, 10[1,1]: memory cell, 10[i,j]: memory cell, 10[m,n]: memory cell, 10_A: memory cell, 10_B: memory cell, 10: memory cell, 11: transistor, 12: capacitor, 20[1]: memory array, 20[2]: memory array, 20[5]: memory array, 20[m]: memory array, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51_A: functional circuit, 51_B: functional circuit, 51: functional circuit, 52_a: transistor, 52_b: transistor, 53_a: transistor, 53_b: transistor, 54_a: transistor, 54_b: transistor, 55_a: transistor, 55_b: transistor, 70[1]: repeating unit, 70[p]: repeating unit, 70: repeating unit, 71_A: precharge circuit, 71_B: precharge circuit, 72_A: switch circuit, 72_B: switch circuit, 73: write/read circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 91: opening, 92: opening, 93: space, 94: space, 96: opening, 97: opening, 100: capacitor, 110a: conductor, 110b: conductor, 110: conductor, 120: conductor, 121f: insulator, 121: insulator, 130: insulator, 140: insulator, 141: insulator, 142f: insulator, 142f_1: insulator, 142f_2: insulator, 142g: insulator, 142k: insulator, 142p: opening, 142: insulator, 143: insulator, 144a: insulator, 144a_f: insulator, 144b: insulator, 144b_f: insulator, 144b_g: insulator, 144f: insulator, 144f_1: insulator, 144f_2: insulator, 144g: insulator, 144: insulator, 147f: insulator, 147f_1: insulator, 147f_2: insulator, 147g: insulator, 148f: insulator, 148: insulator, 149f: insulator, 149g: insulator, 149: insulator, 150: memory cell, 200: transistor, 230f: oxide semiconductor, 230i: region, 230n: region, 230: oxide semiconductor, 231f: metal oxide, 231g: metal oxide, 231: metal oxide, 240a: conductor, 240b: conductor, 240f: conductor, 240: conductor, 242a: conductor, 242b: conductor, 242f: conductor, 242p: opening, 242: conductor, 245: conductor, 250f: insulator, 250: insulator, 251f:

insulator, 251: insulator, 252a: insulator, 252a_f: insulator, 252a_g: insulator, 252a_h: insulator, 252b: insulator, 252b_g: insulator, 252: insulator, 260f: conductor, 260: conductor, 262a: conductor, 262b: conductor, 262: conductor, 277f: insulator, 277: insulator, 283: insulator, 287: insulator, 300A: memory device, 300: memory device, 301: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 610: substrate, 611a: precursor, 611b: precursor, 612a: reactant, 612b: reactant, 613a: oxide, 613b: oxide, 613c: oxide, 621: layer, 622: layer, 631: layer, 641: layer, 644: conductor, 645: conductor, 646: conductor, 648: insulator, 650: structure body, 653: region, 654: region, 660: oxide, 662: oxide, 700: electronic component, 702: printed circuit board, 704: mounting board, 711: mold, 712: land, 713: electrode pad, 714: wire, 720: memory device, 721: driver circuit layer, 722: memory circuit layer, 730: electronic component, 731: interposer, 732: package substrate, 733: electrode, 735: semiconductor device, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door, 6800: artificial satellite, 6801: body, 6802: solar panel, 6803: antenna, 6804: planet, 6805: secondary battery, 6807: control device

1. A transistor comprising:
a first conductor comprising a columnar region;
a first insulator comprising a first region of a tubular shape;
a second conductor comprising a first opening penetrated by the first conductor;
a first semiconductor positioned over the second conductor and comprising a second region of a tubular shape; and
a third conductor over the first semiconductor,
wherein the first region surrounds the columnar region,
wherein the first conductor comprises a third region positioned above the first opening, and
wherein the third region of the first conductor is surrounded by the second region with the first region therebetween.

2. The transistor according to claim 1, wherein the third conductor overlaps with the first conductor.

3. The transistor according to claim 1, comprising:
a second insulator,
wherein the second insulator comprises a second opening,
wherein the first conductor comprises a region positioned in the second opening, and
wherein the second conductor comprises a region in contact with a top surface of the second insulator.

4. A transistor comprising:
a first conductor comprising a columnar region;
a first insulator comprising a first region of a tubular shape;
a second conductor comprising a first opening penetrated by the first conductor;
a first semiconductor positioned over the second conductor and comprising a second region of a tubular shape;
a second insulator over the first conductor; and
a third conductor over the second insulator,
wherein the first region surrounds the columnar region,
wherein the first conductor comprises a third region positioned above the first opening,
wherein the third region of the first conductor is surrounded by the second region of the first semiconductor with the first region therebetween, and
wherein the third conductor overlaps with the first conductor with the second insulator therebetween.

5. (canceled)

6. The transistor according to claim 4, wherein the first semiconductor comprises a region positioned over the second insulator and positioned between the second insulator and the third conductor.

7. The transistor according to claim 4,
wherein the first insulator comprises at least one of silicon oxide and silicon oxynitride, and
wherein the second insulator comprises at least one of silicon nitride and silicon nitride oxide.

8. The transistor according to claim 4, comprising:
a third insulator,
wherein the third insulator comprises a second opening,
wherein the first conductor comprises a region positioned in the second opening, and
wherein the second conductor comprises a region in contact with a top surface of the second insulator.

9. The transistor according to claim 1 or claim 4, wherein the third conductor is in contact with a top surface of the first semiconductor.

10. The transistor according to claim 1 or claim 4, wherein the first semiconductor comprises a region in contact with a side surface of the third conductor.

11. The transistor according to claim 1, wherein the first semiconductor is a metal oxide comprising indium or zinc.

12. A memory device comprising:
a transistor and a capacitor over the transistor,
wherein the transistor comprises a first conductor comprising a columnar region,
wherein the transistor comprises a first insulator comprising a first region of a tubular shape,
wherein the transistor comprises a second conductor comprising a first opening penetrated by the first conductor,
wherein the transistor comprises a first semiconductor positioned over the second conductor and comprising a second region of a tubular shape,
wherein the transistor comprises a third conductor over the first semiconductor,
wherein the capacitor comprises a fourth conductor comprising a columnar region, a second insulator provided to cover a side surface of the fourth conductor, and a fifth conductor over the second insulator,
wherein the first region of the first insulator surrounds the columnar region of the first conductor,
wherein the first conductor comprises a third region positioned above the first opening,
wherein the third region of the first conductor is surrounded by the second region of the first semiconductor with the first region therebetween, and
wherein the fourth conductor is positioned over the third conductor.

13. The memory device according to claim 12, wherein the third conductor overlaps with the first conductor.

14. The memory device according to claim 12, wherein the first conductor and the fourth conductor overlap with each other in a plan view.

15. The memory device according to claim 12, comprising:
a third insulator,
wherein the third insulator comprises a second opening, and
wherein the fourth conductor comprises a fourth region positioned in the second opening and having a side surface in contact with the third insulator and a fifth region positioned over the fourth region and having a side surface in contact with the second insulator.

16. The transistor according to claim 4, wherein the third conductor is in contact with a top surface of the first semiconductor.

17. The transistor according to claim 4, wherein the first semiconductor comprises a region in contact with a side surface of the third conductor.

18. The transistor according to claim 4, wherein the first semiconductor is a metal oxide comprising indium or zinc.
